(19) United States
(12) Patent Application Publication
(10) Pub. No.: US 2026/0090229 A1
(43) Pub. Date: Mar. 26, 2026

(54) SEMICONDUCTOR NANOPARTICLE, METHOD OF PRODUCING THE SAME AND ELECTRONIC DEVICE INCLUDING THE SAME

(71) Applicant: SAMSUNG ELECTRONICS CO., LTD., Suwon-si (KR)

(72) Inventors: Jong Hoon WON, Suwon-si (KR); Sungi Kim, Suwon-si (KR); Deuk Kyu MOON, Suwon-si (KR); Shang Hyeun PARK, Suwon-si (KR); Young Hoon LEE, Suwon-si (KR); Deuk Seok CHUNG, Suwon-si (KR)

(21) Appl. No.: 19/208,190

(22) Filed: May 14, 2025

(30) Foreign Application Priority Data
May 14, 2024 (KR) 10-2024-0063226

(51) Int. Cl. H10K 59/38; H10K 102/00

(52) U.S. Cl. CPC H10K 59/38; H10K 2102/331

(57) ABSTRACT

A display panel, a semiconductor nanoparticle composite, an electronic device and a color filter are provided. The display panel includes a light emitting panel and a color conversion panel facing the light emitting panel, where the light emitting panel includes a light emitting device configured to emit incident light including first light and second light. A maximum peak emission wavelength of the first light is present in a range of greater than or equal to about 440 nm and less than or equal to about 480 nm, and a maximum peak emission wavelength of the second light is present in a range of greater than or equal to about 500 nm and less than or equal to about 580 nm.

### CROSS-REFERENCE TO RELATED APPLICATION

This application is based on and claims priority to Korean Patent Application No. 10-2024-0063226 filed in the Korean Intellectual Property Office on May 14, 2021, and all the benefits accruing therefrom under 35 U.S.C. § 119, the entire content of which is incorporated herein by reference.

### BACKGROUND

### 1. Field

A semiconductor nanoparticle composite, a display panel including a semiconductor nanoparticle composite, an electronic device including the display panel, and a color filter including the semiconductor nanoparticle composite are disclosed,

### 2. Description of the Related Art

A semiconductor nanoparticle may exhibit different aspects, characteristics, or properties compared to a corresponding bulk material having substantially the same composition. For example, the semiconductor nanoparticle may have different physical properties based on the nanostructure (e.g., bandgap energy, a luminescent property, or the like), The semiconductor nanoparticle may be configured to emit light upon excitation by incident light or an applied voltage. The luminescent nanostructure may find applicability in a variety of devices (e.g., a display panel or an electronic device including the display panel). From an environmental point of view, developing a luminescent nanoparticle that does not contain a harmful heavy metal, such as cadmium, and yet achieving an improvement in one or more luminescent or optical properties is desirable.

### SUMMARY

An embodiment provides a semiconductor nanoparticle composite (or a pattern thereof, e.g., a light-emitting color filter) configured to provide enhanced display quality (e.g., increased luminance) in a display device.

An embodiment relates to a color conversion panel including the semiconductor nanoparticle composite or the pattern thereof, or a display panel including the semiconductor nanoparticle composite or the pattern thereof.

In an embodiment, a display panel includes a light emitting panel; and a color conversion panel facing, e.g., with a surface opposite a surface of the light emitting panel,
wherein the light emitting panel is configured to emit an incident light including a first light with a peak emission wavelength greater than or equal to about 440 nanometers (nm) and less than or equal to about 480 nm, and a second light with a peak emission wavelength of greater than or equal to about 500 nm and less than or equal to about 580 nm,
the color conversion panel includes a color conversion layer including a color conversion region (e.g., two or more color conversion regions),
the color conversion region includes a first region corresponding to a green pixel,
the first region includes a composite, e.g., a first composite, including a matrix and a semiconductor nanoparticle, e.g., a plurality of luminescent nanostructures dispersed within the matrix, and
the semiconductor nanoparticle includes (e.g., a Group 11-13-16 compound including) silver, a Group 13 metal, and a chalcogen element, the Group 13 metal includes indium and gallium, the chalcogen element includes sulfur.

In the semiconductor nanoparticle, a mole ratio of gallium to indium may be greater than or equal to about 6:1 and less than or equal to about 30:1, and a mole ratio of silver to indium may be greater than or equal to about 3:1 and less than or equal to about 19:1.

In an embodiment, the composite, e.g., the first composite, has an absorbance of greater than or equal to about 80% for the first light, and the composite, e.g., the first composite has a transmittance of greater than or equal to about 55% for light having a wavelength of 530 nm.

The light-emitting panel of the display panel may include a light-emitting device. The light-emitting device may include an organic light emitting diode, a micro LED, a mini LED, a nanorod-including LED, or a combination thereof.

The light emitting panel or the light emitting device of the light-emitting panel may include a first electrode and a second electrode, and an emission layer (e.g., a light emitting layer) disposed between the first electrode and the second electrode, The emission layer, e.g., a light-emitting layer, may include an organic compound and a dopant.

The emission layer may include a first emission layer or a first emission stack, which hereinafter can be referred to as the first emission layer and a second emission layer (or a second emission stack, which hereinafter can be referred to as the second emission layer) disposed on the first emission layer. The first emission layer may be configured to emit the first light. The second emission layer may be configured to emit the second light. The emission layer may further include a first charge generation layer disposed between the first emission layer and the second emission layer. The emission layer may further include a charge auxiliary layer disposed between the first electrode and the first emission layer, between the second electrode and the second emission layer, or between the first electrode and the first emission layer and between the second electrode and the second emission layer.

The first emission stack may include a first emission layer disposed between the charge auxiliary layers (e.g., a hole transport layer and an electron transport layer). The second emission stack may include a second emission layer disposed between the charge auxiliary layers (e.g., a hole transport layer and an electron transport layer).

The emission layer may include a second emission layer disposed between two or more first emission layers. The emission layer may include a first emission layer disposed between two or more second emission layers.

In an embodiment, in the light-emitting panel of the display panel, a first emission stack configured to emit blue light, a second emission stack configured to emit green light, and the first emission stack configured to emit blue light may be laminated (stacked) in this order. A charge generation layer may be disposed or may not be disposed between the respective emission stacks. Each emission stack may include a hole transport layer/a light-emitting layer/an electron transport layer.

The incident light may include green light and blue light.

The peak emission wavelength of the second light may be greater than or equal to about 515 nm and less than or equal to about 535 nm. The peak emission wavelength of the first light may be greater than about 440 nm, greater than or equal to about 445 nm, greater than or equal to about 450 nm, for example, greater than or equal to about 455 nm and less than or equal to about 470 nm, or less than or equal to about 465 nm.

The Group 13 metal may include indium, gallium, aluminum, or a combination thereof. The Group 13 metal may include indium and gallium. The chalcogen element may include sulfur, selenium, or a combination thereof. In the semiconductor nanoparticle, the chalcogen element may include sulfur and may optionally include or may not include selenium. In an embodiment the chalcogen element includes only sulfur. The semiconductor nanoparticle may further include zinc. The semiconductor nanoparticle or a surface thereof may include gallium and zinc. The semiconductor nanoparticle may further include chlorine.

The semiconductor nanoparticle may have a charge balance value (total cations/total anions) represented by the following formula of greater than or equal to about 0.8 and less than or equal to about 1.8, or less than or equal to about 2.5:

$$charge balance value = \{ [ Ag ] + 3 \times ( [ Group 13 metal ] ) + 2 [ Zn ] \} / ( 2 \times [ CH A ] )$$

where [Ag], [Group 13 metal], [Zn], and [CHA] are mole amounts of silver, Group 13 metal, zinc, and chalcogen element in the semiconductor nanoparticle, respectively.

The charge balance value may be greater than or equal to about 0.9, or greater than or equal to about 1.

The charge balance value may be less than or equal to about 2.1, less than or equal to about 1.8, less than or equal to about 1.3, less than or equal to about 1.2, or less than or equal to about 1.1.

In the semiconductor nanoparticle, a mole ratio (Ga/In) of gallium to indium may be greater than or equal to about 6:1, greater than or equal to about 6.4:1, greater than or equal to about 6.7:1 and less than or equal to about 35:1, or less than or equal to about 32:1, less than or equal to about 10:1, or less than or equal to about 8:1.

In the semiconductor nanoparticle, a mole ratio (Ag:In) of silver to indium may be greater than or equal to about 3:1, greater than or equal to about 3.8:1, greater than or equal to about 4.5:1, greater than or equal to about 5.2:1, or greater than or equal to about 6.1:1 and less than or equal to about 19:1, less than or equal to about 12:1, less than or equal to about 8:1, less than or equal to about 7:1, or less than or equal to about 6.5:1.

In the semiconductor nanoparticle, a mole ratio (Ga:S) of gallium to sulfur may be less than or equal to about 1:1, less than or equal to about 0.9:1, less than or equal to about 0.63:1, or less than or equal to about 0.6:1. The mole ratio (Ga:S) of gallium to sulfur may be greater than or equal to about 0.1:1, greater than or equal to about 0.3:1, greater than or equal to about 0.35:1, greater than or equal to about 0.48:1, greater than or equal to about 0.5:1, or greater than or equal to about 0.53:1.

In the semiconductor nanoparticle, a mole ratio (In:S) of indium to sulfur may be greater than or equal to about 0.02:1, greater than or equal to about 0.05:1, greater than or equal to about 0.06:1, greater than or equal to about 0.07:1, or greater than or equal to about 0.08:1 and less than or equal to about 0.12:1, less than or equal to about 0.1:1, or less than or equal to about 0.08:1.

In the semiconductor nanoparticle, a mole ratio (Ag:S) of silver to sulfur may be greater than or equal to about 0.3:1, greater than or equal to about 0.35:1, greater than or equal to about 0.37:1, or greater than or equal to about 0.39:1, and less than or equal to about 0.44:1, less than or equal to about 0.42:1, or less than or equal to about 0.4:1.

In the semiconductor nanoparticle, a mole ratio [(In+Ga):S] of a total content of indium and gallium to sulfur may be greater than or equal to about 0.4:1, greater than or equal to about 0.5:1, greater than or equal to about 0.54:1, greater than or equal to about 0.55:1, greater than or equal to about 0.57:1, or greater than or equal to about 0.61:1 and less than or equal to about 0.85:1, less than or equal to about 0.67:1, or less than or equal to about 0.65:1.

In the semiconductor nanoparticle, a mole ratio ((In+Ga):Ag) of a total content of indium and gallium to silver may be greater than or equal to about 1:1, greater than or equal to about 1.2:1, greater than or equal to about 1.4:1, greater than or equal to about 1.41:1, greater than or equal to about 1.47:1, greater than or equal to about 1.48:1, greater than or equal to about 1.51:1, greater than or equal to about 1.6:1, greater than or equal to about 1.64:1, greater than or equal to about 1.7:1, or greater than or equal to about 1.8:1 and less than or equal to about 7.0:1, less than or equal to about 3.5:1, less than or equal to about 2:1, less than or equal to about 1.8:1, less than or equal to about 1.66:1, less than or equal to about 1.65:1, or less than or equal to about 1.5:1.

In the semiconductor nanoparticle, a mole ratio [Ga:(In+Ga)] of gallium to a total content of indium and gallium may be less than or equal to about 0.99:1, less than or equal to about 0.97:1, less than or equal to about 0.9:1, less than or equal to about 0.89:1, less than or equal to about 0.88:1, or less than or equal to about 0.87:1. The mole ratio of gallium to a total content of indium and gallium may be greater than or equal to about 0.65:1, greater than or equal to about 0.7:1, greater than or equal to about 0.86:1, greater than or equal to about 0.87:1, or greater than or equal to about 0.88:1.

In the semiconductor nanoparticle, a mole ratio [Ag:(Ag+In+Ga)] of silver to a total content of silver, indium, and gallium may be greater than or equal to about 0.2:1, greater than or equal to about 0.31:1, greater than or equal to about 0.37:1, greater than or equal to about 0.375:1, greater than or equal to about 0.38:1, greater than or equal to about 0.4:1, or greater than or equal to about 0.41:1 and less than or equal to about 0.5:1, less than or equal to about 0.45:1, less than or equal to about 0.42:1, less than or equal to about 0.415:1, less than or equal to about 0.41:1, or less than or equal to about 0.40:1.

In the semiconductor nanoparticle, a mole ratio [S:(Ag+In+Ga)] of sulfur to a total content of silver, indium, and gallium may be greater than or equal to about 0.8:1, greater than or equal to about 0.92:1, greater than or equal to about 0.97:1, or greater than or equal to about 1:1, and less than or equal to about 1.2:1, less than or equal to about 1.12:1, less than or equal to about 1.1:1, less than or equal to about 1.08:1, less than or equal to about 1.06:1, less than or equal to about 1.04:1, or less than or equal to about 1.02:1.

The semiconductor nanoparticle may include a first semiconductor nanocrystal including silver, indium, gallium, and sulfur, and a second semiconductor nanocrystal including silver, gallium, and sulfur.

The semiconductor nanoparticle may include an additional semiconductor nanocrystal (e.g., a third semiconductor nanocrystal or a fourth semiconductor nanocrystal) including zinc, sulfur, and optionally gallium. For example, the semiconductor nanoparticle may include a third semiconductor nanocrystal including zinc, gallium, and sulfur, or a combination thereof.

In the semiconductor nanoparticle, a mole ratio of zinc to a chalcogen element (e.g., sulfur) may be less than or equal to about 0.8:1, less than or equal to about 0.3:1, less than or equal to about 0.25:1, or less than or equal to about 0.19:1. In the semiconductor nanoparticle, the mole ratio of zinc to the chalcogen element (e.g., sulfur) may be greater than or equal to about 0.01:1 or greater than or equal to about 0.05:1.

In the semiconductor nanoparticles, a mole ratio (Zn:Ag) of zinc (Zn) to silver (Ag) may be greater than or equal to about 0.3:1, or greater than or equal to about 0.5:1 and less than or equal to about 5:1, less than or equal to about 3.5:1, or less than or equal to about 2:1.

The semiconductor nanoparticle may not include lithium. The semiconductor nanoparticle may not include sodium. The semiconductor nanoparticle may not include an alkali metal. The semiconductor nanoparticle may include or may not include copper. The semiconductor nanoparticle or the composite including a first semiconductor nanoparticle, e.g., the first composite including a first semiconductor nanoparticle may be configured to emit green light.

The green light or the first composite, e.g., a first composite including a first semiconductor nanoparticle, may have a peak emission wavelength of greater than or equal to about 500 nm or greater than or equal to about 505 nm and less than or equal to about 580 nm, or less than or equal to about 550 nm.

The green light may have a full width at half maximum of greater than or equal to about 15 nm and less than or equal to about 45 nm.

The semiconductor nanoparticle or composite, e.g., the first composite including the first semiconductor nanoparticle may have a quantum efficiency of greater than or equal to about 40% or greater than or equal to about 60%.

In the semiconductor nanoparticle, an absorption ratio (A450:A350) of light having a wavelength of 450 nm to light having a wavelength of 350 nm in a ultraviolet visual (UV-Vis) absorption spectrum may be greater than or equal to about 0.1:1, greater than or equal to about 0.15:1, greater than or equal to about 0.2:1, greater than or equal to about 0.22:1, greater than or equal to about 0.23:1, greater than or equal to about 0.25:1, greater than or equal to about 0.28:1, or greater than or equal to about 0.32:1 and less than or equal to about 0.5:1, less than or equal to about 0.45:1, less than or equal to about 0.4:1, less than or equal to about 0.35:1, or less than or equal to about 0.32:1.

In the semiconductor nanoparticle, an absorption ratio (A530:A350) of light having a wavelength of 530 nm to light having a wavelength of 350 nm in a UV-Vis absorption spectrum may be greater than or equal to about 0.001:1, greater than or equal to about 0.005:1, greater than or equal to about 0.01:1, greater than or equal to about 0.02:1, greater than or equal to about 0.03:1, or greater than or equal to about 0.04, greater than or equal to about 0.05:1 and less than or equal to about 0.2:1, less than or equal to about 0.16:1, less than or equal to about 0.15:1, less than or equal to about 0.13:1, less than or equal to about 0.12:1, less than or equal to about 0.1:1, or less than or equal to about 0.08:1.

The composite, e.g., the first composite including the first semiconductor nanoparticle may have an absorbance for the first light of greater than or equal to about 85% or greater than or equal to about 89%.

The composite, e.g., the first composite including the first semiconductor nanoparticle may have an absorbance for the first light of less than or equal to about 99% or less than or equal to about 90%.

The composite, e.g., the first composite including the first semiconductor nanoparticle may have a transmittance for light having a wavelength of 530 nm of greater than or equal to about 55%, greater than or equal to about 60%, or greater than or equal to about 64%.

The composite, e.g., the first composite including the first semiconductor nanoparticle may have a transmittance for light having a wavelength of 530 nm of less than or equal to about 99%, less than or equal to about 90%, or less than or equal to about 85%.

The composite, e.g., the first composite including the first semiconductor nanoparticle may have, for example, an (one-side) external quantum efficiency as defined by the following formula, when measured in an integrating hemisphere, of greater than or equal to about 20%, greater than or equal to about 25%, greater than or equal to about 30%, greater than or equal to about 32%, greater than or equal to about 34%, greater than or equal to about 35%, greater than or equal to about 37%, greater than or equal to about 38%, greater than or equal to about 39%, or greater than or equal to about 42%:

$$External Quantum Efficiency ( EQE , \% ) = [ A / B ] \times 100$$

A: Total amount of green light from the composite, e.g., the first composite (e.g., emitted from one side)
B: Amount of the first light

The (one-side) external quantum efficiency may be less than or equal to about 50%, less than or equal to about 45%, less than or equal to about 40%, or less than or equal to about 39%. As measured in an integrating sphere, the quantum efficiency emitted from both sides of the composite may be about twice the one-side external quantum efficiency. In an embodiment, the external quantum efficiency may be less than or equal to about 100%, less than or equal to about 95%, less than or equal to about 90%, less than or equal to about 84%, less than or equal to about 80%, or less than or equal to about 78%.

The color conversion panel may further include a partition wall defining each region of the color conversion layer.

The color conversion region may further include a second region corresponding to a red pixel, a third region corresponding to a blue pixel, or a combination thereof.

An embodiment relates to a semiconductor nanoparticle composite, e.g., a first, second, or third composite (or a pattern including the same), wherein the semiconductor nanoparticle composite (e.g., first, second, or third composite) includes a matrix (e.g., a polymer matrix) and semiconductor nanoparticles, e.g., first, second, or third semiconductor nanoparticles dispersed in the matrix.

The semiconductor nanoparticle includes (e.g., a Group 11-13-16 compound including) silver, a Group 13 metal, and a chalcogen element, the Group 13 metal includes indium and gallium, the chalcogen element includes sulfur.

In the semiconductor nanoparticle, a mole ratio of gallium to indium may be greater than or equal to about 6:1 and less than or equal to about 30:1, and a mole ratio of silver to indium may be greater than or equal to about 3:1 and less than or equal to about 19:1. In an embodiment, the semiconductor nanoparticle composite has an absorbance of greater than or equal to about 80%, or greater than or equal to about 82% and less than or equal to about 97%, less than or equal to about 96.8%, less than or equal to about 95%, or less than or equal to about 94%, or less than or equal to about 91% for a first light or blue light having a wavelength of 450 nm to 465 nm.

In an embodiment, the semiconductor nanoparticle composite has a transmittance of greater than or equal to about 55%, greater than or equal to about 58%, or greater than or equal to about 64%, and less than or equal to about 100%, less than or equal to about 95%, less than or equal to about 90%, or less than or equal to about 85% for light having a wavelength of 530 nm.

The semiconductor nanoparticle composite may have an (e.g., on one side) external quantum efficiency of greater than or equal to about 29%, greater than or equal to about 31%, greater than or equal to about 33%, or greater than or equal to about 34%, and less than or equal to about 50%, less than or equal to about 45%, or less than or equal to about 40%.

The external quantum efficiency of the semiconductor nanoparticle composite may be greater than or equal to about 29%, greater than or equal to about 31%, greater than or equal to about 33%, greater than or equal to about 34%, greater than or equal to about 50%, greater than or equal to about 65%, greater than or equal to about 70%, greater than or equal to about 75%, or greater than or equal to about 80% and less than or equal to about 100%, less than or equal to about 90%, less than or equal to about 80%, less than or equal to about 70%, or less than or equal to about 60%.

The details regarding the semiconductor nanoparticle are as described herein.

The absorbance, the transmittance, and the external quantum efficiency of the composite of the semiconductor nanoparticles are as described for the first composite.

The semiconductor nanoparticle composite may further include a first organic ligand, and the first organic ligand includes a compound represented by R₁—COOA, wherein R₁ is a first organic group, and A is a hydrogen atom or a portion bound to a surface of the semiconductor nanoparticle.

The semiconductor nanoparticle may include the first organic ligand bound to a surface of the semiconductor nanoparticle.

The ink composition including the semiconductor nanoparticle may further include a second organic ligand different from the first ligand. The second organic ligand may include a compound represented by R₂S-A, wherein R₂ is a second organic group, and A is a hydrogen atom or a portion bound to a surface of the semiconductor nanoparticle.

The semiconductor nanoparticle composite, e.g., the first composite, may further include fine particles of a metal oxide.

In the semiconductor nanoparticle composite, e.g., the first composite, an amount of the semiconductor nanoparticle may be greater than or equal to about 5 weight percent (wt %) and less than or equal to about 45 wt %, or greater than or equal to about 10 wt % and less than or equal to about 25 wt %, based on a total weight of the semiconductor nanoparticle composite.

In the semiconductor nanoparticle composite, e.g., the first composite, an amount of the fine particles of the metal oxide may be greater than or equal to about 1 wt %, or greater than or equal to about 3 wt %, or greater than or equal to about 5 wt % and less than or equal to about 15 wt %, less than or equal to about 10 wt %, or less than or equal to about 8 wt %.

The semiconductor nanoparticle composite, e.g., the first composite, may have a thickness of greater than or equal to about 2 micrometers (μm), greater than or equal to about 4 μm, greater than or equal to about 6 μm, or greater than or equal to about 7 μm. The semiconductor nanoparticle composite, e.g., the first composite, may have a thickness of less than or equal to about 50 μm, less than or equal to about 30 μm, less than or equal to about 15 μm, or less than or equal to about 10 μm.

An embodiment is directed to a pattern or a wavelength-converting color filter including the semiconductor nanoparticle composite, e.g., the first composite

In an embodiment, an electronic device (or a display device) includes the color conversion panel or the display panel.

In an embodiment, the display device may be or may be included in a display device for an augmented reality/virtual reality device, a portable terminal device, a monitor, a notebook, a television, an electric display board, a camera, or a vehicle electronic component.

The semiconductor nanoparticle composite, e.g., the first composite, according to an embodiment may provide a display panel implementing enhanced luminance and display quality. The display panel according to an embodiment may exhibit increased emission efficiency and increased luminance, and may provide enhanced display quality.

### BRIEF DESCRIPTION OF THE DRAWINGS

FIG. 1A is a perspective view illustrating an example of a display panel including a color conversion panel according to an embodiment.

FIG. 1B is a cross-sectional view of the display panel of FIG. 1A.

FIG. 2 is a plan view illustrating an example of a pixel array of the display panel of FIG. 1A.

FIG. 3A is a schematic cross-sectional view of a display panel according to an embodiment.

FIG. 3B is a schematic cross-sectional view of a display panel according to an embodiment.

FIG. 3C and FIG. 3D are schematic cross-sectional views of a display panel according to an embodiment.

FIG. 3E is a schematic cross-sectional view of a display panel according to an embodiment.

FIG. 3F is a schematic cross-sectional view of a light emitting panel according to an embodiment.

FIG. 4A is a cross-sectional view of a light-emitting device included in a light-emitting panel according to an embodiment.

FIG. 4B is a cross-sectional view of a light-emitting device included in a light-emitting panel according to an embodiment.

FIG. 4C is a cross-sectional view of a light-emitting device included in a light-emitting panel according to an embodiment.

FIG. 4D is a cross-sectional view of a light-emitting device included in a light-emitting panel according to an embodiment.

FIG. 5 is a schematic cross-sectional view of a color conversion panel included in a display panel according to an embodiment.

FIG. 6 schematically illustrates a pattern formation process (inkjet printing method) using an ink composition of an embodiment.

FIG. 7 illustrates changes in absorbance (percent, %) of a semiconductor nanoparticle composite according to wavelength (nanometers, nm) and an electroluminescence spectrum of a light-emitting device.

FIG. 8 illustrates a graph showing absorbance at 350 nanometers according to wavelength (nanometers, nm) of UV-Vis absorption spectra of semiconductor nanoparticles synthesized in Reference Examples 1 to 5 and the electroluminescence spectrum of light-emitting devices.

### DETAILED DESCRIPTION

Advantages and features of the techniques described hereinafter, and methods of achieving them, will become apparent with reference to the exemplary embodiments described below in further detail in conjunction with the accompanying drawings. However, the embodiments should not be construed as being limited to the exemplary embodiments set forth herein. If not defined otherwise, all terms (including technical and scientific terms) as used herein may be defined as commonly understood by one having ordinary skill in the art. The terms defined in a generally-used dictionary may not be interpreted ideally or exaggeratedly unless clearly defined. In addition, unless explicitly described to the contrary, the word “comprise” and variations such as “comprises” or “comprising,” will be understood to imply the inclusion of stated elements but not the exclusion of any other elements.

In the drawings, the thickness of layers, films, panels, regions, etc., are exaggerated for clarity. Like reference numerals designate like elements throughout the specification.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

As used herein, the singular forms “a,” “an,” and “the” are intended to include the plural forms, including “at least one,” unless the context clearly indicates otherwise. For example, the wording “semiconductor nanoparticle” may refer to a single semiconductor nanoparticle or may refer to a plurality of semiconductor nanoparticles. “At least one” is not to be construed as being limited to “a” or “an.” “Or” means “and/or.” As used herein, the term “and/or” includes any and all combinations of one or more of the associated listed items.

It will be understood that, although the terms “first,” “second,” “third” etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, “a first element,” “component,” “region,” “layer”, or “section” discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, ±5%, or ±3% of the stated value.

As used herein, the expression “not including cadmium (or other harmful heavy metal)” may refer to the case in which a concentration of cadmium (or other harmful heavy metal) may be less than or equal to about 100 parts per million by weight (ppmw), less than or equal to about 50 ppmw, less than or equal to about 10 ppmw, less than or equal to about 1 ppmw, less than or equal to about 0.1 ppmw, less than or equal to about 0.01 ppmw, or about zero. In one or more embodiments, substantially no amount of cadmium (or other harmful heavy metal) may be present or, if present, an amount of cadmium (or other harmful heavy metal) may be less than or equal to a detection limit or as an impurity level of a given analysis tool.

Hereinafter, as used herein, when a definition is not otherwise provided, “substituted” refers to replacement of at least one hydrogen of a compound by a substituent such as a C1 to C30 alkyl group, a C2 to C30 alkenyl group, a C2 to C30 alkynyl group, a C6 to C30 aryl group, a C7 to C30 alkylaryl group, a C7 to C30 arylalkyl group, a C6 to C30 aryloxy group, a C6 to C30 arylthio group, a C1 to C30 alkoxy group, a C1 to C30 alkylthio group, a C1 to C30 heteroalkyl group, a C3 to C30 heteroalkylaryl group, a C2 to C30 alkylheteroaryl group, a C2 to C30 heteroarylalkyl group, a C1 to C30 heteroaryloxy group, a C1 to C30 heteroarylthio group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group or an amine group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation, a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof. The specified number or range of carbon atoms in a group is exclusive of any substituents.

In addition, when a definition is not otherwise provided below, “hetero” means a case including 1 to 3 heteroatoms such as N, O, P, Si, S, Se, Ge, or B.

In addition, the term “aliphatic hydrocarbon group” as used herein refers to a C1 to C30 linear or branched alkyl group, a C2 to C30 linear or branched alkenyl group, or a C2 to C30 linear or branched alkynyl group, and the term “aromatic organic group” as used herein refers to a C6 to C30 aryl group or a C2 to C30 heteroaryl group.

As used herein, the term “(meth)acrylate” refers to acrylate and/or methacrylate.

As used herein, the term “Group” refers to a Group of Periodic Table.

As used herein, the terms “a nanoparticle” and “a nanostructure” refer to a structure having at least one region or characteristic dimension with a nanoscale dimension. In one or more embodiments, the dimension of the nanoparticle or the nanostructure may be less than about 500 nm, less than about 300 nm, less than about 250 nm, less than about 150 nm, less than about 100 nm, less than about 50 nm, or less than about 30 nm. The nanoparticle or nanostructure may have any shape, such as a nanowire, a nanorod, a nanotube, a multi-pod type shape having two or more pods, a nanodot, or the like, but embodiments are not limited thereto. The nanoparticle or nanostructure may be, for example, substantially crystalline, substantially monocrystalline, polycrystalline, amorphous, or a combination thereof.

A quantum dot may be, for example, a semiconductor-containing nanocrystal particle that can exhibit a quantum confinement or exciton confinement effect, and is a type of a luminescent nanostructure (e.g., capable of emitting light by energy excitation). Herein, a shape of the “quantum dot” or the nanoparticle is not limited unless otherwise expressly defined.

As used herein, the term “dispersion” refers to a dispersion in which a dispersed phase is a solid, and a continuous medium includes a liquid or a solid different from the dispersed phase. It is to be understood that the “dispersion” may be a colloidal dispersion in which the dispersed phase has a dimension of greater than or equal to about 1 nm, for example, greater than or equal to about 2 nm, greater than or equal to about 3 nm, or greater than or equal to about 4 nm and less than or equal to several micrometers (μm), (e.g., less than or equal to about 2 μm, less than or equal to about 1 μm, less than or equal to about 900 nm, less than or equal to about 800 nm, less than or equal to about 700 nm, less than or equal to about 600 nm, or less than or equal to about 500 nm).

Herein, a dimension (a size, a diameter, or a thickness, etc.) may be a value for a single entity or an average value for a plurality of nanoparticles. As used herein, the term “average” (e.g., an average size of the quantum dot) may be a mean value or a median value. In one or more embodiments, the average may be “mean” average.

As used herein, the term “peak emission wavelength” is the wavelength at which a given emission spectrum of the light reaches its maximum.

In one or more embodiments, a quantum efficiency may be readily and reproducibly determined using commercially available equipment (e.g., from Hitachi or Hamamatsu, etc.) and referring to manuals provided by, for example, respective equipment manufacturers. The quantum efficiency (which can be interchangeably used with the term “quantum yield” (QY)) may be measured in a solution state or a solid state (i.e., in a composite). In one or more embodiments, the quantum efficiency (or the quantum yield) is the ratio of photons emitted to photons absorbed by the nanostructure or population thereof. In one or more embodiments, the quantum efficiency may be measured by any method. For example, there may be two methods for measuring the fluorescence quantum yield or efficiency: the absolute method and the relative method. The quantum efficiency measured by the absolute method may be referred to as an absolute quantum efficiency.

In the absolute method, the quantum efficiency may be obtained by detecting the fluorescence of all samples through an integrating sphere. In the relative method, the quantum efficiency of the unknown sample may be calculated by comparing the fluorescence intensity of a standard dye (a standard sample) with the fluorescence intensity of the unknown sample. Coumarin 153, Coumarin 545, Rhodamine 101 inner salt, Anthracene and Rhodamine 6G may be used as standard dyes according to their photoluminescence (PL) wavelengths, but embodiments are not limited thereto.

As used herein, a (%) light transmittance refers to a fraction (or percentage) of transmitted light or incident light. It is the amount of light that passes through a given material or substance and emerges on the other side. The light transmittance may be defined as follows:

$$\% T = 100 \times ( I / Io )$$

where l is an amount of the transmitted light, and lo is an amount of the incident light.

The light transmittance may be easily and reproducibly determined using commercially available equipment, for example, by referring to manuals provided by each equipment manufacturer.

A semiconductor nanoparticle may be included in a variety of electronic devices. An electrical and/or an optical property of the semiconductor nanoparticle may be controlled for example, by the elemental composition of the semiconductor nanoparticle, the size of the semiconductor nanoparticle, and/or the shape of the semiconductor nanoparticle. In one or more embodiments, the semiconductor nanoparticle may be a semiconductor nanocrystal particle. The semiconductor nanoparticle such as a quantum dot may have a relatively large surface area per a unit volume, and thus, may exhibit a quantum confinement effect, exhibiting physical optical properties different from a corresponding bulk material having the same composition. Therefore, a semiconductor nanoparticle such as a quantum dot may absorb energy (e.g., incident light) supplied from an excitation source to form an excited state, which upon relaxation is capable of emitting an energy corresponding to its energy bandgap.

The semiconductor nanoparticle may also be used in a color conversion panel (e.g., a photoluminescent color filter). In a display device including a quantum dot-containing color conversion panel or a luminescent type color filter, a quantum dot layer is used as a luminescent material and is disposed in a relatively front part of a device to convert an incident light (e.g., a blue light) provided from a light source to light of a different spectrum (for example, a green light or a red light). In such a color conversion panel, the color conversion of the excitation light may occur in a relatively front part of the device, the light may be scattered in all directions, which may address a viewing angle problem of the liquid crystal display, and a light loss problem caused by using an absorption type color filter may be addressed as well. As used herein, the term “color conversion panel” refers to an electronic device including a color conversion layer (or a color conversion structure),

The display panel of an embodiment may include a light-emitting panel that emits incident light (or mixed incident light) including, for example, first light and second light.

The light-emitting panel may have, for example, a tandem structure in which a plurality of emission layers are stacked. In the display panel of an embodiment, the light-emitting panel may employ a tandem structure (for example, including a green light-emitting layer or a green phosphorescent layer as inserted) and may emit mixed light including green light and blue light. Together with the light-emitting panel that emits mixed incident light, the display panel of an embodiment includes a color conversion panel as described herein (for example, a color conversion panel including a semiconductor nanoparticle composite including a silver-indium-gallium-sulfur containing semiconductor nanoparticle and having controlled absorbance/transmittance). Such a color conversion panel may exhibit improved optical properties (e.g., increased quantum efficiency, luminance, etc.) when used with the light-emitting panel.

In the display panel of an embodiment, a green pixel is configured to extract green incident light out of the panel with increased luminance.

In an embodiment, the display panel includes:
a light-emitting panel; and
a color conversion panel facing the light-emitting panel,
wherein the light-emitting panel includes a light-emitting device configured to emit incident light including first light and second light,
a maximum peak emission wavelength of the first light exists in a range of greater than or equal to about 440 nm and less than or equal to about 480 nm,
a maximum peak emission wavelength of the second light exists in a range of greater than or equal to about 500 nm and less than or equal to about 580 nm,
the color conversion panel includes a color conversion layer including a color conversion region,
the color conversion region includes a first region corresponding to a green pixel,
the first region includes a first composite including a matrix and semiconductor nanoparticles dispersed in the matrix,
the semiconductor nanoparticles include a Group 11-13-16 compound including silver, a Group 13 metal, and a chalcogen element,
the Group 13 metal includes indium and gallium,
the chalcogen element includes sulfur.

In the semiconductor nanoparticles, a mole ratio of gallium to indium may be greater than or equal to about 6:1 and less than or equal to about 30:1, and a mole ratio of silver to indium may be greater than or equal to about 3:1 and less than or equal to about 19:1. In an embodiment, the first composite exhibits an absorbance of greater than or equal to about 80% for the first light, and the first composite shows a transmittance of greater than or equal to about 55% for light having a wavelength of 530 nm. In an embodiment, the composite exhibits an absorbance greater than or equal to about 80% and less than or equal to about 99% for the first light, and a transmittance greater than or equal to about 55% and less than or equal to about 99% for light having a wavelength of 530 nanometers.

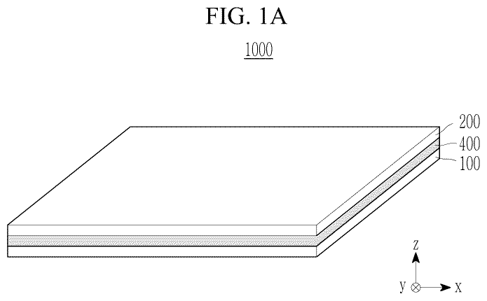

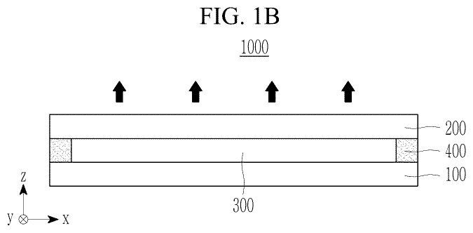

Hereinafter, the display panel and the color conversion panel will be described in further detail with reference to the drawings. Referring to FIGS. 1A and 1B, the display panel 1000 according to an embodiment may include a light emitting panel 100 and a color conversion panel 200. The display panel 1000 or the electronic device may further include a light transmitting layer 300 disposed between the light emitting panel 100 and the color conversion panel 200, and a binding material 400 binding the light emitting panel 100 and the color conversion panel 200.

The light emitting panel 100 and the color conversion panel 200 each may have a surface opposite the other, i.e., the two respective panels may face each other, with the light transmitting layer (or the light transmitting panel) disposed between the two panels. The color conversion panel 200 may be disposed in a direction such that for example, light emitting from the light emitting panel 100 may irradiate the light transmitting layer 300. The binding material 400 may be disposed along edges of the light emitting panel 100 and the color conversion panel 200, and may be, for example, a sealing material.

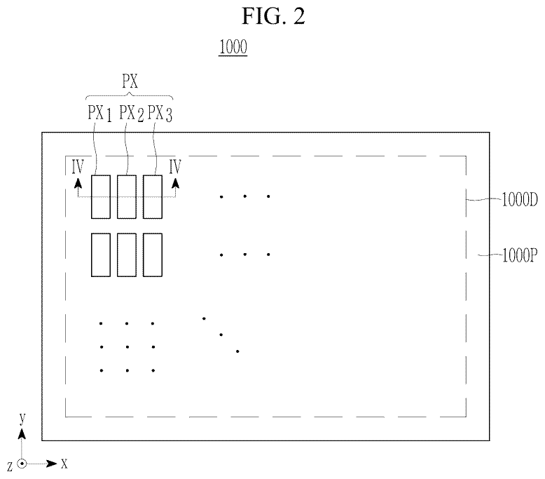

FIG. 2 is a plan view of an embodiment of a pixel arrangement of a display panel. Referring to FIG. 2, the display panel 1000 may include a display area 1000D displaying an image and a non-display area 1000P positioned in a peripheral area of the display area 1000D and disposed with a binding material.

The display area 1000D may include a plurality of pixels PX arranged along a row (e.g., an x direction), and a column (e.g., a y direction), and each representative pixel PX may include a plurality of sub-pixels PX₁, PX₂, and PX₃ expressing, e.g., displaying, different colors from each other. An embodiment may be idealized with a structure in which three sub-pixels PX₁, PX₂, and PX₃ are configured to provide a pixel. An embodiment may further include an additional sub-pixel, such as a white sub-pixel, and may further include, e.g., at least one, sub-pixel expressing, e.g., displaying the same colors. The plurality of pixels PX may be aligned, for example, in a Bayer matrix, a matrix sold under the trade designation PenTile, a diamond matrix, or the like, or a combination thereof.

The sub-pixels PX₁, PX₂, and PX₃ may express, e.g., display, three primary colors or a color of a combination of three primary colors, for example, may express, e.g., display, a color of red, green, blue, or a combination thereof. For example, the first sub-pixel PX₁ may express, e.g., display, a red color, and the second sub-pixel PX₂ may express, e.g., display, a green color, and the third sub-pixel PX₃ may express, e.g., display, a blue color.

In the drawing, all sub-pixels are idealized to have the same size, but these are not limited thereto, and at least one of the sub-pixels may be larger or smaller than other sub-pixels. In the drawing, all sub-pixels are idealized to have the same shape, but it is not limited thereto and at least one of the sub-pixels may have different shape from the other sub-pixels.

In the display panel of an embodiment, a light-emitting panel 100 may emit incident light (e.g., mixed incident light) including first light (e.g., blue light) and second light (e.g., green light). The light-emitting panel 100 may not emit red light (e.g., light having a wavelength of greater than or equal to about 600 nm to about 680 nm).

A peak emission wavelength of the first light may exist at greater than or equal to about 440 nm, greater than or equal to about 445 nm, greater than or equal to about 450 nm, greater than or equal to about 455 nm, or greater than or equal to about 460 nm. The peak emission wavelength of the first light may exist at less than or equal to about 480 nm, for example, less than or equal to about 475 nm, less than or equal to about 470 nm, or less than or equal to about 465 nm. A peak emission wavelength of the second light may exist at greater than or equal to about 500 nm, greater than or equal to about 505 nm, greater than or equal to about 510 nm, or greater than or equal to about 515 nm. A maximum peak emission wavelength of the second light may exist at less than or equal to about 580 nm, less than or equal to about 575 nm, less than or equal to about 570 nm, less than or equal to about 565 nm, less than or equal to about 560 nm, less than or equal to about 550 nm, less than or equal to about 540 nm, less than or equal to about 535 nm, or less than or equal to about 530 nm.

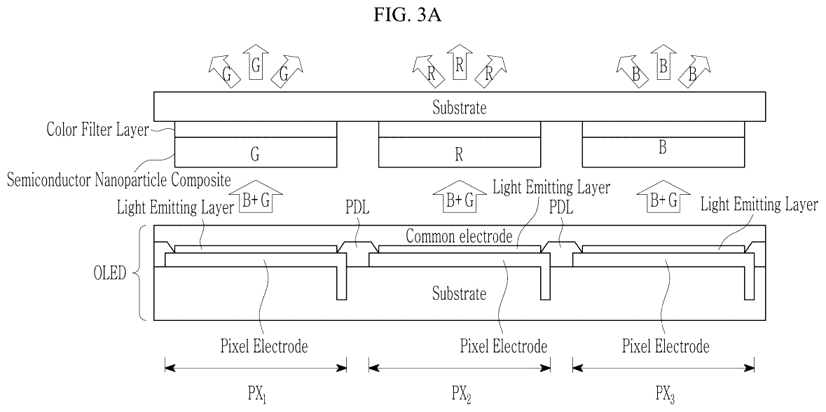

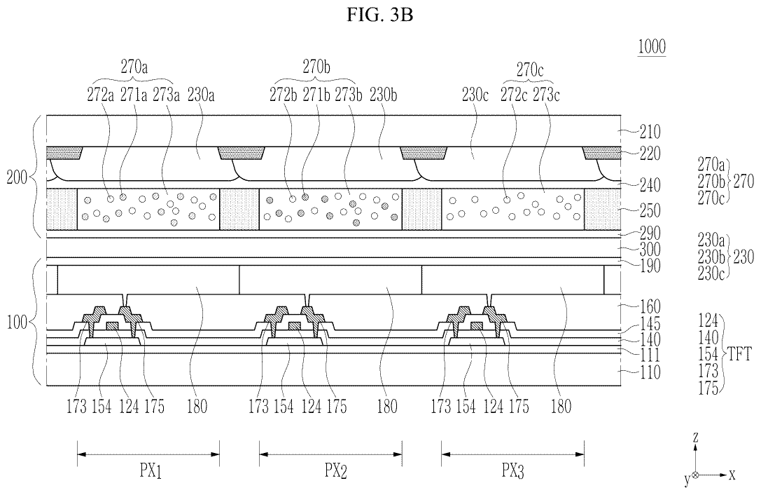

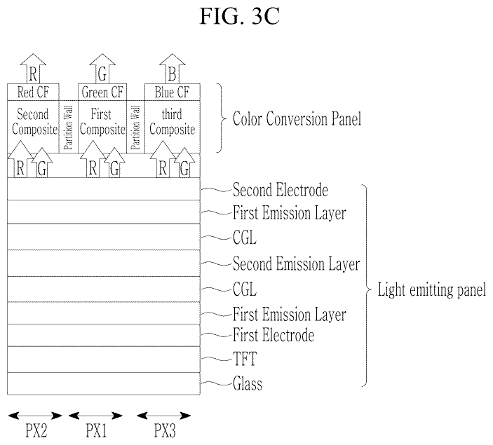

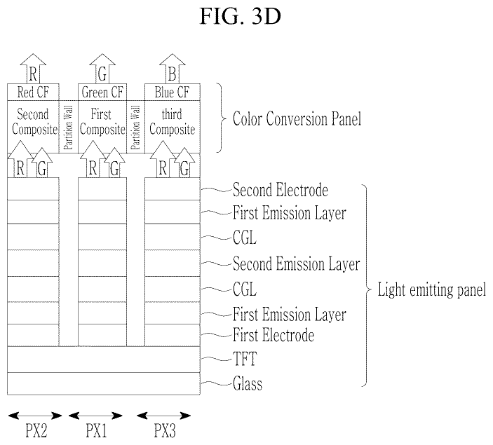

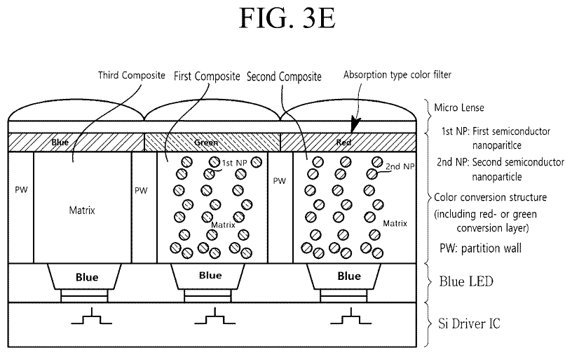

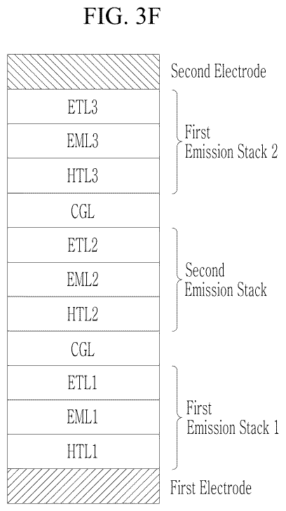

Hereinafter, a display panel including a light-emitting panel 100 and a color conversion panel 200 will be described in more detail with reference to FIGS. 3A, 3B, 3C, and 3D.

FIG. 3A illustrates a schematic cross-sectional view of a device (or a display panel) according to an embodiment. Referring to FIG. 3A, a light source (or light-emitting panel) may include an organic light-emitting diode that emits blue light (and optionally green light). The organic light-emitting diode may include two or more pixel electrodes formed on a substrate, a pixel defining layer formed between adjacent pixel electrodes, an organic emission layer formed on each pixel electrode, and a common electrode layer formed on the organic emission layer. A thin-film transistor and a substrate may be disposed below the organic light-emitting diode. A pixel region of the OLED may be disposed corresponding to first, second, and third regions described below. In FIG. 3A, the color conversion panel and the light-emitting panel are illustrated as being separated, but the color conversion panel may be laminated directly on the light-emitting panel.

A color conversion layer (or a stacked structure including the same) including a semiconductor nanoparticle composite or a pattern thereof may be disposed on the light-emitting panel. The color conversion layer may include a first region corresponding to a green pixel. The color conversion layer may further include a second region corresponding to a red pixel. The first region may include a green light-emitting semiconductor nanoparticle. The second region may include a red light-emitting semiconductor nanoparticle. A substrate may be disposed on the color conversion layer. An Incident light (B+G, i.e., incident light including the first light and the second light) emitted from the light-emitting panel or the light-emitting device may be incident on the first region and the second region and configured to emit green and red light, respectively. Among the incident light emitted from the light-emitting device, the first light or a blue light may pass through the third region. An element (a first optical element or an incident light blocking layer) that blocks the incident light or a portion thereof may be disposed between the nanoparticle composite layer (R, G) and the substrate, if desired. When the incident light includes blue light and green light, a green light blocking filter may be further included in the third region. The first optical element or the incident light blocking layer will be described in more detail below. Such a device may be manufactured by separately preparing the above-described color conversion panel and the light-emitting panel (e.g., emitting blue light and green light) and then combining them. Alternatively, the device may be manufactured by directly forming a pattern of the nanoparticle composite on the light-emitting panel.

In the color conversion panel or the display panel of an embodiment, a substrate may be a substrate including an insulating material. The substrate may be an inorganic material substrate (e.g., a glass substrate) or an organic material substrate (e.g., a polymer substrate). In an embodiment, the substrate may be a polymer substrate. The substrate may include, but is not limited to, a polymer such as glass; polyesters such as polyethylene terephthalate (PET) and polyethylene naphthalate (PEN); polyimide; polyamide; polyamide-imide; polycarbonate; polymethyl methacrylate; polyacrylate; copolymers thereof; or combinations thereof; a polysiloxane (e.g., PDMS); an inorganic material such as Al₂O₃ and ZnO; or combinations thereof. The thickness of the substrate may be appropriately selected in consideration of the substrate material and the like and is not particularly limited. The substrate may be flexible. The (upper) substrate may be configured to have a transmittance of greater than or equal to about 50%, greater than or equal to about 60%, greater than or equal to about 70%, greater than or equal to about 80%, or greater than or equal to about 90% for light emitted from the semiconductor nanoparticle.

A wiring layer including a thin-film transistor or the like may be formed on the substrate (e.g., a lower substrate). The wiring layer may further include a gate line, a storage voltage line, a gate insulating layer, a data line, a source electrode, a drain electrode, a semiconductor, and a passivation layer. The detailed structure of the wiring layer may vary depending on an embodiment. The gate line and the storage voltage line are electrically separated from each other, and the data line crosses the gate line and the storage voltage line with insulation therebetween. The gate electrode, the source electrode, and the drain electrode may constitute a control terminal, an input terminal, and an output terminal of the thin-film transistor, respectively. The drain electrode may be electrically connected to a pixel electrode described below.

A pixel electrode may function as an electrode (e.g., an anode) of the display device. The pixel electrode may be formed of a transparent conductive material such as indium tin oxide (ITO) or indium zinc oxide (IZO). The pixel electrode may include (e.g., may be formed of) a light-shielding material such as gold (Au), platinum (Pt), nickel (Ni), tungsten (W), chromium (Cr), molybdenum (Mo), iron (Fe), cobalt (Co), copper (Cu), palladium (Pd), or titanium (Ti). The pixel electrode may have a two-layer structure in which the transparent conductive material and the light-shielding material are sequentially stacked.

Between two adjacent pixel electrodes, a pixel define layer (PDL) that overlaps with an end of the pixel electrode and separates the pixel electrodes on a pixel-by-pixel basis may be formed. The pixel define layer, as an insulating layer, may electrically insulate the two or more pixel electrodes.

The pixel define layer may cover only a portion of an upper surface of the pixel electrode, and the remaining portion of the pixel electrode not covered by the pixel define layer may form an opening. An organic emission layer, which will be described below, may be formed on the region defined by the opening.

The organic emission layer may be defined into individual pixel regions by the pixel electrode and the pixel define layer. That is, a region where one organic light-emitting unit layer is formed in contact with one pixel electrode separated by the pixel define layer may be defined as one pixel region. In the display device according to an embodiment, the organic emission layer may be defined into a first pixel region, a second pixel region, and a third pixel region, and each pixel region may be spaced apart at a predetermined distance by the pixel define layer.

An emission layer (e.g., an organic emission layer) may be configured to emit incident light belonging to a visible light region or a UV region. Each of the first to third pixel regions of the emission layer may emit light of the same color. In an embodiment, the emission layer may be configured to emit first light (e.g., blue light) and second light (e.g., green light). When each pixel region of the emission layer is designed to emit the same light, each pixel region of the emission layer may be formed of the same or similar material, or may exhibit the same or similar physical property. In this case, the formation of the emission layer may be facilitated, and a large-scale or large-area process of the display device may also be facilitated. In an embodiment, at least one of the pixel regions of the emission layer (or the organic emission layer) may be configured to emit light different from that of an adjacent region.

The emission layer (e.g., the organic emission layer) may include an emission layer unit (e.g., an organic light-emitting layer unit) for each pixel region, and each emission layer unit may further include an additional layer (e.g., a hole injection layer, a hole transport layer, an electron transport layer, etc.) in addition to the emission layer.

A common electrode may function as a cathode of the display device.

The common electrode may be formed of a transparent conductive material such as indium tin oxide (ITO) or indium zinc oxide (IZO). The common electrode may be integrally formed on the organic emission layer. A planarization layer or a passivation layer (not shown) may be formed on the common electrode. The planarization layer may include an (e.g., transparent) insulating material to secure electrical insulation with respect to the common electrode.

Referring to FIG. 3B, a light-emitting panel 100 may include a light-emitting device that emits light in a predetermined wavelength region and a circuit element for switching and/or driving the light-emitting device. The light-emitting panel 100 of an embodiment may include a lower substrate 110, a buffer layer 111, a thin-film transistor (TFT), a light-emitting device 180, and optionally an encapsulation layer 190.

The lower substrate 110 is as described herein with respect to the substrate. The buffer layer 111 may include an organic material, an inorganic material, or an organic-inorganic material, and may include, for example, an oxide, a nitride, or an oxynitride, and specifically may include silicon oxide, silicon nitride, silicon oxynitride, or combinations thereof, but is not limited thereto. The buffer layer 111 may have one or more layers and may cover the entire surface of the lower substrate 110. The buffer layer 111 may be omitted.

The thin-film transistor TFT may be a three-terminal device for switching and/or driving the light-emitting device 180, which will be described below, and one or two or more TFTs may be included per subpixel. The thin-film transistor (TFT) includes a gate electrode 124, a semiconductor layer 154 overlapping the gate electrode 124, a gate insulating layer 140 positioned between the gate electrode 124 and the semiconductor layer 154, and a source electrode 173 and a drain electrode 175 electrically connected to the semiconductor layer 154. In the drawing, a coplanar top gate structure is illustrated as an example, but the structure is not limited thereto and may have various configurations.

The gate electrode 124 can be electrically connected to a gate line (not shown) and may include a low-resistance metal such as aluminum (Al), molybdenum (Mo), copper (Cu), titanium (Ti), silver (Ag), gold (Au), an alloy thereof, or a combination thereof, but is not limited thereto.

The semiconductor layer 154 may be an inorganic semiconductor such as amorphous silicon, polycrystalline silicon, or an oxide semiconductor; an organic semiconductor; an organic-inorganic semiconductor; or a combination thereof. For example, the semiconductor layer 154 may include an oxide semiconductor including at least one of indium (In), zinc (Zn), tin (Sn), and gallium (Ga), and the oxide semiconductor may include, for example, indium-gallium-zinc oxide, zinc-tin oxide, or a combination thereof, but is not limited thereto. The semiconductor layer 154 may include a channel region and a doped region disposed on both sides of the channel region, which are electrically connected to the source electrode 173 and the drain electrode 175, respectively.

The gate insulating layer 140 may include an organic material, an inorganic material, or an organic-inorganic material, and may include, for example, an oxide, a nitride, or an oxynitride, and specifically may include a silicon oxide, a silicon nitride, a silicon oxynitride, or combinations thereof, but is not limited thereto. In the drawing, an example is illustrated in which the gate insulating layer 140 is formed over the entire surface of the lower substrate 110, but it is not limited thereto and the gate insulating layer 140 may be selectively formed between the gate electrode 124 and the semiconductor layer 154. The gate insulating layer 140 may have one layer or two or more layers.

The source electrode 173 and the drain electrode 175 may include a low-resistance metal such as aluminum (Al), molybdenum (Mo), copper (Cu), titanium (Ti), silver (Ag), gold (Au), an alloy thereof, or a combination thereof, but are not limited thereto. The source electrode 173 and the drain electrode 175 may be electrically connected to doped regions of the semiconductor layer 154, respectively. The source electrode 173 may be electrically connected to a data line (not shown), and the drain electrode 175 may be electrically connected to a light-emitting device 180, which will be described below.

An interlayer insulating layer 145 may be further formed between the gate electrode 124 and the source/drain electrodes 173 and 175. The interlayer insulating layer 145 may include an organic material, an inorganic material, or an organic-inorganic material, and may include, for example, an oxide, a nitride, or an oxynitride, and specifically may include silicon oxide, silicon nitride, silicon oxynitride, or combinations thereof, but is not limited thereto. The interlayer insulating layer 145 may have one layer or two or more layers.

A protective layer 160 may be formed on the thin-film transistor (TFT). The protective layer 160 may be, for example, a passivation layer. The protective layer 160 may include an organic material, an inorganic material, or an organic-inorganic material, and may include, for example, polyacryl, polyimide, polyamide, polyamide-imide, or combinations thereof, but is not limited thereto. The protective layer 160 may have one layer or two or more layers.

In the light-emitting panel of an embodiment, a light-emitting device 180 may be disposed for each subpixel (PX₁, PX₂, PX₃). The light-emitting device 180 disposed in each subpixel (PX₁, PX₂, PX₃) may be driven independently. The light-emitting device 180 may be, for example, a light-emitting diode. The light-emitting device 180 may be an electroluminescent device. The light-emitting device 180 may be a micro LED. The light-emitting device 180 may be an inorganic nano light-emitting diode or a QD-NED device including the same. The light-emitting device 180 may include a pair of electrodes and an emission layer disposed between the pair of electrodes.

The light emitting device 180 or the emission layer may include a luminescent material capable of emitting light in a predetermined wavelength region, and may include a luminescent material that emits light of a first emission spectrum belonging to the visible light wavelength spectrum. The luminescent material may include an organic luminescent material, an inorganic luminescent material, an organic-inorganic luminescent material, or a combination thereof, and may be one or two or more kinds.

The light emitting device 180 may be, for example, an organic light emitting diode, an inorganic light emitting diode, or a combination thereof. The inorganic light emitting diode may include, for example, a quantum dot light emitting diode, a perovskite light emitting diode, a micro light emitting diode, an inorganic nano light emitting diode, or a combination thereof, but is not limited thereto.

Referring to FIGS. 3C and 3D schematically illustrating a display panel of an embodiment, a light emitting panel may have a structure in which an oxide-based TFT is disposed on a substrate, and a light emitting device having a tandem structure may be disposed on the TFT. The light emitting device may include a first emission layer or a first emission stack (e.g., a blue emission layer or stack or a green emission layer or stack), a second emission layer or a second emission stack (e.g., a green emission layer or stack or a blue emission layer or stack), and optionally another first emission layer or another first emission stack (e.g., a blue emission layer or stack or a green emission layer or stack) between a first electrode and a second electrode that face each other, and, if desired, a charge generation layer (CGL) may be disposed or may not be disposed between the respective emission layers (e.g., emission stacks). In FIG. 3C, the first electrode and the second electrode are illustrated in an unpatterned form, but they may each be patterned into a plurality of electrode elements corresponding to pixels (see FIG. 3D). The first electrode may be an anode or a cathode. The second electrode may be a cathode or an anode. The first emission stack and the second emission stack may include an emission layer and a charge auxiliary layer. In an embodiment, the first (or second) emission stack may have a structure of a hole transport layer/a first (or second) emission layer/an electron transport layer.

In an embodiment, the first emission layer and the second emission layer in FIGS. 3C and 3D may each include a first emission stack and a second emission stack. In an embodiment, the first emission stack may include a hole auxiliary layer/a green emission layer/an electron auxiliary layer. In an embodiment, the second emission stack may include a hole auxiliary layer/a blue emission layer/an electron auxiliary layer. In an embodiment, the first emission stack may include a hole auxiliary layer/a blue emission layer/an electron auxiliary layer. In an embodiment, the second emission stack may include a hole auxiliary layer/a green emission layer/an electron auxiliary layer.

In an embodiment of a light emitting panel, for example, referring to FIG. 3F, the first emission stack may include a hole auxiliary layer (e.g., HTL1)/a (blue or green) emission layer (EML1)/an electron auxiliary layer (e.g., ETL1) (first emission stack 1) and a hole auxiliary layer (e.g., HTL3)/a (blue or green) emission layer (EML3)/an electron auxiliary layer (e.g., ETL3) (first emission stack 2), where HTL1 may be present between the first electrode and the emission layer (EML1), and ETL3 may be disposed between EML3 and the second electrode. In an embodiment, the second emission stack may be disposed between the first emission stack 1 and the first emission stack 2 and may include a hole auxiliary layer (e.g., HTL2)/a (green or blue) emission layer (EML2)/an electron auxiliary layer (e.g., ETL3). A CGL may be disposed between the first emission stack and the second emission stack (for example, between ETL1 and HTL2, and between ETL2 and HTL3). In FIGS. 3C and 3D, a charge auxiliary layer (e.g., a hole auxiliary layer or an electron auxiliary layer) may be disposed or may not be disposed, if desired, between the first emission layer and the charge generation layer (CGL) or between the second emission layer and the charge generation layer (CGL). The hole auxiliary layer may include a hole injection layer, a hole transport layer, an electron blocking layer, or a combination thereof, but is not limited thereto. The electron auxiliary layer may include an electron injection layer, an electron transport layer, a hole blocking layer, or a combination thereof, but is not limited thereto.

Referring to FIG. 3E schematically illustrating a display panel of an embodiment, a circuit (Si driver integrated circuit (IC)) for driving a light source (e.g., an LED, an OLED, a micro LED, an inorganic nanorod, or a combination thereof) configured to emit an incident light (for example, a blue light and/or a green light)) may be disposed below the light source. The color conversion layer may include a first composite including a semiconductor nanoparticle (a first NP) that emits first light (for example, green light), and an additional composite that emits light, e.g., a second composite including a semiconductor nanoparticle (a second NP) that emits second light (red light), or a third composite that emits or transmits third light (for example, incident light or blue light). A partition wall PW (for example, based on an inorganic material such as silicon or silicon oxide, or based on an organic material) may be disposed between the composites. The partition wall may include a trench hole, a via hole, or a combination thereof. On the light extraction surface of the color conversion layer, a first optical element (for example, a color filter, a blue filter, a green filter, or a red filter that blocks light other than light of a predetermined color) may be disposed. An additional optical element, such as a microlens, may be further disposed on the first optical element.

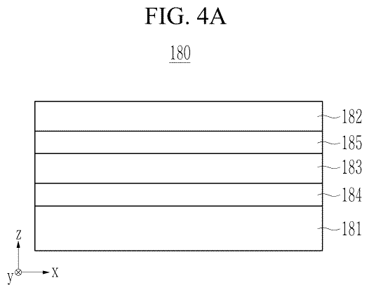

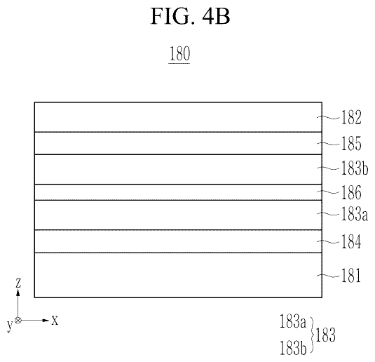

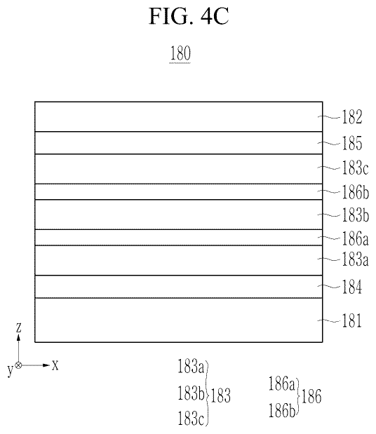

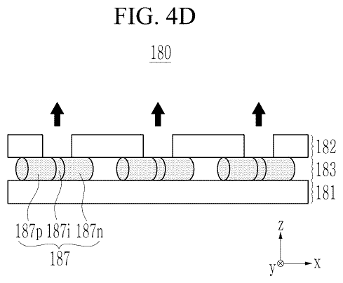

FIGS. 4A to 4E are cross-sectional views showing light emitting devices of an embodiment, respectively.

Referring to FIG. 4A, the light emitting device 180 may include a first electrode 181 and a second electrode 182 facing each other; a light emitting layer 183 located between the first electrode 181 and the second electrode 182; and optionally auxiliary layers 184 and 185 located between the first electrode 181 and the light emitting layer (or the emission layer) 183, and located between the second electrode 182 and the light emitting layer 183, respectively.

The first electrode 181 and the second electrode 182 may be disposed to face each other along a thickness direction (for example, a z direction), and any one of the first electrode 181 and the second electrode 182 may be an anode and the other may be a cathode. The first electrode 181 may be a light transmitting electrode, a semi-transparent electrode, or a reflective electrode, and the second electrode 182 may be a light transmitting electrode or a semi-transparent electrode. The light transmitting electrode or semi-transparent electrode may be, for example, made of a thin single layer or multiple layers of a metal thin film including conductive metal oxides, such as indium tin oxide (ITO), indium zinc oxide (IZO), zinc oxide (ZnO), tin oxide (SnO), aluminum tin oxide (AlTO), fluorine-doped tin oxide (FTO), or the like; or silver (Ag), copper (Cu), aluminum (Al), magnesium (Mg), magnesium-silver (Mg—Ag), magnesium-aluminum (Mg—Al), or a combination thereof. The reflective electrode may include a metal, a metal nitride, or a combination thereof, for example, silver (Ag), copper (Cu), aluminum (Al), gold (Au), titanium (Ti), chromium (Cr), nickel (Ni), an alloy thereof, a nitride thereof (e.g., TiN), or a combination thereof, but embodiments are not limited thereto.

The emission layer 183 may include a first luminescent material (body) capable of emitting light of a first emission spectrum (or first light) and a second luminescent material (body) capable of emitting light of a second emission spectrum (or second light). The first emission spectrum may be a blue emission spectrum. The second emission spectrum may be a green emission spectrum.

The blue emission spectrum or the first light may have a peak emission wavelength of greater than or equal to about 400 nm to less than about 500 nm and within the range, in a wavelength region of about 410 nm to about 490 nm, about 420 nm to about 480 nm, about 430 nm to about 470 nm, about 440 nm to about 465 nm, about 445 nm to about 460 nm, or about 450 nm to about 458 nm. In an embodiment, the light of the blue emission spectrum or the first light may have a peak emission wavelength of greater than or equal to about 400 nm and less than about 500 nm, about 410 nm to about 490 nm, about 420 nm to about 480 nm, about 430 nm to about 475 nm, about 440 nm to about 460 nm, about 445 nm to about 458 nm, or about 450 nm to about 455 nm.

A green emission spectrum or a second light may have a peak emission wavelength of greater than or equal to about 500 nm and less than about 590 nm, and within the above range, may belong to a wavelength region of about 510 nm to about 580 nm, about 515 nm to about 570 nm, about 520 nm to about 560 nm, about 525 nm to about 555 nm, about 530 nm to about 550 nm, about 535 nm to about 545 nm, or a combination range thereof. The green emission spectrum or the second light may have a peak emission wavelength within the above ranges. In an embodiment, the green emission spectrum or the second light may have a peak emission wavelength of greater than or equal to about 500 nm and less than or equal to about 580 nm, about 510 nm to about 570 nm, about 515 nm to about 565 nm, about 520 nm to about 560 nm, about 525 nm to about 550 nm, about 530 nm to about 545 nm, or about 535 nm to about 540 nm.

The first luminescent material (for example, a blue light emitting material) may be one or two or more kinds. The second luminescent material (for example, a green light emitting material) may be one or two or more kinds.

As an example, the emission layer 183, the first luminescent material, the second luminescent material, or a combination thereof (hereinafter may be referred to as the emission layer) may include a (electron transporting or hole transporting) host material and a dopant material.

As an example, the emission layer 183 may include a phosphorescent material, a fluorescent material, or a combination thereof. The first luminescent material may include a fluorescent material, a phosphorescent material, or a combination thereof. The second luminescent material may include a phosphorescent material, a fluorescent material, or a combination thereof. As an example, the luminescent material may include an organic luminescent material, and the organic luminescent material may be a low molecular compound, a polymer compound, or a combination thereof. Examples of the phosphorescent material and the fluorescent material are not particularly limited and may be appropriately selected from known materials. The first luminescent material and/or the second luminescent material may include a phosphorescent dopant. The dopant may be an organometallic compound including a metal M. The metal M may include iridium (Ir), platinum (Pt), osmium (Os), titanium (Ti), zirconium (Zr), hafnium (Hf), europium (Eu), terbium (Tb), thulium (Tm), rhodium (Rh), ruthenium (Ru), rhenium (Re), beryllium (Be), magnesium (Mg), aluminum (Al), calcium (Ca), manganese (Mn), cobalt (Co), copper (Cu), zinc (Zn), gallium (Ga), germanium (Ge), rhodium (Rh), palladium (Pd), silver (Ag), gold (Au), or a combination thereof.

In an embodiment, the phosphorescent dopant may include an organometallic compound containing iridium (Ir), an organometallic compound containing platinum (Pt), or an organometallic compound containing osmium (Os). In an embodiment, the dopant may include an organometallic compound having a square-planar coordination structure including the metal M (for example, as described above). The dopant may include a substituted or unsubstituted C5-C30 carbocyclic group, a substituted or unsubstituted C1-C30 heterocyclic group, a non-cyclic group, or a combination thereof. The C5-C30 carbocyclic group or the C1-C30 heterocyclic group may include a six-membered ring, a fused ring in which two or more six-membered rings are condensed together, or a fused ring in which one or more six-membered rings and one five-membered ring are condensed together. The six-membered ring may include a cyclohexane group, a cyclohexene group, an adamantane group, a norbornane group, a norbornene group, a benzene group, a pyridine group, a pyrimidine group, a pyrazine group, a pyridazine group, a triazine group, or a combination thereof. The five-membered ring may include a cyclopentane group, a cyclopentene group, a cyclopentadiene group, a furan group, a thiophene group, a silole group, a pyrrole group, a pyrazole group, an imidazole group, a triazole group, an oxazole group, an isoxazole group, a thiazole group, an isothiazole group, an oxadiazole group, a thiadiazole group, or a combination thereof.

The dopant may include the metal M and an organic ligand, and the metal M and the organic ligand may form one, two, or three cyclometallated rings. The dopant may include a tetradentate organic ligand capable of forming three or four (for example, three) cyclometallated rings with the metal M. The tetradentate organic ligand may include, for example, a benzimidazole group and a pyridine group, but is not limited thereto. When the luminescent material includes an organic luminescent material, the light emitting device 180 may be an organic light emitting diode.

As an example, the luminescent material may include an inorganic luminescent material, and the inorganic luminescent material may be an inorganic semiconductor, a quantum dot, a perovskite, or a combination thereof. The inorganic semiconductor may include a metal nitride, a metal oxide, or a combination thereof. The metal nitride, the metal oxide, or the combination thereof may include a Group Ill metal such as aluminum, gallium, indium, or thallium, a Group IV metal such as silicon, germanium, or tin, or a combination thereof. When the luminescent material includes an inorganic luminescent material, the light emitting device 180 may be a quantum dot light emitting diode, a perovskite light emitting diode, or a micro light emitting diode (μLED). The materials usable as the inorganic luminescent material are known.

In an embodiment, the light emitting device 180 may further include an auxiliary layer 184 and 185. The auxiliary layer 184 and 185 may be disposed between a first electrode 181 and a light emitting layer 183, and between a second electrode 182 and a light emitting layer 183, respectively. The auxiliary layer 184 and 185 may be a charge auxiliary layer for controlling injection and/or mobility of charges. The auxiliary layers 184 and 185 may include at least one layer or two layers, and for example, may include a hole injection layer, a hole transport layer, an electron blocking layer, an electron injection layer, an electron transport layer, a hole blocking layer, or a combination thereof. At least one of the auxiliary layers 184 and 185 may be omitted, if desired. The auxiliary layer may be formed of a material appropriately selected from materials known for an organic electroluminescent device, or the like.

The light emitting devices 180 disposed in each of the subpixels PX₁, PX₂, and PX₃ may be the same or different from each other. The light emitting devices 180 in each of the subpixels PX₁, PX₂, and PX₃ may emit a light having the same or different emission spectra. The light emitting devices 180 in each of the subpixels PX₁, PX₂, and PX₃ may emit, for example, light having a blue emission spectrum, light having a green emission spectrum, or a combination thereof. The light emitting devices 180 in each of the subpixels PX₁, PX₂, and PX₃ may be separated by a pixel defining layer (not shown).

In an embodiment, the light emitting device 180 may be a light emitting device having a tandem structure. In an embodiment, the light emitting device or the emission layer included therein may include a first emission layer and a second emission layer disposed on the first emission layer. The first emission layer may emit the first light, and the second emission layer may emit the second light. A first charge generation layer may be disposed between the first emission layer and the second emission layer. Optionally, a charge auxiliary layer may be further disposed between the first electrode and the first emission layer, between the second electrode and the second emission layer, or a combination thereof.

In an embodiment, the emission layer may include a second emission layer disposed between two or more first emission layers, a first emission layer disposed between two or more second emission layers, or a combination thereof. The first emission layer may be configured to emit the first light. The second emission layer may be configured to emit the second light.

Referring to FIG. 4B, the light emitting device 180 may be a light emitting device having a tandem structure, and may include a first electrode 181 and a second electrode 182 facing each other; a first light emitting layer 183a and a second light emitting layer 183b located between the first electrode 181 and the second electrode 182; a charge generation layer 186 located between the first light emitting layer 183a and the second light emitting layer 183b, and optionally auxiliary layers 184 and 185 located between the first electrode 181 and the first light emitting layer 183a, and/or between the second electrode 182 and the second light emitting layer 183b, respectively.

Details of the first electrode 181, the second electrode 182, and the auxiliary layers 184 and 185 are as described herein.

The first light emitting layer 183a and the second light emitting layer 183b may emit a light having the same or different emission spectra. In an embodiment, the first light emitting layer 183a or the second light emitting layer 183b may emit light having a blue emission spectrum or light having a green emission spectrum, respectively. The charge generation layer 186 may inject an electric charge into the first light emitting layer 183a and/or the second light emitting layer 183b, and may control a charge balance between the first light emitting layer 183a and the second light emitting layer 183b.

The charge generation layer 186 may include, for example, an n-type layer and a p-type layer, and may include, for example, an electron transport material and/or a hole transport material including an n-type dopant and/or a p-type dopant. The charge generation layer 186 may include one layer or two or more layers.

Referring to FIG. 4C, a light emitting device 180 (having a tandem structure) may include a first electrode 181 and a second electrode 182 facing each other; a first light emitting layer 183a, a second light emitting layer 183b, and a third light emitting layer 183c located between the first electrode 181 and the second electrode 182; a first charge generation layer 186a located between the first light emitting layer 183a and the second light emitting layer 183b; a second charge generation layer 186b located between the second light emitting layer 183b and the third light emitting layer 183c; and optionally, auxiliary layers 184 and 185 located between the first electrode 181 and the first light emitting layer 183a, and/or between the second electrode 182 and the third light emitting layer 183c, respectively.

Details of the first electrode 181, the second electrode 182, and the auxiliary layers 184 and 185 are as described herein.

The first light emitting layer 183a, the second light emitting layer 183b, and the third light emitting layer 183c may emit a light having the same or different emission spectra. The first light emitting layer 183a, the second light emitting layer 183b, and the third light emitting layer 183c may emit a blue light. In an embodiment, the first light emitting layer 183a and the third light emitting layer 183c may emit light of a blue emission spectrum, and the second light emitting layer 183b may emit light of a green emission spectrum. In another embodiment, the first light emitting layer 183a and the third light emitting layer 183c may emit light of a green emission spectrum, and the second light emitting layer 183b may emit light of a blue emission spectrum.

The first charge generation layer 186a may inject an electric charge into the first light emitting layer 183a and/or the second light emitting layer 183b, and may control charge balances between the first light emitting layer 183a and the second light emitting layer 183b. The second charge generation layer 186b may inject an electric charge into the second light emitting layer 183b and/or the third light emitting layer 183c, and may control charge balances between the second light emitting layer 183b and the third light emitting layer 183c. Each of the first and second charge generation layers 186a and 186b may include one layer or two or more layers, respectively.

Referring to FIG. 4D, in an embodiment, the light emitting device 180 may include a light emitting layer 183, a first electrode 181, a second electrode 182, and a plurality of nanostructures 187 arranged in the light emitting layer 183.

One of the first electrode 181 and the second electrode 182 may be an anode and the other may be a cathode. The first electrode 181 and the second electrode 182 may be an electrode patterned according to a direction of an arrangement of the plurality of nanostructures 187, and may include, for example, a conductive oxide such as indium tin oxide (ITO), indium zinc oxide (IZO), zinc oxide (ZnO), tin oxide (SnO), aluminum tin oxide (AlTO), fluorine-doped tin oxide (FTO), or the like; or silver (Ag), copper (Cu), aluminum (Al), gold (Au), titanium (Ti), chromium (Cr), nickel (Ni), an alloy thereof, a nitride thereof (e.g., TiN); or a combination thereof, but embodiments are not limited thereto.

The light emitting layer 183 may include a plurality of nanostructures 187, and each of the subpixels PX₁, PX₂, and PX₃ may include a plurality of nanostructures 187. In an embodiment, the plurality of nanostructures 187 may be arranged in one direction, but embodiments are not limited thereto. The nanostructures 187 may be a compound-containing semiconductor that is configured to emit light of a predetermined wavelength for example with an application of an electric current, and may be, for example, a linear nanostructure, such as a nanorod or a nanoneedle. A diameter or a long diameter of the nanostructures 187 may be, for example, several nanometers to several hundreds of nanometers, and aspect ratios of the nanostructures 187 may be greater than about 1, greater than or equal to about 1.5, greater than or equal to about 2.0, greater than or equal to about 3.0, greater than or equal to about 4.0, greater than or equal to about 4.5 or greater than or equal to about 5.0 to less than or equal to about 20, for example, greater than about 1 to about 20, about 1.5 to about 20, about 2.0 to about 20, about 3.0 to about 20, about 4.0 to about 20, about 4.5 to about 20, or about 5.0 to about 20.

Each of the nanostructures 187 may include a p-type region 187p, an n-type region 187n, and a multiple quantum well region 187i, and may be configured to emit light from the multiple quantum well region 187i. The nanostructure 187 may include, for example, gallium nitride (GaN), indium gallium nitride (InGaN), aluminum gallium nitride (AlGaN), or a combination thereof, and may have, for example, a core-shell structure.

The plurality of nanostructures 187 may each emit light having the same or different emission spectra. In an embodiment, the nanostructure may emit light of a blue emission spectrum, for example, light of a blue emission spectrum having a peak emission wavelength in a wavelength region of greater than or equal to about 400 nm to less than 500 nm, about 410 nm to about 490 nm, or about 420 nm to about 480 nm.

A plurality of nanostructures 187 may emit light having identical or different emission spectra. In an embodiment, the plurality of nanostructures 187 may include a first nanostructure. The first nanostructure may emit light having a blue emission spectrum and light having a green emission spectrum. In an embodiment, the plurality of nanostructures 187 may include a first nanostructure configured to emit light having a blue emission spectrum and a second nanostructure (not shown) configured to emit light having a green emission spectrum.

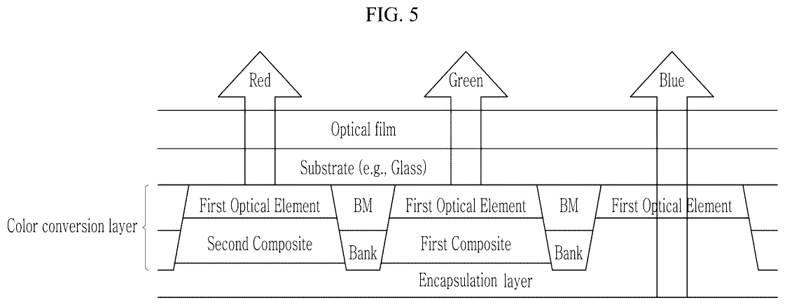

A display panel of an embodiment includes a color conversion panel (or a color conversion structure) 200. The color conversion panel 200 may receive mixed incident light supplied from the emission panel 100, convert the incident light into light having an emission spectrum different from that of the incident light, and emit the converted light toward an observer (not shown). Hereinafter, with reference to FIG. 5, the color conversion panel will be described in more detail. Referring to FIG. 5, the color conversion panel 200 of an embodiment may further include a partition wall (e.g., a black matrix (BM), a bank, or a combination thereof) that defines each region of the color conversion layer 270. The color conversion layer may be a patterned film of a composite including a semiconductor nanoparticle. The color conversion region includes one or more first regions configured to convert the emission spectrum of the incident light into a green light spectrum (e.g., for example as receiving the incident light). The first region may correspond to a green pixel. The first region includes a first composite. In an embodiment, the first composite includes a matrix (e.g., a polymer matrix) and a semiconductor nanoparticle dispersed in the matrix. The first composite (or the first region) is configured to emit green light. A first optical element (e.g., a first optical element such as an absorptive color filter) may be disposed on the light extraction surface of the color conversion layer. An additional optical element such as a microlens may be further disposed on the first optical element.

The first optical element (or the first optical filter layer) may block light of a predetermined wavelength region of the visible light and may transmit light of the remaining wavelength region, and may block, for example, blue light (or green light) and transmit light except for the blue light (or green light). The first optical element may transmit green light, red light, and/or yellow light, which is a mixed color of green and red light. The first optical element may transmit blue light and block green light, and may be disposed on a blue light emission pixel.

The first optical element may substantially block excitation light and transmit light of a desired wavelength region. The transmittance of the first optical element for light of the desired wavelength region may be greater than or equal to about 70%, greater than or equal to about 80%, greater than or equal to about 90%, or even 100%.

The first optical element that selectively transmits red light may be disposed at a position overlapping a red light emission region, and the first optical element that selectively transmits green light may be disposed at a position overlapping a green light emission region, respectively.

The first optical element may include a first region that blocks (e.g., absorbs) blue light and red light and selectively transmits light within a predetermined range (e.g., greater than or equal to about 500 nm, greater than or equal to about 510 nm, or greater than or equal to about 515 nm and less than or equal to about 550 nm, less than or equal to about 545 nm, less than or equal to about 540 nm, less than or equal to about 535 nm, less than or equal to about 530 nm, less than or equal to about 525 nm, or less than or equal to about 520 nm); a second region that blocks (e.g., absorbs) blue light and green light and selectively transmits light within a predetermined range (e.g., greater than or equal to about 600 nm, greater than or equal to about 610 nm, or greater than or equal to about 615 nm and less than or equal to about 650 nm, less than or equal to about 645 nm, less than or equal to about 640 nm, less than or equal to about 635 nm, less than or equal to about 630 nm, less than or equal to about 625 nm, or less than or equal to about 620 nm); or a combination thereof. When a light source emits a mixture of blue and green light, the first optical element may further include a third region that selectively transmits blue light and blocks green light.

The first region may be disposed at a position overlapping the green light emission region. The second region may be disposed at a position overlapping the red light emission region. The third region may be disposed at a position overlapping the blue light emission region.

The first region, the second region, and optionally the third region may be optically isolated. Such a first optical element may contribute to the improvement of color purity of the display device. The first optical element may be formed as an integrated layer having a relatively flat surface.

The first optical element may include a polymer thin film including a dye and/or a pigment that absorbs light of a wavelength intended to be blocked. The first optical element may include a single layer having a low refractive index and may be a transparent thin film having a refractive index of less than or equal to about 1.4, less than or equal to about 1.3, or less than or equal to about 1.2. The second optical filter layer or the first optical element having a low refractive index may be, for example, a porous silicon oxide, a porous organic material, a porous organic: Inorganic composite, or a combination thereof.

The first optical element may include a plurality of layers having different refractive indices. Two layers having different refractive indices may be alternately stacked. For example, a first or second optical filter layer may be formed by alternately stacking a material having a high refractive index and a material having a low refractive index.

The color conversion region may include one or more second regions configured to emit light of a color different from the green light (e.g., red light) (e.g., by irradiation of incident light), and the second region may include a second composite. The semiconductor nanoparticle composite of the second region may include semiconductor nanoparticles that emit light having a wavelength (e.g., a different color or red) different from that of the semiconductor nanoparticle composite of the first region.

The color conversion panel may further include one or more third regions that emit or transmit blue light. The blue light may have a peak emission wavelength in the range of greater than or equal to about 380 nm (e.g., greater than or equal to about 440 nm, greater than or equal to about 445 nm, greater than or equal to about 450 nm, or greater than or equal to about 455 nm) and less than or equal to about 480 nm (less than or equal to about 475 nm, less than or equal to about 470 nm, less than or equal to about 465 nm, or less than or equal to about 460 nm).

Referring again to FIG. 3B, a color conversion panel 200 (e.g., a color conversion layer 270) of an embodiment faces an light emitting device 180 of the light emitting panel 100. The color conversion panel 200 (e.g., the color conversion layer 270) of an embodiment may include at least one color conversion region that converts the emission spectrum of light supplied from the emission panel 100 into a different emission spectrum, and the color conversion region may convert the light of the emission spectrum supplied from the emission panel 100 into light of the emission spectrum of a color displayed in each subpixel PX₁, PX₂, PX₃. The color conversion panel 200 of an embodiment may further include an upper substrate 210, a light blocking pattern or a black matrix 220, a color filter layer or a first optical element 230, a planarization layer 240, a partition wall 250, an encapsulation layer 290, or a combination thereof. In an embodiment, a first sub-pixel PX₁, a second sub-pixel PX₂, and a third sub-pixel PX₃ respectively display green, red, and blue, and light of a green emission spectrum, a red emission spectrum, and a blue emission spectrum may be emitted from a first color conversion region 270a, a second color conversion region 270b, and a third color conversion region or light-transmitting region 270c, respectively. In an embodiment, a first color filter 230a overlapping the first color conversion region 270a may be a green filter, a second color filter 230b overlapping the second color conversion region 270b may be a red filter, and a third color filter 230c overlapping the third color conversion or light-transmitting region 270c may be a blue filter. The first color filter 230a, the second color filter 230b, or the third color filter 230c may include a pigment or dye that selectively transmits light of a green wavelength spectrum, a red wavelength spectrum, or a blue wavelength spectrum, respectively, and absorbs and/or reflects light of the remaining wavelength spectra. The composite may include semiconductor nanoparticles 271a, 271b dispersed in a matrix 273a, 273b, 273c. The third region 270c includes a third composite, and the third composite includes a matrix and may include or may not include semiconductor nanoparticles. A light scatter 272a, 272b, and 272c may be included in each composite.

In a display device including such a color conversion panel, the physical properties (e.g., optical properties and stability) of the semiconductor nanoparticles may directly affect the display quality of the device. For example, the luminescent material included in the color conversion panel disposed on the front side of the device may be required to have not only high emission efficiency but also an improved absorbance with respect to the incident light. When applied as a patterned thin film such as a color filter, a reduction in the absorbance of the incident light may directly cause blue light leakage in the display device, negatively affect the color gamut (e.g., DCI matching rate), and the use of an absorptive color filter to prevent blue light leakage may lead to a further decrease in emission efficiency. The reduced absorbance of the semiconductor nanoparticles may lead to decreased luminance of the device including the nanoparticles.

Many of the nanoparticles capable of exhibiting a property (optical property and/or stability) applicable to a device include a cadmium-based compound (e.g., a cadmium chalcogenide). Cadmium poses a serious environmental and health issue and is one of the regulated elements. Accordingly, for an environmentally friendly nanoparticle that is cadmium-free, in-depth research has been conducted on a nanocrystal based on a Group III-V compound. However, the present inventors have found that a cadmium-free semiconductor nanoparticle tends to exhibit relatively inferior optical property (e.g., emission efficiency and/or incident light absorbance) compared to a semiconductor nanoparticle containing a harmful heavy metal. Therefore, there is a technical need for the development of a semiconductor nanoparticle that can exhibit an increased incident light absorbance and a narrowed full width at half maximum compared to a cadmium-free nanoparticle based on a Group III-V compound (e.g., an indium phosphide).

Meanwhile, in a display panel in which a color conversion panel including a semiconductor nanoparticle as a light emitting material is disposed on a light emitting panel (e.g., an OLED), blue light provided from a light source (e.g., a blue OLED) is converted into red and green while passing through a color conversion layer based on the semiconductor nanoparticle in the color conversion panel, or is extracted as blue light so that a desired color can be displayed at each pixel of the display panel. Research has been continuously conducted to enhance the emission efficiency of the semiconductor nanoparticle-based color conversion layer while using a blue light emitting device as a light source.

However, the present inventors have found that the color conversion layer may include a predetermined amount of the semiconductor nanoparticle, thereby having a technical limitation in improving the efficiency and luminance of the color conversion layer. In order to improve the luminance and display quality of the display panel, the addition of a green emission layer (e.g., a green OLED) as a light source may be considered. However, as confirmed by the present inventors, when the light emitting panel includes both the green emission layer and the blue emission layer, even a color conversion layer including a semiconductor nanoparticle configured to absorb incident light at a relatively high level may fail to provide a desired level of enhanced photo-conversion efficiency or luminance. In other words, a color conversion layer including a cadmium-free semiconductor nanoparticle configured to emit green light while having an enhanced absorbance (e.g., a semiconductor nanoparticle based on silver-indium-gallium-sulfur) may have difficulty exhibiting a desired degree of improvement or enhancement in photo-conversion efficiency and luminance when mixed light of blue light and green light is provided as incident light.

In the display panel of an embodiment, the color conversion panel includes a predetermined amount of a cadmium-free semiconductor nanoparticle in the color conversion layer, and can convert the mixed incident light provided from the light emitting panel with significantly improved efficiency and provide enhanced luminance.

Accordingly, in an embodiment, a first composite included in a first region of the color conversion layer (or a semiconductor nanoparticle composite of an embodiment) includes a matrix (e.g., a polymer matrix) and a semiconductor nanoparticle that is dispersed in the matrix and configured to convert a light emission spectrum of incident light. The semiconductor nanoparticle includes a Group 11-13-16 compound including silver, a Group 13 metal, and a chalcogen element, wherein the Group 13 metal includes indium and gallium, and the chalcogen element includes sulfur. In the present specification, the detailed description of the first composite can be applied to the semiconductor nanoparticle composite of an embodiment, and vice versa.

In the color conversion panel of an embodiment, the first composite has an absorbance for the first light greater than or equal to about 80%, and the first composite has a transmittance greater than or equal to about 55% for light having a wavelength of 530 nm. The first light may have a wavelength of 450 nm to 465 nm

The absorbance of the first composite for the first light may be greater than or equal to about 81%, greater than or equal to about 82%, greater than or equal to about 83%, greater than or equal to about 84%, greater than or equal to about 85%, greater than or equal to about 86%, greater than or equal to about 87%, greater than or equal to about 88%, greater than or equal to about 89%, or greater than or equal to about 90%. The absorbance of the first composite for the first light may be less than or equal to about 99%, less than or equal to about 98%, less than or equal to about 97%, less than or equal to about 96%, less than or equal to about 95%, less than or equal to about 94%, less than or equal to about 93%, less than or equal to about 92%, less than or equal to about 91%, less than or equal to about 90%, less than or equal to about 89%, or less than or equal to about 88%.

The transmittance of the first composite for light having a wavelength of 530 nm may be greater than or equal to about 55%, greater than or equal to about 56%, greater than or equal to about 57%, greater than or equal to about 58%, greater than or equal to about 59%, greater than or equal to about 60%, greater than or equal to about 61%, greater than or equal to about 62%, greater than or equal to about 63%, greater than or equal to about 64%, greater than or equal to about 65%, greater than or equal to about 66%, greater than or equal to about 67%, greater than or equal to about 68%, greater than or equal to about 69%, greater than or equal to about 70%, greater than or equal to about 71%, greater than or equal to about 72%, greater than or equal to about 73%, greater than or equal to about 74%, or greater than or equal to about 75%.

The first composite may have a transmittance for light having a wavelength of 530 nm less than or equal to about 99%, less than or equal to about 96%, less than or equal to about 93%, less than or equal to about 90%, less than or equal to about 87%, less than or equal to about 85%, less than or equal to about 81%, less than or equal to about 79%, less than or equal to about 78%, less than or equal to about 77%, less than or equal to about 76%, or less than or equal to about 75%.

Surprisingly, the present inventors have found that when the first composite exhibits the absorbance for the first light within the range described herein and exhibits the transmittance for light having a wavelength of 530 nm within the range described herein, an enhanced level of photo-conversion efficiency can be achieved, and a green pixel including the same can implement enhanced luminance.

In an embodiment, the semiconductor nanoparticle included in the first composite includes a Group 11-13-16 compound including silver, a Group 13 metal, and a chalcogen element. The semiconductor nanoparticle may further include zinc. In an embodiment, the semiconductor nanoparticle, the first composite, or the color conversion layer may not include cadmium. The semiconductor nanoparticle, the first composite, or the color conversion layer may not include lead, mercury, or a combination thereof.

The semiconductor nanoparticle of an embodiment may be configured to emit green light or second light. A maximum peak emission wavelength of the green light may be greater than or equal to about 500 nm, greater than or equal to about 501 nm, greater than or equal to about 504 nm, greater than or equal to about 505 nm, greater than or equal to about 510 nm, greater than or equal to about 515 nm, or greater than or equal to about 520 nm. The maximum peak emission wavelength of the green light may be less than or equal to about 550 nm, less than or equal to about 545 nm, less than or equal to about 540 nm, less than or equal to about 530 nm, less than or equal to about 525 nm, less than or equal to about 520 nm, less than or equal to about 515 nm, or less than or equal to about 510 nm.

In an embodiment, the semiconductor nanoparticle may achieve enhanced optical properties (e.g., a narrow full width at half maximum, increased quantum yield, and blue light absorbance) while emitting light in a desired wavelength range. The semiconductor nanoparticle of the embodiment may be utilized as a material for various color conversion (or wavelength down-conversion), such as a color conversion panel or a color conversion sheet, and may exhibit increased absorbance per weight of emitting particles, thereby enabling a panel or sheet including the same to be manufactured at reduced cost and providing improved photoconversion efficiency.

In the semiconductor nanoparticle of the embodiment, the group 13 metal may include indium, gallium, aluminum, or a combination thereof. The group 13 metal may include indium and gallium. The chalcogen element may include sulfur, selenium, or a combination thereof. The chalcogen element may include sulfur. The semiconductor nanoparticle may include gallium and zinc on a surface thereof. In an embodiment, the semiconductor nanoparticle may include or may not include copper. In an embodiment, the semiconductor nanoparticle may not include lithium. The semiconductor nanoparticle may include or may not include an alkali metal such as lithium, sodium, potassium, or the like.

The semiconductor nanoparticle may have a charge balance value represented by the following equation, which may be greater than or equal to about 0.8 and less than or equal to about 2.5, or less than or equal to about 1.5:

$$charge balance value = \{ [ Ag ] + 3 \times ( [ group 13 metal ] ) + 2 \times [ Zn ] \} / ( 2 \times [ CH A ] )$$

wherein [Ag], [group 13 metal], [Zn], and [CHA] are mole contents of silver, a group 13 metal (e.g., indium, gallium, or a combination thereof), zinc, and a chalcogen element (e.g., sulfur, selenium, or a combination thereof) in the semiconductor nanoparticle, respectively.

The group 13 metal may include indium and gallium. The chalcogen element may include sulfur.

In an embodiment, the charge balance value may be represented by the following equation:

$$charge balance value = \{ [ Ag ] + 3 \times ( [ ln ] + [ Ga ] ) + 2 \times [ Zn ] \} / ( 2 \times [ S ] )$$

wherein [Ag], [In], [Ga], [Zn], and [S] are mole contents of silver, indium, gallium, zinc, and sulfur in the semiconductor nanoparticle, respectively.

The charge balance value may be less than or equal to about 2.4, less than or equal to about 2.3, less than or equal to about 2.2, less than or equal to about 2.1, less than or equal to about 2, less than or equal to about 1.8, less than or equal to about 1.5, less than or equal to about 1.45, less than or equal to about 1.4, less than or equal to about 1.35, less than or equal to about 1.33, less than or equal to about 1.31, less than or equal to about 1.3, less than or equal to about 1.29, less than or equal to about 1.28, less than or equal to about 1.27, less than or equal to about 1.26, less than or equal to about 1.25, less than or equal to about 1.24, less than or equal to about 1.23, less than or equal to about 1.22, less than or equal to about 1.21, less than or equal to about 1.2, less than or equal to about 1.15, less than or equal to about 1.1, or less than or equal to about 1.05.

The charge balance value may be greater than or equal to about 0.81, greater than or equal to about 0.85, greater than or equal to about 0.9, greater than or equal to about 0.95, greater than or equal to about 0.97, greater than or equal to about 0.99, greater than or equal to about 1, greater than or equal to about 1.01, greater than or equal to about 1.02, greater than or equal to about 1.03, greater than or equal to about 1.04, greater than or equal to about 1.05, greater than or equal to about 1.06, greater than or equal to about 1.07, greater than or equal to about 1.08, greater than or equal to about 1.09, greater than or equal to about 1.1, greater than or equal to about 1.11, greater than or equal to about 1.12, greater than or equal to about 1.13, greater than or equal to about 1.14, greater than or equal to about 1.15, greater than or equal to about 1.16, greater than or equal to about 1.17, greater than or equal to about 1.18, greater than or equal to about 1.19, greater than or equal to about 1.2, greater than or equal to about 1.21, greater than or equal to about 1.22, greater than or equal to about 1.23, greater than or equal to about 1.24, or greater than or equal to about 1.25.

In the semiconductor nanoparticle, the mole ratio (Ga:In) of gallium to indium may be greater than or equal to about 6:1, greater than or equal to about 6.4:1, greater than or equal to about 6.43:1, greater than or equal to about 6.45:1, greater than or equal to about 6.7:1, greater than or equal to about 6.75:1, greater than or equal to about 6.77:1, greater than or equal to about 7:1, greater than or equal to about 7.1:1, greater than or equal to about 7.2:1, greater than or equal to about 7.26:1, greater than or equal to about 7.6:1, greater than or equal to about 7.62:1, or greater than or equal to about 8:1, and less than or equal to about 35:1, less than or equal to about 32:1, less than or equal to about 30:1, less than or equal to about 15:1, less than or equal to about 14:1, less than or equal to about 13:1, less than or equal to about 12:1, less than or equal to about 10:1, less than or equal to about 9:1, or less than or equal to about 8.5:1.

In the semiconductor nanoparticle of an embodiment, the mole ratio (Ag:In) of silver to indium may be greater than or equal to about 1.5:1, greater than or equal to about 1.7:1, greater than or equal to about 1.8:1, greater than or equal to about 1.88:1, greater than or equal to about 2:1, greater than or equal to about 3:1, greater than or equal to about 3.8:1, greater than or equal to about 4:1, greater than or equal to about 4.3:1, greater than or equal to about 4.5:1, greater than or equal to about 4.53:1, greater than or equal to about 4.7:1, greater than or equal to about 4.9:1, greater than or equal to about 5:1, greater than or equal to about 5.2:1, greater than or equal to about 5.22:1, greater than or equal to about 5.5:1, greater than or equal to about 5.59:1, greater than or equal to about 6:1, or greater than or equal to about 6.1:1. In the semiconductor nanoparticle of an embodiment, the mole ratio (Ag:In) of silver to indium may be less than or equal to about 25:1, less than or equal to about 20:1, less than or equal to about 19:1, less than or equal to about 12:1, less than or equal to about 8:1, less than or equal to about 7:1, or less than or equal to about 6.5:1.

In the semiconductor nanoparticle of an embodiment, the mole ratio (Ga:S) of gallium to sulfur may be greater than or equal to about 0.1:1, greater than or equal to about 0.15:1, greater than or equal to about 0.2:1, greater than or equal to about 0.25:1, greater than or equal to about 0.3:1, greater than or equal to about 0.31:1, greater than or equal to about 0.32:1, greater than or equal to about 0.33:1, greater than or equal to about 0.34:1, greater than or equal to about 0.35:1, greater than or equal to about 0.38:1, greater than or equal to about 0.4:1, greater than or equal to about 0.47:1, greater than or equal to about 0.48:1, greater than or equal to about 0.5:1, greater than or equal to about 0.51:1, greater than or equal to about 0.53:1, greater than or equal to about 0.55:1, greater than or equal to about 0.56:1, greater than or equal to about 0.58:1, greater than or equal to about 0.6:1, or greater than or equal to about 0.62:1. The mole ratio (Ga:S) of gallium to sulfur may be less than or equal to about 1:1, less than or equal to about 0.9:1, less than or equal to about 0.8:1, less than or equal to about 0.65:1, less than or equal to about 0.63:1, less than or equal to about 0.6:1, less than or equal to about 0.55:1, less than or equal to about 0.45:1, less than or equal to about 0.42:1, less than or equal to about 0.41:1, or less than or equal to about 0.4:1.

In the semiconductor nanoparticle of an embodiment, the mole ratio (In:S) of indium to sulfur may be greater than or equal to about 0.01:1, greater than or equal to about 0.02:1, greater than or equal to about 0.03:1, greater than or equal to about 0.04:1, greater than or equal to about 0.05:1, greater than or equal to about 0.06:1, greater than or equal to about 0.07:1, greater than or equal to about 0.08:1, greater than or equal to about 0.09:1, or greater than or equal to about 0.1:1. The mole ratio (In:S) of indium to sulfur may be less than or equal to about 0.5:1, less than or equal to about 0.4:1, less than or equal to about 0.3:1, less than or equal to about 0.25:1, less than or equal to about 0.15:1, less than or equal to about 0.14:1, less than or equal to about 0.13:1, less than or equal to about 0.12:1, less than about 0.1:1, or less than or equal to about 0.08:1.

In the semiconductor nanoparticle of an embodiment, the mole ratio (Ag:S) of silver to sulfur may be greater than or equal to about 0.03:1, greater than or equal to about 0.05:1, greater than or equal to about 0.06:1, greater than or equal to about 0.07:1, greater than or equal to about 0.08:1, greater than or equal to about 0.09:1, greater than or equal to about 0.1:1, greater than or equal to about 0.15:1, greater than or equal to about 0.2:1, greater than or equal to about 0.25:1, greater than or equal to about 0.3:1, greater than or equal to about 0.35:1, greater than or equal to about 0.36:1, greater than or equal to about 0.37:1, greater than or equal to about 0.38:1, greater than or equal to about 0.39:1, greater than or equal to about 0.4:1, or greater than or equal to about 0.45:1. The mole ratio (Ag:S) of silver to sulfur may be less than or equal to about 1:1, less than or equal to about 0.6:1, less than or equal to about 0.5:1, less than or equal to about 0.44:1, less than or equal to about 0.4:1, or less than or equal to about 0.39:1.

In the semiconductor nanoparticle, the mole ratio [(In+Ga):S] of the total of indium and gallium to sulfur may be greater than or equal to about 0.4:1, greater than or equal to about 0.45:1, greater than or equal to about 0.5:1, greater than or equal to about 0.51:1, greater than or equal to about 0.52:1, greater than or equal to about 0.54:1, greater than or equal to about 0.55:1, greater than or equal to about 0.56:1, greater than or equal to about 0.57:1, greater than or equal to about 0.575:1, greater than or equal to about 0.58:1, greater than or equal to about 0.59:1, greater than or equal to about 0.6:1, or greater than or equal to about 0.61:1, and less than or equal to about 1:1, less than or equal to about 0.9:1, less than or equal to about 0.85:1, less than or equal to about 0.67:1, less than or equal to about 0.65:1, less than or equal to about 0.64:1, less than or equal to about 0.63:1, or less than or equal to about 0.62:1.

In the semiconductor nanoparticle, the mole ratio ((In+Ga):Ag) of the total of indium and gallium to silver may be greater than or equal to about 1:1, greater than or equal to about 1.1:1, greater than or equal to about 1.2:1, greater than or equal to about 1.3:1, greater than or equal to about 1.35:1, greater than or equal to about 1.38:1, greater than or equal to about 1.4:1, greater than or equal to about 1.41:1, greater than or equal to about 1.46:1, greater than or equal to about 1.47:1, greater than or equal to about 1.48:1, greater than or equal to about 1.49:1, greater than or equal to about 1.6:1, greater than or equal to about 1.62:1, greater than or equal to about 1.64:1, greater than or equal to about 1.68:1, greater than or equal to about 1.8:1, greater than or equal to about 1.85:1, greater than or equal to about 1.9:1, greater than or equal to about 1.95:1, greater than or equal to about 1.99:1, greater than or equal to about 2:1, greater than or equal to about 2.1:1, greater than or equal to about 2.2:1, greater than or equal to about 2.3:1, or greater than or equal to about 2.35:1, and less than or equal to about 7:1, less than or equal to about 6.5:1, less than or equal to about 6.3:1, less than or equal to about 6:1, less than or equal to about 5.9:1, less than or equal to about 5.7:1, less than or equal to about 5.66:1, less than or equal to about 5.5:1, less than or equal to about 5.3:1, less than or equal to about 5.1:1, less than or equal to about 4.5:1, less than or equal to about 4:1, less than or equal to about 3.5:1, less than or equal to about 3.2:1, less than or equal to about 3:1, less than or equal to about 2.8:1, less than or equal to about 2.6:1, less than or equal to about 2.4:1, less than or equal to about 1.8:1, less than or equal to about 1.7:1, less than or equal to about 1.67:1, less than or equal to about 1.66:1, or less than or equal to about 1.65:1.

In the semiconductor nanoparticle of an embodiment, the mole ratio of gallium to a total of indium and gallium (Ga:(In+Ga)) may be greater than or equal to about 0.5:1, greater than or equal to about 0.55:1, greater than or equal to about 0.6:1, greater than or equal to about 0.65:1, greater than or equal to about 0.7:1, greater than or equal to about 0.75:1, greater than or equal to about 0.8:1, greater than or equal to about 0.82:1, greater than or equal to about 0.85:1, greater than or equal to about 0.86:1, greater than or equal to about 0.87:1, or greater than or equal to about 0.88:1. The mole ratio of gallium to a total of indium and gallium may be less than or equal to about 0.99:1, less than or equal to about 0.98:1, less than or equal to about 0.97:1, less than or equal to about 0.96:1, less than or equal to about 0.95:1, less than or equal to about 0.94:1, less than or equal to about 0.93:1, less than or equal to about 0.92:1, less than or equal to about 0.91:1, less than or equal to about 0.9:1, less than or equal to about 0.89:1, or less than or equal to about 0.83:1.

In the semiconductor nanoparticle of an embodiment, a mole ratio of sulfur to a total of silver, indium, and gallium (S:(Ag+In+Ga)) may be greater than or equal to about 0.65:1, greater than or equal to about 0.68:1, greater than or equal to about 0.7:1, greater than or equal to about 0.75:1, greater than or equal to about 0.8:1, greater than or equal to about 0.85:1, greater than or equal to about 0.9:1, greater than or equal to about 0.92:1, greater than or equal to about 0.95:1, greater than or equal to about 1:1, greater than or equal to about 1.02:1, greater than or equal to about 1.05:1, greater than or equal to about 1.1:1, greater than or equal to about 1.2:1, greater than or equal to about 1.3:1, greater than or equal to about 1.35:1, greater than or equal to about 1.36:1, greater than or equal to about 1.38:1, greater than or equal to about 1.4:1, or greater than or equal to about 1.45:1. In the semiconductor nanoparticle, a mole ratio of sulfur to a total of silver, indium, and gallium (S:(Ag+In+Ga)) may be less than or equal to about 3:1, less than or equal to about 2.5:1, less than or equal to about 2:1, less than or equal to about 1.9:1, less than or equal to about 1.88:1, less than or equal to about 1.6:1, less than or equal to about 1.55:1, less than or equal to about 1.5:1, less than or equal to about 1.45:1, less than or equal to about 1.4:1, less than or equal to about 1.35:1, less than or equal to about 1.33:1, less than or equal to about 1.3:1, less than or equal to about 1.25:1, less than or equal to about 1.2:1, less than or equal to about 1.17:1, less than or equal to about 1.15:1, less than or equal to about 1.09:1, less than or equal to about 1.05:1, or less than or equal to about 1.02:1.

In the semiconductor nanoparticle, a mole ratio of silver to a total of silver, indium, and gallium [Ag:(Ag+In+Ga)] may be greater than or equal to about 0.31:1, greater than or equal to about 0.35:1, greater than or equal to about 0.36:1, greater than or equal to about 0.37:1, greater than or equal to about 0.375:1, greater than or equal to about 0.38:1, greater than or equal to about 0.39:1, greater than or equal to about 0.4:1, greater than or equal to about 0.415:1, and may be less than or equal to about 0.7:1, less than or equal to about 0.6:1, less than or equal to about 0.5:1, less than or equal to about 0.45:1, less than or equal to about 0.43:1, or less than or equal to about 0.41:1.

In the semiconductor nanoparticle of an embodiment, a mole ratio of zinc to indium (Zn:In) may be greater than or equal to about 0.1:1, greater than or equal to about 0.3:1, greater than or equal to about 0.5:1, greater than or equal to about 0.7:1, greater than or equal to about 0.75:1, greater than or equal to about 0.78:1, greater than or equal to about 0.9:1, greater than or equal to about 1:1, greater than or equal to about 1.2:1, greater than or equal to about 1.4:1, greater than or equal to about 1.6:1, greater than or equal to about 1.7:1, or greater than or equal to about 1.72:1. In the semiconductor nanoparticle of an embodiment, a mole ratio of zinc to indium may be less than or equal to about 3:1, less than or equal to about 2.5:1, less than or equal to about 2:1, less than or equal to about 1.9:1, less than or equal to about 1.85:1, less than or equal to about 1.7:1, less than or equal to about 1.75:1, or less than or equal to about 1.72:1.

In the semiconductor nanoparticle, an amount of indium may have a concentration gradient that changes (e.g., decreases) in a radial direction (e.g., proceeding from a center to an outer edge). In an embodiment, in the semiconductor nanoparticle, an amount of indium in a portion adjacent to a surface (e.g., a shell layer or an outermost layer) may be smaller than a content of indium in an inner portion of the semiconductor nanoparticle. In an embodiment, in the semiconductor nanoparticle, the portion adjacent to the surface (e.g., the shell layer or the outermost layer) may not include indium.

In the semiconductor nanoparticle of an embodiment, gallium may be exposed to or located on a surface of a semiconductor nanocrystal, zinc may be located on the surface of the semiconductor nanocrystal, and an organic ligand (e.g., a first organic ligand or a second organic ligand as described herein) may be adjacent to or in contact with the surface of the semiconductor nanocrystal.

In an embodiment, the semiconductor nanoparticle may include a first semiconductor nanocrystal (or a core including the same) and a second semiconductor nanocrystal (or a shell including the same) (e.g., disposed on or surrounding the first semiconductor nanocrystal). The semiconductor nanoparticle may have a core-shell structure. The first semiconductor nanocrystal may have a composition different from that of the second semiconductor nanocrystal. The semiconductor nanoparticle or the shell may further include an inorganic layer including a zinc chalcogenide as an outermost layer, for example. The zinc chalcogenide may include zinc; and selenium, sulfur, or a combination thereof. The zinc chalcogenide may include ZnSe, ZnSeS, ZnS, or a combination thereof. The semiconductor nanoparticle or the shell may further include a layer (including a third semiconductor nanocrystal) including zinc, gallium, and sulfur between the outermost layer and the second semiconductor nanocrystal, for example.

A size (e.g., an average size) of the first semiconductor nanocrystal or the core may be greater than or equal to about 0.5 nm, greater than or equal to about 1 nm, greater than or equal to about 1.5 nm, greater than or equal to about 1.7 nm, greater than or equal to about 1.9 nm, greater than or equal to about 2 nm, greater than or equal to about 2.1 nm, greater than or equal to about 2.3 nm, greater than or equal to about 2.5 nm, greater than or equal to about 2.7 nm, greater than or equal to about 2.9 nm, greater than or equal to about 3 nm, greater than or equal to about 3.1 nm, greater than or equal to about 3.3 nm, greater than or equal to about 3.5 nm, greater than or equal to about 3.7 nm, or greater than or equal to about 3.9 nm. A size of the first semiconductor nanocrystal or the core may be less than or equal to about 5 nm, less than or equal to about 4.5 nm, less than or equal to about 4 nm, less than or equal to about 3.5 nm, less than or equal to about 3 nm, less than or equal to about 2.5 nm, less than or equal to about 2 nm, or less than or equal to about 1.5 nm.

A thickness or an average thickness (hereinafter, referred to as “thickness”) of the second semiconductor nanocrystal, the third semiconductor nanocrystal, or the shell may be greater than or equal to about 0.1 nm, greater than or equal to about 0.3 nm, greater than or equal to about 0.5 nm, greater than or equal to about 0.7 nm, greater than or equal to about 1 nm, greater than or equal to about 1.5 nm, greater than or equal to about 1.7 nm, greater than or equal to about 1.9 nm, greater than or equal to about 2 nm, greater than or equal to about 2.1 nm, greater than or equal to about 2.3 nm, greater than or equal to about 2.5 nm, greater than or equal to about 2.7 nm, greater than or equal to about 2.9 nm, greater than or equal to about 3 nm, greater than or equal to about 3.1 nm, greater than or equal to about 3.3 nm, greater than or equal to about 3.5 nm, greater than or equal to about 3.7 nm, or greater than or equal to about 3.9 nm. A thickness of the second semiconductor nanocrystal, the third semiconductor nanocrystal, or the shell may be less than or equal to about 5 nm, less than or equal to about 4.5 nm, less than or equal to about 4 nm, less than or equal to about 3.5 nm, less than or equal to about 3 nm, less than or equal to about 2.5 nm, less than or equal to about 2 nm, or less than or equal to about 1.5 nm.

In an embodiment, a thickness of the inorganic layer may be appropriately selected. An (average) thickness of the inorganic layer may be less than or equal to about 5 nm, less than or equal to about 4 nm, less than or equal to about 3.5 nm, less than or equal to about 3 nm, less than or equal to about 2.5 nm, less than or equal to about 2 nm, less than or equal to about 1.5 nm, less than or equal to about 1 nm, or less than or equal to about 0.8 nm. An (average) thickness of the inorganic layer may be greater than or equal to about 0.1 nm, greater than or equal to about 0.3 nm, greater than or equal to about 0.5 nm, or greater than or equal to about 0.7 nm. An (average) thickness of the inorganic layer may be in a range of about 0.1 nm to about 5 nm, about 0.3 nm to about 4 nm, about 0.5 nm to about 3.5 nm, about 0.7 nm to about 3 nm, about 0.9 nm to about 2.5 nm, about 1 nm to about 2 nm, about 1.5 nm to about 1.7 nm, or a combination thereof.

The first semiconductor nanocrystal may include silver, a group 13 metal (e.g., indium, gallium, or a combination thereof), and a chalcogen element (e.g., sulfur, optionally selenium). The first semiconductor nanocrystal may include a quaternary alloy semiconductor material based on a group 11-13-16 compound including silver (Ag), indium, gallium, and sulfur. The semiconductor nanoparticle or the first semiconductor nanocrystal may include silver indium gallium sulfide, for example, Ag(InₓGa₁₋ₓ)S₂ (where x is greater than 0 and less than or equal to 1). A mole ratio among respective components in the first semiconductor nanocrystal may be adjusted so that final nanoparticles exhibit a desired composition and optical property.

The second semiconductor nanocrystal may include a group 13 metal (indium, gallium, or a combination thereof) and a chalcogen element (sulfur, optionally selenium).

The second semiconductor nanocrystal may further include silver (Ag). The second semiconductor nanocrystal may include silver, gallium, and sulfur. The second semiconductor nanocrystal may include a ternary alloy semiconductor material including silver, gallium, and sulfur. The second semiconductor nanocrystal may have a composition different from that of the first semiconductor nanocrystal. The second semiconductor nanocrystal may include a group 13-16 compound, a group 11-13-16 compound, or a combination thereof. The group 13-16 compound may include gallium sulfide, gallium selenide, indium sulfide, indium selenide, indium gallium sulfide, indium gallium selenide, indium gallium selenide sulfide, or a combination thereof. A bandgap energy of the second semiconductor nanocrystal may be different from that of the first semiconductor nanocrystal. The second semiconductor nanocrystal may cover at least a portion of the first semiconductor nanocrystal. A bandgap energy of the second semiconductor nanocrystal may be greater than a bandgap energy of the first semiconductor nanocrystal. A bandgap energy of the second semiconductor nanocrystal may be smaller than a bandgap energy of the first semiconductor nanocrystal. A mole ratio among respective components in the second semiconductor nanocrystal may be adjusted so that final nanoparticles exhibit a desired composition and optical property.

The third semiconductor nanocrystal may include zinc, gallium, and sulfur. The third semiconductor nanocrystal may include ZnGaS.

A bandgap energy of the second semiconductor nanocrystal may be smaller than a bandgap energy of the third semiconductor nanocrystal. The second semiconductor nanocrystal may be disposed between the first semiconductor nanocrystal and the inorganic layer (or the third semiconductor nanocrystal). The third semiconductor nanocrystal may be disposed between the second semiconductor nanocrystal and the inorganic layer.

The second semiconductor nanocrystal or the first semiconductor nanocrystal may exhibit crystallinity when observed by an appropriate analytical means (e.g., X-ray diffraction analysis, high-angle annular dark field (HAADF)-scanning transmission electron microscope (STEM) analysis, or other electron microscope analysis). In an embodiment, the first semiconductor nanocrystal or the second semiconductor nanocrystal may be amorphous when observed by an appropriate analytical means.

In an embodiment, a size or an average size (hereinafter, referred to as “particle size”) of the semiconductor nanoparticle may be greater than or equal to about 1 nm, greater than or equal to about 1.5 nm, greater than or equal to about 2 nm, greater than or equal to about 2.5 nm, greater than or equal to about 3 nm, greater than or equal to about 3.5 nm, greater than or equal to about 4 nm, greater than or equal to about 4.5 nm, greater than or equal to about 5 nm, greater than or equal to about 5.5 nm, greater than or equal to about 6 nm, greater than or equal to about 6.5 nm, greater than or equal to about 7 nm, greater than or equal to about 7.5 nm, greater than or equal to about 8 nm, greater than or equal to about 8.5 nm, greater than or equal to about 9 nm, greater than or equal to about 9.5 nm, greater than or equal to about 10 nm, or greater than or equal to about 10.5 nm. The particle size of the semiconductor nanoparticle may be less than or equal to about 50 nm, less than or equal to about 48 nm, less than or equal to about 46 nm, less than or equal to about 44 nm, less than or equal to about 42 nm, less than or equal to about 40 nm, less than or equal to about 35 nm, less than or equal to about 30 nm, less than or equal to about 25 nm, less than or equal to about 20 nm, less than or equal to about 18 nm, less than or equal to about 16 nm, less than or equal to about 14 nm, less than or equal to about 12 nm, less than or equal to about 11 nm, less than or equal to about 10 nm, less than or equal to about 8 nm, less than or equal to about 6 nm, or less than or equal to about 4 nm. Herein, the particle size may refer to a particle diameter. When the nanoparticles or the first semiconductor nanocrystals are not spherical, the particle size may refer to a diameter calculated by converting a two-dimensional area observed by transmission electron microscope analysis into a circle. The size may be a value calculated from the composition and emission wavelength of the nanoparticles.

A method of preparing a semiconductor nanoparticle according to an embodiment may include obtaining a first semiconductor nanocrystal including silver, a group 13 metal, and a chalcogen element; heating a reaction medium including an organic solvent and an organic ligand to a predetermined temperature; and adding the first semiconductor nanocrystal, a first precursor, a second precursor, and a silver compound to the reaction medium, wherein one of the first precursor and the second precursor is a gallium precursor and the other is a sulfur precursor.

In the reaction medium, in the presence of the first semiconductor nanocrystal, contact and reaction among the first precursor, the second precursor, and optionally the silver compound may be performed. In an embodiment, the first precursor may be the gallium precursor and the second precursor may be the sulfur precursor. In an embodiment, the first precursor may be the sulfur precursor and the second precursor may be the gallium precursor. The predetermined temperature may be one or more temperatures.

The predetermined temperature may be a first temperature (e.g., greater than or equal to about 120° C. (greater than or equal to about 180° C.) and less than or equal to about 280° C.), or a reaction temperature. The reaction temperature may be greater than or equal to about 180° C. (greater than or equal to about 190° C., or greater than or equal to about 240° C.) and less than or equal to about 380° C.

A time for the contact or the reaction (hereinafter, referred to as “reaction time”) may be controlled so as to obtain a desired charge balance value of the nanoparticles.

The first temperature may be different from (lower or higher than) the reaction temperature.

In an embodiment, the first semiconductor nanocrystal, the first precursor, the second precursor, and the silver compound may be added at the first temperature, and the obtained mixture may be heated to the reaction temperature. A difference between the first temperature and the reaction temperature may be greater than or equal to about 10° C., greater than or equal to about 20° C., greater than or equal to about 30° C., greater than or equal to about 40° C., greater than or equal to about 50° C., greater than or equal to about 60° C., greater than or equal to about 70° C., greater than or equal to about 80° C., greater than or equal to about 90° C., or greater than or equal to about 100° C. The difference between the first temperature and the reaction temperature may be less than or equal to about 200° C., less than or equal to about 190° C., less than or equal to about 180° C., less than or equal to about 170° C., less than or equal to about 160° C., less than or equal to about 150° C., less than or equal to about 140° C., less than or equal to about 130° C., less than or equal to about 120° C., less than or equal to about 110° C., less than or equal to about 100° C., less than or equal to about 90° C., less than or equal to about 80° C., less than or equal to about 70° C., less than or equal to about 60° C., less than or equal to about 50° C., less than or equal to about 40° C., less than or equal to about 30° C., or less than or equal to about 20° C.

The first temperature may be greater than or equal to about 120° C., greater than or equal to about 200° C., greater than or equal to about 210° C., greater than or equal to about 220° C., greater than or equal to about 230° C., greater than or equal to about 240° C., or greater than or equal to about 250° C. The first temperature may be less than or equal to about 280° C., less than or equal to about 275° C., less than or equal to about 270° C., less than or equal to about 265° C., less than or equal to about 260° C., less than or equal to about 255° C., less than or equal to about 250° C., less than or equal to about 240° C., less than or equal to about 230° C., less than or equal to about 220° C., less than or equal to about 210° C., less than or equal to about 200° C., less than or equal to about 190° C., less than or equal to about 180° C., less than or equal to about 170° C., less than or equal to about 160° C., or less than or equal to about 150° C.

The reaction temperature may be greater than or equal to about 180° C., greater than or equal to about 245° C., greater than or equal to about 250° C., greater than or equal to about 255° C., greater than or equal to about 260° C., greater than or equal to about 265° C., greater than or equal to about 270° C., greater than or equal to about 275° C., greater than or equal to about 280° C., greater than or equal to about 285° C., greater than or equal to about 290° C., greater than or equal to about 295° C., greater than or equal to about 300° C., greater than or equal to about 305° C., greater than or equal to about 310° C., greater than or equal to about 315° C., greater than or equal to about 320° C., greater than or equal to about 330° C., greater than or equal to about 335° C., greater than or equal to about 340° C., or greater than or equal to about 345° C.

The reaction temperature may be less than or equal to about 380° C., less than or equal to about 375° C., less than or equal to about 370° C., less than or equal to about 365° C., less than or equal to about 360° C., less than or equal to about 355° C., less than or equal to about 350° C., less than or equal to about 340° C., less than or equal to about 330° C., less than or equal to about 320° C., less than or equal to about 310° C., less than or equal to about 300° C., less than or equal to about 290° C., less than or equal to about 280° C., less than or equal to about 270° C., less than or equal to about 260° C., or less than or equal to about 250° C.

The reaction time may be controlled in consideration of the first temperature and the reaction temperature so as to obtain a desired charge balance value of the nanoparticles. In the method according to an embodiment, by adjusting the reaction conditions, occurrence of by-products (e.g., gallium oxide) can be effectively suppressed, and the nanoparticles can exhibit a charge balance value (and optionally, mole ratios among respective elements in the semiconductor nanoparticle as described herein).

In an embodiment, the reaction time may be in a range of about 1 minute to about 240 minutes, about 5 minutes to about 200 minutes, about 10 minutes to about 3 hours, about 20 minutes to about 150 minutes, about 30 minutes to about 100 minutes, or a combination thereof. The reaction time may be selected in consideration of types of the precursors, the reaction temperature, a desired composition in the final particles, or the like.

The method according to an embodiment may further include preparing an additional reaction medium including an organic solvent; and adding the formed nanoparticles, a zinc precursor (and optionally a gallium precursor), and a chalcogen precursor to the additional reaction medium while heating the additional reaction medium to the reaction temperature, and further reacting to provide a third semiconductor nanocrystal layer and/or an outer layer including a zinc gallium chalcogenide or a zinc chalcogenide on a surface of the nanoparticles. The chalcogen precursor may include a sulfur precursor, a selenium precursor, or a combination thereof. The temperature for the additional reaction may refer to the description provided for the reaction temperature.

Details of regarding the first semiconductor nanocrystal are as described herein. The first semiconductor nanocrystal may include silver (Ag), indium, gallium, and sulfur. A method of manufacturing the first semiconductor nanocrystal is not particularly limited and may be appropriately selected.

In an embodiment, the first semiconductor nanocrystal may be obtained by reacting necessary precursors according to a composition, for example, a silver precursor, an indium precursor, a gallium precursor, and a sulfur precursor, in a solution including an organic ligand and an organic solvent at a predetermined reaction temperature (e.g., about 20° C. to about 300° C., about 80° C. to about 295° C., about 120° C. to about 290° C., or about 200° C. to about 280° C.), and separating the resulting product. For the separation and recovery, reference may be made to the method described later herein.

In preparation of the first semiconductor nanocrystal, a mole ratio among the respective precursors may be adjusted to obtain a desired composition of the first semiconductor nanocrystal. In an embodiment, an amount of the silver precursor based on 1 mole of indium may be greater than or equal to about 0.1 mole, greater than or equal to about 0.3 mole, greater than or equal to about 0.5 mole, greater than or equal to about 0.7 mole, greater than or equal to about 1 mole, greater than or equal to about 1.5 moles, greater than or equal to about 2 moles, or greater than or equal to about 2.5 moles.

In an embodiment, an amount of the silver precursor based on 1 mole of indium may be less than or equal to about 10 moles, less than or equal to about 8 moles, less than or equal to about 6 moles, less than or equal to about 4 moles, less than or equal to about 2 moles, less than or equal to about 1.2 moles, less than or equal to about 1 mole, or less than or equal to about 0.5 mole.

In an embodiment, an amount of the gallium precursor based on 1 mole of indium may be greater than or equal to about 0.5 mole, greater than or equal to about 1 mole, greater than or equal to about 1.5 moles, greater than or equal to about 2 moles, or greater than or equal to about 2.5 moles.

In an embodiment, an amount of the gallium precursor based on 1 mole of silver may be less than or equal to about 15 moles, less than or equal to about 12 moles, less than or equal to about 10 moles, less than or equal to about 8 moles, less than or equal to about 5 moles, or less than or equal to about 3 moles.

In an embodiment, an amount of the sulfur precursor based on 1 mole of indium may be greater than or equal to about 0.5 mole, greater than or equal to about 1 mole, greater than or equal to about 1.5 moles, greater than or equal to about 2 moles, greater than or equal to about 2.5 moles, greater than or equal to about 3 moles, greater than or equal to about 3.5 moles, greater than or equal to about 4 moles, or greater than or equal to about 4.5 moles. In an embodiment, an amount of the sulfur precursor based on 1 mole of indium may be less than or equal to about 20 moles, less than or equal to about 15 moles, less than or equal to about 10 moles, less than or equal to about 8 moles, less than or equal to about 6 moles, less than or equal to about 4 moles, or less than or equal to about 2 moles.

In the method, the core or the first semiconductor nanocrystal may be dispersed in an appropriate organic solvent (e.g., an aliphatic hydrocarbon solvent) and then added thereto.

An amount of the silver compound may be adjusted in consideration of a content of the core, a desired absorption property in the final particles, and a desired composition of the semiconductor nanoparticles. An amount of the silver compound may be greater than or equal to about 0.1 mole percent (mol %) based on the gallium precursor. The silver compound may be added to the medium in an amount greater than or equal to about 0.1 mol %, for example, greater than or equal to about 0.5 mol % and less than or equal to about 100 mol %, or less than or equal to about 70 mol %, or less than or equal to about 50 mol %, for example, less than or equal to about 25 mol % based on the gallium precursor. The amount of the silver compound may be greater than or equal to about 1 mol % and less than or equal to about 12 mol %. The silver compound may be added to the reaction medium in an amount greater than or equal to about 0.5 mol % based on the gallium precursor. The amount of the silver compound may be greater than or equal to about 1 mol %, greater than or equal to about 1.5 mol %, greater than or equal to about 2 mol %, greater than or equal to about 2.5 mol %, greater than or equal to about 3 mol %, greater than or equal to about 4 mol %, greater than or equal to about 5 mol %, greater than or equal to about 6 mol %, greater than or equal to about 7 mol %, greater than or equal to about 8 mol %, greater than or equal to about 9 mol %, greater than or equal to about 10 mol %, greater than or equal to about 11 mol %, greater than or equal to about 12 mol %, greater than or equal to about 13 mol %, greater than or equal to about 14 mol %, or greater than or equal to about 15 mol % based on the gallium precursor. The amount of the silver compound may be less than or equal to about 50 mol %, less than or equal to about 30 mol %, less than or equal to about 25 mol %, less than or equal to about 20 mol %, less than or equal to about 18 mol %, less than or equal to about 17 mol %, less than or equal to about 16 mol %, less than or equal to about 15 mol %, less than or equal to about 14 mol %, less than or equal to about 13 mol %, less than or equal to about 12 mol %, less than or equal to about 11 mol %, less than or equal to about 10 mol %, less than or equal to about 9 mol %, less than or equal to about 8 mol %, less than or equal to about 7 mol %, less than or equal to about 6 mol %, less than or equal to about 5 mol %, less than or equal to about 4 mol %, or less than or equal to about 3 mol % based on the gallium precursor. The amount of the silver compound may be greater than or equal to about 1 mol % and less than or equal to about 12 mol %.

A type of the silver precursor or the silver compound is not particularly limited and may be appropriately selected. The silver precursor or the silver compound may include a silver powder, an alkylated silver compound, a silver alkoxide, a silver carboxylate, a silver acetylacetonate, a silver nitrate, a silver sulfate, a silver halide, a silver cyanide, a silver hydroxide, a silver oxide, a silver peroxide, a silver carbonate, or a combination thereof. The silver precursor may include a silver nitrate, a silver acetate, a silver acetylacetonate, a silver chloride, a silver bromide, a silver iodide, or a combination thereof.

A type of the indium precursor is not particularly limited and may be selected appropriately. The indium precursor may include an indium powder, an alkylated indium compound, an indium alkoxide, an indium carboxylate, an indium nitrate, an indium perchlorate, an indium sulfate, an indium acetylacetonate, an indium halide, an indium cyanide, an indium hydroxide, an indium oxide, an indium peroxide, an indium carbonate, an indium acetate, or a combination thereof, The indium precursor may include an indium carboxylate such as indium oleate and indium myristate, an indium acetate, an indium hydroxide, an indium chloride, an indium bromide, an indium iodide, or a combination thereof.

A type of the gallium precursor is not particularly limited and may be appropriately selected. The gallium precursor may include a gallium powder, an alkylated gallium compound, a gallium alkoxide, a gallium carboxylate, a gallium nitrate, a gallium perchlorate, a gallium sulfate, a gallium acetylacetonate, a gallium halide, a gallium cyanide, a gallium hydroxide, a gallium oxide, a gallium peroxide, a gallium carbonate, or a combination thereof. The gallium precursor may include a gallium chloride, a gallium iodide, a gallium bromide, a gallium acetate, a gallium acetylacetonate, a gallium oleate, a gallium palmitate, a gallium stearate, a gallium myristate, a gallium hydroxide, or a combination thereof.

A type of the sulfur precursor is not particularly limited and may be appropriately selected, The sulfur precursor may be an organic solvent dispersion or a reaction product of sulfur and an organic solvent, for example, a octadecene sulfide (S-ODE), a trioctylphosphine-sulfide (S-TOP), a tributylphosphine-sulfide (S-TBP), a triphenylphosphine-sulfide (S-TPP), a trioctylamine-sulfide (S-TOA), a bis(trimethylsilylalkyl) sulfide, a bis(trimethylsilyl) sulfide, a mercapto propyl silane, an ammonium sulfide, a sodium sulfide, a C1-C30 thiol compound (e.g., α-toluene thiol, octane thiol, dodecanethiol, octadecene thiol, or the like), an isothiocyanate compound (e.g., cyclohexyl isothiocyanate or the like), an alkylenetrithiocarbonate (e.g., ethylene trithiocarbonate or the like), allyl mercaptan, a thiourea compound (e.g., (di)alkylthiourea having a C1 to C40 alkyl group, for example, methylthiourea, dimethylthiourea, ethylthiourea, diethyl thiourea, ethyl methyl thiourea, dipropyl thiourea, or the like; or an arylthiourea such as a phenyl thiourea), or a combination thereof.

The selenium precursor, if present, may include selenium-trioctylphosphine (Se-TOP), selenium-tributylphosphine (Se-TBP), selenium-triphenylphosphine (Se-TPP), or a combination thereof,

A type of the zinc precursor is not particularly limited and may be appropriately selected. In an embodiment, the zinc precursor may include a Zn metal powder, an alkylated Zn compound, a Zn alkoxide, a Zn carboxylate, a Zn nitrate, a Zn perchlorate, a Zn sulfate, a Zn acetylacetonate, a Zn halide, a Zn cyanide, a Zn hydroxide, a Zn oxide, a Zn peroxide, or a combination thereof, The zinc precursor may be dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, or a combination thereof.

The organic ligand may include R³COOH, R³NH₂, R³₂NH, R³₃N, R³SH, R³H₂PO, R³₂HPO, R³₃PO, R³H₂P, R³₂HP, R³₃P, R³OH, R³COOR⁴, R³PO (OH)₂, R³HPOOH, R³₂POOH, or a combination thereof, wherein R³ and R⁴ are each independently substituted or unsubstituted C1 to C40 (or C3 to C24), an aliphatic hydrocarbon group (e.g., alkyl group, alkenyl group, or alkynyl group), or a substituted or unsubstituted C6 to C40 (or a C6 to C24) aromatic hydrocarbon group (e.g., a C6 to C20 aryl group), or a combination thereof. The organic ligand may be bound (e.g., linked) to the surface of the semiconductor nanoparticle. In an aspect, the organic ligand may be in contact with or adjacent to the surface of the semiconductor nanoparticle. The organic ligand may be a ligand (i.e., a native ligand) bonded to the surface of the semiconductor nanoparticle as prepared. The native ligand may be introduced in the manufacturing process of semiconductor nanoparticle such as quantum dots and can coordinate a surface of the semiconductor nanoparticle. Non-limiting examples of the organic ligand may include methane thiol, ethane thiol, propane thiol, butane thiol, pentane thiol, hexane thiol, heptane thiol, octane thiol, nonanethiol, decanethiol, dodecane thiol, hexadecane thiol, octadecane thiol, benzyl thiol; methyl amine, ethyl amine, propyl amine, butyl amine, pentyl amine, hexyl amine, octyl amine, dodecyl amine, hexadecyl amine, octadecyl amine, dimethyl amine, diethyl amine, dipropyl amine; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid; substituted or unsubstituted methyl phosphine (e.g., trimethyl phosphine, methyldiphenyl phosphine, or the like), substituted or unsubstituted ethyl phosphine (e.g., triethyl phosphine, ethyldiphenyl phosphine, or the like), substituted or unsubstituted propyl phosphine, substituted or unsubstituted butyl phosphine, substituted or unsubstituted pentyl phosphine, substituted or unsubstituted octylphosphine (e.g., trioctylphosphine (TOP)), or the like; a phosphine oxide such as substituted or unsubstituted methyl phosphine oxide (e.g., trimethyl phosphine oxide, methyldiphenylphosphine oxide, or the like), substituted or unsubstituted ethyl phosphine oxide (e.g., triethyl phosphine oxide, ethyldiphenyl phosphine oxide, or the like), substituted or unsubstituted propyl phosphine oxide, substituted or unsubstituted butyl phosphine oxide, substituted or unsubstituted octylphosphine oxide (e.g., trioctylphosphine oxide (TOPO), or the like); diphenyl phosphine, a triphenyl phosphine, or an oxide compound thereof; a C5 to C20 alkylphosphinic acid or a C5 to C20 alkyl phosphonic acid such as phosphonic acid, hexylphosphinic acid, octylphosphinic acid, dodecanephosphinic acid, tetradecanephosphinic acid, hexadecanephosphinic acid, octadecanephosphinic acid, or the like, but embodiments are not limited thereto, The organic ligand may be used alone or as a combination of two or more,

The organic solvent may include an amine solvent (e.g., an aliphatic amine for example having a C1 to C50 aliphatic amine); a nitrogen-containing heterocyclic compound such as pyridine; a C6 to C40 aliphatic hydrocarbon (e.g., alkane, alkene, alkyne, or the like) such as hexadecane, octadecane, octadecene, or squalene; a C6 to C30 aromatic hydrocarbon such as phenyldodecane, phenyltetradecane, phenyl hexadecane, or the like; a phosphine substituted with a C6 to C22 alkyl group such as trioctylphosphine; a phosphine oxide substituted with a C6 to C22 alkyl group such as trioctylphosphine oxide, or the like; a C12 to C22 aromatic ether such as phenyl ether, or benzyl ether, or the like; or a combination thereof, The amine solvent may be a compound having one or more (e.g., two or three) C1-C50, C2-C45, C3-C40, C4-C35, C5-C30, C6-C25, C7-C20, C8-C15, or C6-C22 aliphatic hydrocarbon groups (alkyl group, alkenyl group, or alkynyl group), In an embodiment, the amine solvent may be a C6-C22 primary amine such as hexadecyl amine and oleylamine; a C6-C22 secondary amine such as dioctyl amine or the like; a C6-C22 tertiary amine such as trioctylamine or the like; or a combination thereof,

The amounts of the organic ligand and each precursor in the reaction medium may be appropriately selected in consideration of the type of solvent, the types of the organic ligand and each precursor, the desired size and composition of the particles, and the like. The mole ratio among the precursors may be appropriately selected in consideration of the desired mole ratio in the final nanoparticles, the reactivity among the precursors, and the like. The method of adding each precursor is not particularly limited, and may be divided and injected one or more times, preferably from 2 times to less than or equal to about 10 times. Each of the precursors may be added simultaneously or sequentially. The reaction may be carried out in an inert gas atmosphere, in air, or under vacuum, but is not limited thereto.

In an embodiment, after the completion of the reaction, a nonsolvent may be added to a final reaction solution to facilitate separation (e.g., precipitation) of the semiconductor nanoparticle as synthesized (for example, with a coordinating organic ligand). The nonsolvent may be a polar solvent that is miscible with the solvent used in the reaction, but cannot disperse the semiconductor nanoparticle, The nonsolvent may be selected depending on the solvent used in the reaction and may be for example, acetone, ethanol, butanol, isopropanol, ethanediol, water, tetrahydrofuran (THF), dimethylsulfoxide (DMSO), diethylether, formaldehyde, acetaldehyde, a solvent having a similar solubility parameter to the foregoing solvents, or a combination thereof. The separation may be performed by centrifugation, precipitation, chromatography, or distillation. Separated semiconductor nanoparticle may be washed by adding to a washing solvent as needed. The washing solvent is not particularly limited, and a solvent having a solubility parameter similar to that of the organic solvent or ligand may be used. The nonsolvent or washing solvent may be an alcohol; an alkane solvent such as hexane, heptane, octane, or the like; an aromatic solvent such as; toluene, benzene, or the like; a haloalkane solvent such as chloroform, or the like; or a combination thereof, but embodiments are not limited thereto.

The semiconductor nanoparticle may be dispersed in a dispersion solvent. The semiconductor nanoparticle may form an organic solvent dispersion. The organic solvent dispersion may include or may not include water and/or an organic solvent miscible with water. The dispersion solvent may be appropriately selected. The dispersion solvent may include the above-described organic solvent. The dispersion solvent may include a substituted or unsubstituted C1 to C40 aliphatic hydrocarbon, a substituted or unsubstituted C6 to C40 aromatic hydrocarbon, or a combination thereof.

The shape of the semiconductor nanoparticle is not particularly limited and may include, for example, a spherical shape, a polyhedral shape, a pyramidal shape, a multipod shape, or a cubic shape, a nanotube, a nanowire, a nanofiber, a nanosheet, or a combination thereof, but is not limited thereto.

The semiconductor nanoparticle of an embodiment may be configured to emit light of a desired wavelength while exhibiting an improved physical property. The light may be green light or second light. The light may include a band-edge emission.

The peak emission wavelength of the light may be greater than or equal to about 500 nm, greater than or equal to about 505 nm, greater than or equal to about 510 nm, greater than or equal to about 515 nm, greater than or equal to about 520 nm, greater than or equal to about 525 nm, greater than or equal to about 530 nm, greater than or equal to about 535 nm, greater than or equal to about 540 nm, greater than or equal to about 545 nm, greater than or equal to about 550 nm, greater than or equal to about 555 nm, greater than or equal to about 560 nm, greater than or equal to about 565 nm, greater than or equal to about 570 nm, greater than or equal to about 575 nm, greater than or equal to about 580 nm, greater than or equal to about 585 nm, greater than or equal to about 590 nm, or greater than or equal to about 600 nm. The peak emission wavelength of the light may be less than or equal to about 650 nm, less than or equal to about 620 nm, less than or equal to about 600 nm, less than or equal to about 595 nm, less than or equal to about 590 nm, less than or equal to about 580 nm, less than or equal to about 575 nm, less than or equal to about 570 nm, less than or equal to about 565 nm, less than or equal to about 560 nm, less than or equal to about 555 nm, less than or equal to about 550 nm, less than or equal to about 545 nm, less than or equal to about 540 nm, less than or equal to about 535 nm, less than or equal to about 530 nm, less than or equal to about 525 nm, less than or equal to about 520 nm, or less than or equal to about 515 nm.

The spectrum of the light or the semiconductor nanoparticle may have a full width at half maximum (FWHM) greater than or equal to about 5 nm, greater than or equal to about 10 nm, greater than or equal to about 15 nm, greater than or equal to about 20 nm, greater than or equal to about 25 nm, or greater than or equal to about 30 nm. The FWHM may be less than or equal to about 70 nm, less than or equal to about 65 nm, less than or equal to about 60 nm, less than or equal to about 55 nm, less than or equal to about 50 nm, less than or equal to about 45 nm, less than or equal to about 40 nm, less than or equal to about 38 nm, less than or equal to about 36 nm, less than or equal to about 35 nm, less than or equal to about 34 nm, less than or equal to about 33 nm, less than or equal to about 32 nm, less than or equal to about 31 nm, less than or equal to about 30 nm, less than or equal to about 29 nm, less than or equal to about 28 nm, less than or equal to about 27 nm, less than or equal to about 26 nm, or less than or equal to about 25 nm.

The semiconductor nanoparticle may exhibit a quantum yield or quantum efficiency (hereinafter, referred to as “quantum yield”) of greater than or equal to about 50%. The quantum yield may be an absolute quantum yield. The quantum yield may be greater than or equal to about 55%, greater than or equal to about 60%, greater than or equal to about 65%, greater than or equal to about 70%, greater than or equal to about 75%, greater than or equal to about 80%, greater than or equal to about 85%, greater than or equal to about 90%, or greater than or equal to about 95%. The quantum yield may be less than or equal to about 100%, less than or equal to about 99.5%, less than or equal to about 99%, less than or equal to about 98%, or less than or equal to about 97%.

The semiconductor nanoparticle may have a ratio of absorbance at 530 nm to the absorbance at 350 nm (Abs 530/Abs 350) in a UV-Vis absorption spectrum of less than or equal to about 0.3:1, less than or equal to about 0.25:1, less than or equal to about 0.2:1, less than or equal to about 0.15:1, less than or equal to about 0.14:1, less than or equal to about 0.13:1, less than or equal to about 0.12:1, less than or equal to about 0.11:1, less than or equal to about 0.1:1, less than or equal to about 0.09:1, less than or equal to about 0.08:1, less than or equal to about 0.07:1, less than or equal to about 0.06:1, less than or equal to about 0.055:1, less than or equal to about 0.05:1, less than or equal to about 0.045:1, less than or equal to about 0.04:1, less than or equal to about 0.035:1, less than or equal to about 0.03:1, less than or equal to about 0.025:1, or less than or equal to about 0.02:1. The semiconductor nanoparticle may have a ratio of absorbance at 530 nm to the absorbance at 350 nm (Abs 530/Abs 350) in a UV-Vis absorption spectrum of greater than or equal to about 0.001:1, greater than or equal to about 0.005:1, greater than or equal to about 0.008:1, greater than or equal to about 0.01:1, greater than or equal to about 0.012:1, greater than or equal to about 0.015:1, greater than or equal to about 0.018:1, greater than or equal to about 0.019:1, greater than or equal to about 0.02:1, greater than or equal to about 0.025:1, greater than or equal to about 0.03:1, greater than or equal to about 0.035:1, or greater than or equal to about 0.04:1.

The semiconductor nanoparticle may have a ratio of absorbance at 450 nm to the absorbance at 350 nm (Abs 450/Abs 350) in a UV-Vis absorption spectrum of less than or equal to about 0.5:1, less than or equal to about 0.4:1, less than or equal to about 0.38:1, less than or equal to about 0.35:1, less than or equal to about 0.32:1, less than or equal to about 0.3:1, less than or equal to about 0.29:1, less than or equal to about 0.28:1, less than or equal to about 0.27:1, less than or equal to about 0.26:1, less than or equal to about 0.25:1, less than or equal to about 0.24:1, or less than or equal to about 0.23:1. The semiconductor nanoparticle may have a ratio of absorbance at 450 nm to the absorbance at 350 nm (Abs 450/Abs 350) in a UV-Vis absorption spectrum of greater than or equal to about 0.05:1, greater than or equal to about 0.09:1, greater than or equal to about 0.1:1, greater than or equal to about 0.12:1, greater than or equal to about 0.15:1, greater than or equal to about 0.16:1, greater than or equal to about 0.17:1, greater than or equal to about 0.18:1, greater than or equal to about 0.19:1, greater than or equal to about 0.2:1, greater than or equal to about 0.22:1, greater than or equal to about 0.23:1, greater than or equal to about 0.25:1, or greater than or equal to about 0.28:1.

A first composite of an embodiment may be manufactured from a composition (e.g., an ink composition) including a semiconductor nanoparticle (e.g., into a solid state through polymerization or the like). The ink composition or the semiconductor nanoparticle may include a first organic ligand. The first organic ligand includes a compound represented by R₁—COO-A, where R₁ is a first organic group and A is a portion that is hydrogen or contacts (e.g., binds to) the surface of the semiconductor nanoparticle. The ink composition or the semiconductor nanoparticle may further include a second organic ligand. The second organic ligand may include a compound represented by R₂S-A, where R₂ is a second organic group and A is a portion that is hydrogen or contacts (e.g., binds to) the surface of the semiconductor nanoparticle.

The first organic ligand may include a C3 to C500 (e.g., C4-C100, C4-C50, C5-C12) carboxyalkyl (meth)acrylate. The first organic ligand may include a small molecule compound (e.g., a non-polymeric compound) having a molecular weight greater than or equal to about 10 grams per mole (g/mol), greater than or equal to about 50 g/mol, or greater than or equal to about 120 g/mol, and less than or equal to about 800 g/mol, less than or equal to about 500 g/mol, less than or equal to about 400 g/mol, less than or equal to about 300 g/mol, or less than or equal to about 250 g/mol.

The second organic ligand may include a C3 to C500 (e.g., C4-C100, C4-C50, C5-C12) carboxylic acid alkyl ester including a thiol group.

In an embodiment, an organic ligand may be bound to the surface of a semiconductor nanoparticle, and the organic ligand may not be separated from the nanoparticle even after stirring the semiconductor nanoparticle for a predetermined time (e.g., for a time of 30 minutes to 3 hours, 1 hour to 2 hours, or a time of a combination thereof) in a poor solvent or a solvent. Without wishing to be bound by any theory, it is believed that a carboxyl group of the first organic ligand and a thiol group of the second organic ligand may be bound to a metal (e.g., gallium, zinc, or a combination thereof) present on the surface of the semiconductor nanoparticle in the form of a carboxylate or thiolate to passivate the surface.

The first organic group may be a substituted or unsubstituted C₁₋₅₀₀, C₂₋₃₀₀, C₃₋₁₀₀, C₄₋₅₀, or C₅₋₁₀ hydrocarbon group and, optionally, for example, in a backbone thereof, at least one methylene may be replaced with —CO—, —O—, —COO—, —S—, —SO—, —NHCO—, or a combination thereof.

The first organic ligand may include a carboxylic acid compound represented by R₁—COOH or a moiety derived therefrom (e.g., a carboxylate group). The first organic group may include a carbon-carbon double bond-containing moiety. The carbon-carbon double bond-containing moiety may include a (meth)acrylate group. The first organic group or the first organic ligand may include or may not include a piperidine moiety, an amine moiety (e.g., —NR—, R is hydrogen or a C1-C10 hydrocarbon group), an amide moiety, or a combination thereof.

The first organic group or R₁ may include a moiety represented by E1-L-*, wherein E1 may be hydrogen, a substituted or unsubstituted C1 to C10 alkyl group, a substituted or unsubstituted C2 to C10 alkenyl group, a (meth)acrylate group, or a combination thereof, and L may be a direct (e.g., single) bond, a substituted or unsubstituted C1-C50, C3-C40, C5-C15, C7-C14, or C10-C12 hydrocarbon group (e.g., an alkylene group, an alkenylene group, or an alkynylene group), [R³—O]n (R³ is ethylene, propylene, isopropylene, or a combination thereof, n is 1 to 140, 2-10, 3-7, or 4-6), —CO—, —O—, —SO—, —COO—, —S—, —NHCO—, or a combination thereof, and * is a portion linked to an adjacent atom (e.g., a carbonyl carbon). The L may be a moiety formed by combining at least two of a substituted or unsubstituted C1 to C50 alkylene group, [R³—O]n (R³ is ethylene, propylene, isopropylene, or a combination thereof, n is 1 to 140, 2-10, 3-7, or 4-6), —CO—, —O—, —SO—, —COO—, —S—, and —NHCO—.

The first organic ligand may include a carboxylic acid compound represented by Chemical Formula 2-1 or Chemical Formula 2-2; or a group or moiety derived from the carboxylic acid compound (e.g., represented by Chemical Formula 2-3 or represented by chemical formula 2-4):

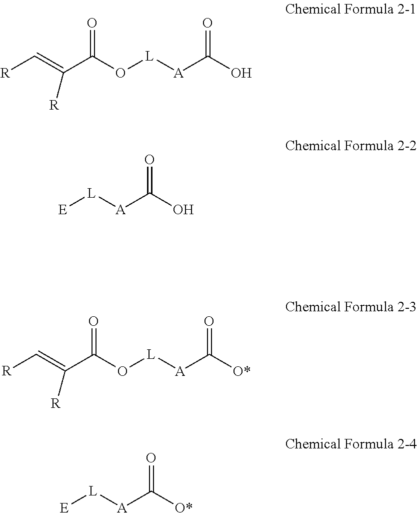

wherein, in each Chemical Formula 2-1, Chemical Formula 2-2, Chemical Formula 2-3, Chemical Formula 2-4, independently,
R is the same or different and is independently hydrogen or a C1 to C10 alkyl (e.g., methyl) group,
E is hydrogen or a substituted or unsubstituted C1 to C10 or C6 to C8 (e.g., aliphatic or aromatic) hydrocarbon group (e.g., an alkyl such as methyl, an alkenyl, or an alkynyl group),
L is a direct bond, a substituted or unsubstituted C1-C50, C3-C40, C5-C15, C7-C14, or C10-C12 hydrocarbon group (e.g., an alkylene group, an alkenylene group, or an alkynylene group), [R³—O]n (R³ is ethylene, propylene, isopropylene, or a combination thereof, n is 1 to 140, 2-10, 3-7, or 4-6), —CO—, —O—, —SO—, —COO—, —S—, —NHCO—, or a combination thereof (e.g., a moiety formed by combining at least two of the foregoing groups),
A is a direct bond, a substituted or unsubstituted C1-C50, C3-C40, C5-C15, or C7-C14 hydrocarbon group (e.g., an alkylene group, an alkenylene group, or an alkynylene group), [R³—O]n (R³ is ethylene, propylene, isopropylene, or a combination thereof, n is 1 to 140, 2-10, 3-7, or 4-6), —CO—, —O—, —SO—, —COO—, —S—, —NHCO—, or a combination thereof (e.g., a moiety formed by combining at least two of the foregoing groups), and
* is a portion to linked (e.g., a point of attachment) to the semiconductor nanoparticle.

In the compound, the COOH group may be converted into COO⁻ (e.g., carboxylate) for the ligand to be bonded to the surface of the semiconductor nanoparticle.

In the definition of L or A, at least one methylene in the hydrocarbon group can be replaced by —CO—, —O—, —SO—, —COO—, —S—, —NHCO—, or a combination thereof (e.g., a moiety formed by combining at least two of the foregoing groups).

The first organic ligand may include a compound represented by any of the following formulas or a moiety (e.g., a carboxylate moiety) derived therefrom:

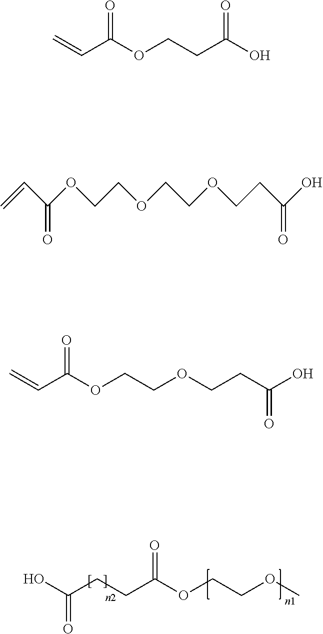

wherein n1 is an integer from 1 to 100, 3-80, 5-70, 7-60, 9-50, 10-45, or 15-35, and n2 is an integer from 1 to 20, 2-15, or 3-10.

The first organic ligand may include a small molecular compound (e.g. a non-polymeric compound) that has a molecular weight of greater than or equal to about 10 g/mol, greater than or equal to about 50 g/mol, or greater than or equal to about 120 g/mol, and less than or equal to about 800 g/mol, less than or equal to about 500 g/mol, less than or equal to about 400 g/mol, less than or equal to about 300 g/mol, or less than or equal to about 250 g/mol.

The ink composition or the semiconductor nanoparticle may further include a second organic ligand different from the first organic ligand. The second organic ligand may bound to a surface of the semiconductor nanoparticle. The second organic ligand may include a compound represented by R₂—SA, wherein R² is a second organic group and A is hydrogen or a portion linked to a surface of the semiconductor nanoparticle.

The second organic group may be a substituted or unsubstituted C₁₋₅₀₀, C₂₋₃₀₀, C₃₋₁₀₀, C₄₋₅₀, or C₅₋₁₀ hydrocarbon group and, optionally, for example in a backbone thereof, at least one methylene may be replaced with —CO—, —O—, —COO—, —S—, —SO—, —NHCO—, or a combination thereof.

The second organic ligand may include a thiol compound represented by R₂—SH or a moiety derived therefrom (e.g., a thiolate group). The second organic group may further include an alkoxy carbonyl moiety. The second organic group or the second organic ligand may include or may not include a piperidine moiety, an amine moiety (e.g., —NR—, R is hydrogen or a C1-C10 hydrocarbon group such as an alkyl group), an amide moiety, or a combination thereof.

The second organic group or R₂ may include a moiety represented by E2-L-*, wherein E2 may be hydrogen, a substituted or unsubstituted C₁ to C10 alkyl group, a substituted or unsubstituted C1 to C10 alkoxy group, or a combination thereof, and L may be a direct bond, a substituted or unsubstituted C1 to C50 hydrocarbon group (e.g., an alkylene group, an alkenylene group, or an alkynylene group), [R³—O]n (R³ is ethylene, propylene, isopropylene, or a combination thereof, n is 1 to 140), —CO—, —O—, —SO—, —COO—, —S—, —NHCO—, or a combination thereof, and * is a portion linked to an adjacent atom (e.g., sulfur). The L may be a moiety formed by combining at least two of a substituted or unsubstituted C1 to C50 alkylene group, [R³—O]n (R³ is ethylene, propylene, isopropylene, or a combination thereof, n is 1 to 140), —CO—, —O—, —SO—, —COO—, —S—, and —NHCO—.

The second organic ligand may include a compound represented by Chemical Formula 3:

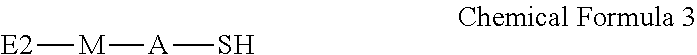

wherein E2 is hydrogen, a substituted or unsubstituted C1 to C10 alkyl (e.g., methyl) group, or a substituted or unsubstituted C1 to C10 alkoxy (e.g., methoxy) group,
M is a direct bond, a substituted or unsubstituted C1 to C50 hydrocarbon group (e.g., an alkylene group, an alkenylene group, or an alkynylene group), [R³—O]n (R³ is ethylene, propylene, isopropylene, or a combination thereof, n is 1 to 140), —CO—, —O—, —SO—, —COO—, —S—, —NHCO—, or a combination thereof (e.g., a moiety formed by combining at least two of the foregoing groups), and
A is a direct bond, a substituted or unsubstituted C1 to C50 hydrocarbon group (e.g., an alkylene group, an alkenylene group, or an alkynylene group), [R³—O]n (R³ is ethylene, propylene, isopropylene, or a combination thereof, n is 1 to 140), —CO—, —O—, —SO—, —COO—, —S—, —NHCO—, or a combination thereof (e.g., a moiety formed by combining at least two of the foregoing groups).

In the compound of the embodiment, the SH group may be converted into S (e.g., thiolate) for the ligand to be bonded to the surface of the semiconductor nanoparticle.

In the definition of M or A, at least one methylene in the hydrocarbon group can be replaced by —CO—, —O—, —SO—, —COO—, —S—, —NHCO—, or a combination thereof (e.g., a moiety formed by combining at least two of the foregoing groups).

The second organic ligand may include a compound represented by Chemical Formula 3-1 or a moiety derived therefrom:

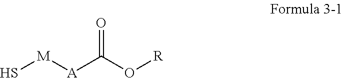

wherein, R is a substituted or unsubstituted C₁ to C10 alkyl (e.g., methyl) group, and
M and A are the same as defined above.

The first organic ligand and the second organic ligand may be readily prepared or synthesized by any known method or may be commercially available.

In an embodiment, the semiconductor nanoparticle may further include a native ligand derived from an organic ligand compound used in its synthesis process, such as an amine compound (e.g., a primary amine having one aliphatic alkyl group such as an oleyl amine). Examples of the organic ligand compound for the native ligands are the same as described herein.

In the ink composition of an embodiment, the semiconductor nanoparticle together with the first organic ligand and optionally the second organic ligand (for example, bound to a surface thereof) may be relatively readily dispersed in a liquid vehicle (e.g., including a monomer or a solvent if present) for an inkjet ink composition,

The second organic ligand may exist or may not exist in the composition.

A mole ratio between the first organic ligand and the second organic ligand may be 1: from about 0 to about 100, 1: from about 0.05 to about 80, 1: from about 0.1 to about 50, 1: from about 0.15 to about 40, 1: from about 0.2 to about 30, 1: from about 0.3 to about 25, 1: from about 0.5 to about 20, 1: from about 0.7 to about 15, 1: from about 0.8 to about 10, 1: from about 0.9 to about 8, 1: from about 1 to about 5, or a combination thereof.

In an embodiment, the composition may further include the second organic ligand and a mole ratio between the second organic ligand (e.g., a thiol based ligand) and the first organic ligand (e.g., a carboxylic acid based ligand) (the second organic ligand: the first organic ligand) may be 1: from about 0.1 to about 1000, 1: from about 0.5 to about 100, 1: from about 0.7 to about 50, 1: from about 0.8 to about 40, 1: from about 1 to about 30, 1: from about 2 to about 20, 1: from about 2.5 to about 10, 1: from about 3 to about 8, or 1: from about 4 to about 6. The mole ratio between the second organic ligand and the first organic ligand (the second organic ligand: the first organic ligand) may be 1: greater than or equal to about 0.6, 1: greater than or equal to about 1.1, 1: greater than or equal to about 1.2, 1: greater than or equal to about 1.5, 1: greater than or equal to about 1.8, or 1: greater than or equal to about 2 and 1: less than or equal to about 10, 1: less than or equal to about 9, 1: less than or equal to about 8, 1: less than or equal to about 7, 1: less than or equal to about 6, 1: less than or equal to about 5, 1: less than or equal to about 4, 1: less than or equal to about 3, 1: less than or equal to about 2, or 1: less than or equal to about 1.

The semiconductor nanoparticle containing the first organic ligand and optionally the second organic ligand (e.g., bound to a surface thereof) can be obtained according to the method described herein. The method may involve a ligand exchange reaction. The ligand may be bound or linked to the semiconductor nanoparticle (e.g., a surface of the semiconductor nanoparticle).

Therefore, in an embodiment, a method of manufacturing an ink composition includes mixing the semiconductor nanoparticle with the monomer together with a first organic ligand and, optionally, a second organic ligand (e.g., containing the same), wherein the semiconductor nanoparticle containing the first organic ligand and, optionally, the second organic ligand is obtained by admixing a semiconductor nanocrystal particle including a Group 11-13-16 compound in an organic solvent with the first organic ligand compound (and, optionally, the second organic ligand) and a zinc salt compound (e.g., a zinc halide or a second zinc salt compound) to obtain a semiconductor nanoparticle containing the first organic ligand (e.g., surface-treated with the first organic ligand). The first organic ligand (and, optionally, the second organic ligand) may be bound to the surface of the semiconductor nanoparticle.

The semiconductor nanocrystal particle containing the Group 11-13-16 compound may include a zinc salt-treated nanocrystal particle, which may be obtained by contacting a nanocrystal particle containing the Group 11-13-16 compound with a first zinc salt compound (for example, in the absence of the first organic ligand) at a first temperature in a first organic solvent.

The method may further include preparing a dispersion in which the zinc salt-treated nanocrystal particle is dispersed the organic solvent. During the mixing, a ligand exchange reaction (with the first organic ligand and optionally the second organic ligand) may occur on the surface of the semiconductor nanoparticle. The method may further include adding the second organic ligand, for example, to the dispersion during the mixing. The ligand exchange reaction may be performed in the presence of the second organic ligand. The semiconductor nanoparticle may include the first organic ligand and optionally the second organic ligand bound to the surface.

The semiconductor nanoparticle includes a first semiconductor nanocrystal and may further include a second semiconductor nanocrystal, an inorganic layer including a zinc chalcogenide, or a combination thereof. Details regarding the first semiconductor nanocrystal, the second semiconductor nanocrystal, the inorganic layer, the outermost layer, and the manufacture of the nanocrystal particle can be referred to as described herein.

In the method of an embodiment, the ligand exchange reaction may involve the use of a zinc salt compound. In an embodiment, the ligand exchange reaction is performed in the presence of a zinc salt compound to obtain a semiconductor nanoparticle having the first organic ligand and optionally the second organic ligand bound at a desired ratio. In the ligand exchange reaction of an embodiment, after subjecting the semiconductor nanoparticle including a native ligand to zinc salt treatment as described herein, a ligand exchange reaction may be performed (for example, in the presence of an additional zinc salt compound).

Details regarding the first organic ligand and the second organic ligand are as described herein.

The first organic solvent may be appropriately selected in consideration of the type of organic ligand compound, the native ligand, and the zinc salt compound. The first organic solvent may be an aliphatic hydrocarbon solvent having C6 to C40 (e.g., an alkane, alkene, or alkyne) such as octane, hexane, or heptane; an aromatic hydrocarbon solvent having C6 to C30 such as toluene or xylene; or a combination thereof.

The (first or second) zinc salt compound may include a zinc fatty acid ester compound of C8 to C50 (e.g., a zinc oleate, a zinc stearate, a zinc myristate, etc.), a zinc halide (e.g., a zinc chloride, a zinc bromide, a zinc iodide, a zinc fluoride, etc.), or a combination thereof. The first zinc salt compound and the second zinc salt compound may be the same or different. The first zinc salt compound may be a zinc fatty acid ester compound having C8 to C50, and the second zinc salt compound may be a zinc halide, or vice versa.

The first temperature may be greater than or equal to about 20° C., greater than or equal to about 30° C., greater than or equal to about 40° C., greater than or equal to about 45° C., or greater than or equal to about 50° C. The first temperature may be less than or equal to about 150° C., less than or equal to about 100° C., less than or equal to about 80° C., less than or equal to about 60° C., less than or equal to about 55° C., or less than or equal to about 45° C.

The temperature of the mixing (admixing) (or the ligand exchange reaction) may be greater than or equal to about 20° C., greater than or equal to about 30° C., greater than or equal to about 40° C., greater than or equal to about 45° C., or greater than or equal to about 50° C. The temperature of the mixing (or the ligand exchange reaction) may be less than or equal to about 150° C., less than or equal to about 100° C., less than or equal to about 80° C., less than or equal to about 60° C., less than or equal to about 55° C., or less than or equal to about 45° C.

The mixing (or the ligand exchange reaction) may be performed for a time period greater than or equal to about 50 minutes, greater than or equal to about 1 hour, greater than or equal to about 90 minutes, greater than or equal to about 100 minutes, greater than or equal to about 2 hours, or greater than or equal to about 3 hours, and less than or equal to about 5 days, less than or equal to about 4 days, less than or equal to about 3 days, less than or equal to about 2 days, less than or equal to about 1 day, or less than or equal to about 12 hours.

The amount of the first zinc salt compound and the amount of the second zinc salt compound may be appropriately selected in consideration of the type of compound, the type of ligand compound, the desired degree of substitution, or the like. An amount of the first zinc salt compound may be greater than or equal to about 10 moles, greater than or equal to about 100 moles, greater than or equal to about 500 moles, greater than or equal to about 1000 moles, greater than or equal to about 5000 moles, greater than or equal to about 10000 moles, greater than or equal to about 15000 moles, greater than or equal to about 20000 moles, and less than or equal to about 200000 moles, less than or equal to about 150000 moles, less than or equal to about 100000 moles, less than or equal to about 50000 moles, less than or equal to about 30000 moles, less than or equal to about 20000 moles, less than or equal to about 10000 moles, less than or equal to about 5000 moles, less than or equal to about 1000 moles, less than or equal to about 500 moles, or less than or equal to about 100 moles, based on 1 mole of the semiconductor nanoparticle, An amount of the second zinc salt compound may be greater than or equal to about 0.01 moles, greater than or equal to about 0.05 moles, greater than or equal to about 0.1 moles, greater than or equal to about 0.3 moles, and less than or equal to about 1 mole, less than or equal to about 0.5 moles, or less than or equal to about 0.1 moles, per 1 mole of the organic ligand compound as used (e.g., a total of the first organic ligand compound and the second organic ligand compound).

The ligand-exchanged semiconductor nanoparticles may be well dispersed in a liquid vehicle (e.g., a monomer as described herein) for an ink composition.

In the method of an embodiment, the amount of the first organic ligand, based on 1 mole of the semiconductor nanoparticle, may be greater than or equal to about 10 moles, greater than or equal to about 50 moles, greater than or equal to about 100 moles, greater than or equal to about 300 moles, greater than or equal to about 500 moles, greater than or equal to about 600 moles, greater than or equal to about 700 moles, greater than or equal to about 1000 moles, greater than or equal to about 1500 moles, greater than or equal to about 2000 moles, greater than or equal to about 2500 moles, greater than or equal to about 3000 moles, greater than or equal to about 3500 moles, greater than or equal to about 4000 moles, greater than or equal to about 4500 moles, greater than or equal to about 5000 moles, greater than or equal to about 5500 moles, greater than or equal to about 6000 moles, greater than or equal to about 6500 moles, greater than or equal to about 7000 moles, greater than or equal to about 7500 moles, greater than or equal to about 8000 moles, greater than or equal to about 8500 moles, greater than or equal to about 9000 moles, greater than or equal to about 10000 moles, greater than or equal to about 12000 moles, greater than or equal to about 15000 moles, greater than or equal to about 17000 moles, greater than or equal to about 19000 moles, or greater than or equal to about 19500 moles, and less than or equal to about 40000 moles, less than or equal to about 30000 moles, or less than or equal to about 20000 moles.

In the method, an amount of the second organic ligand compound, based on 1 mole of the nanocrystal particle, may be greater than or equal to about 0 moles, greater than or equal to about 10 moles, greater than or equal to about 50 moles, greater than or equal to about 100 moles, greater than or equal to about 300 moles, greater than or equal to about 500 moles, greater than or equal to about 600 moles, greater than or equal to about 700 moles, greater than or equal to about 1000 moles, greater than or equal to about 1500 moles, greater than or equal to about 2000 moles, greater than or equal to about 2500 moles, greater than or equal to about 3000 moles, greater than or equal to about 3500 moles, greater than or equal to about 4000 moles, greater than or equal to about 4500 moles, greater than or equal to about 5000 moles, greater than or equal to about 5500 moles, greater than or equal to about 6000 moles, greater than or equal to about 6500 moles, greater than or equal to about 7000 moles, greater than or equal to about 7500 moles, greater than or equal to about 8000 moles, greater than or equal to about 8500 moles, greater than or equal to about 9000 moles, greater than or equal to about 10000 moles, greater than or equal to about 12000 moles, greater than or equal to about 15000 moles, greater than or equal to about 17000 moles, greater than or equal to about 19000 moles, or greater than or equal to about 19500 moles, and less than or equal to about 40000 moles, less than or equal to about 30000 moles, or less than or equal to about 20000 moles.

In an embodiment, the ligand-exchanged semiconductor nanoparticles may exhibit an increased amount of organic material compared to crude semiconductor nanoparticles. In the semiconductor nanoparticles of an embodiment, the content of organic material, based on the total weight of the semiconductor nanoparticles, may be greater than or equal to about 15 wt %, greater than or equal to about 20 wt %, greater than or equal to about 25 wt %, greater than or equal to about 29 wt %, greater than or equal to about 30 wt %, greater than or equal to about 33 wt %, greater than or equal to about 35 wt %, and less than or equal to about 60 wt %, less than or equal to about 55 wt %, less than or equal to about 45 wt %, less than or equal to about 40 wt %, less than or equal to about 38 wt %, or less than or equal to about 36 wt %.

In a semiconductor nanoparticle or a semiconductor nanoparticle in an ink composition of an embodiment, a mole ratio (e.g., Zn:S) of zinc to a chalcogen element (e.g., sulfur) may be less than or equal to about 0.8:1, less than or equal to about 0.3:1, or less than or equal to about 0.25:1. In the semiconductor nanoparticles, the mole ratio (e.g., Zn:S) of zinc to the chalcogen element (e.g., sulfur) may be greater than or equal to about 0.01:1, greater than or equal to about 0.05:1, or greater than or equal to about 0.1:1.

In a semiconductor nanoparticle or a semiconductor nanoparticle in an ink composition of an embodiment, a mole ratio (Zn:Ag) of zinc (Zn) to silver (Ag) may be greater than or equal to about 0.3:1, greater than or equal to about 0.35:1, greater than or equal to about 0.4:1, greater than or equal to about 0.45:1, greater than or equal to about 0.5:1, greater than or equal to about 0.55:1, greater than or equal to about 0.6:1, greater than or equal to about 0.65:1, greater than or equal to about 0.7:1, greater than or equal to about 0.75:1, greater than or equal to about 0.8:1, greater than or equal to about 0.85:1, greater than or equal to about 0.9:1, greater than or equal to about 0.95:1, greater than or equal to about 1:1, greater than or equal to about 1.2:1, greater than or equal to about 1.4:1, greater than or equal to about 1.6:1, greater than or equal to about 1.7:1, greater than or equal to about 1.9:1, greater than or equal to about 2:1, greater than or equal to about 2.5:1, greater than or equal to about 3:1, greater than or equal to about 3.5:1, or greater than or equal to about 4:1. In a semiconductor nanoparticle or a semiconductor nanoparticle in an ink composition of an embodiment, a mole ratio (Zn:Ag) of zinc (Zn) to silver (Ag) may be less than or equal to about 5:1, less than or equal to about 4.7:1, less than or equal to about 4.4:1, less than or equal to about 4.1:1, less than or equal to about 3.9:1, less than or equal to about 3.7:1, less than or equal to about 3.5:1, less than or equal to about 3:1, less than or equal to about 2.7:1, less than or equal to about 2.6:1, or less than or equal to about 2.3:1.

In a semiconductor nanoparticle or a semiconductor nanoparticle in an ink composition of an embodiment, a mole ratio (Zn:In) of zinc (Zn) to indium (In) may be greater than or equal to about 0.1:1, greater than or equal to about 0.3:1, greater than or equal to about 0.5:1, greater than or equal to about 0.7:1, greater than or equal to about 0.9:1, greater than or equal to about 1.1:1, greater than or equal to about 1.3:1, greater than or equal to about 1.5:1, greater than or equal to about 1.7:1, greater than or equal to about 1.9:1, greater than or equal to about 2.1:1, greater than or equal to about 2.3:1, greater than or equal to about 2.5:1, greater than or equal to about 2.7:1, greater than or equal to about 2.9:1, or greater than or equal to about 3:1. In a semiconductor nanoparticle or a semiconductor nanoparticle in an ink composition of an embodiment, a mole ratio (Zn:In) of zinc (Zn) to indium (In) may be less than or equal to about 10:1, less than or equal to about 8:1, less than or equal to about 6:1, less than or equal to about 5:1, less than or equal to about 4.5:1, less than or equal to about 4:1, less than or equal to about 3.5:1, less than or equal to about 2:1, or less than or equal to about 1.6:1.

In a semiconductor nanoparticle or a semiconductor nanoparticle in an ink composition of an embodiment, a mole ratio (Zn:Ga) of zinc (Zn) to gallium (Ga) may be greater than or equal to about 0.1:1, greater than or equal to about 0.2:1, greater than or equal to about 0.3:1, greater than or equal to about 0.35:1, greater than or equal to about 0.4:1, greater than or equal to about 0.45:1, or greater than or equal to about 0.5:1. In the semiconductor nanoparticles in the ink composition, a mole ratio (Zn:Ga) of zinc (Zn) to gallium (Ga) may be less than or equal to about 3:1, less than or equal to about 2.5:1, less than or equal to about 2:1, less than or equal to about 1.9:1, less than or equal to about 1.7:1, less than or equal to about 1.5:1, less than or equal to about 1.4:1, less than or equal to about 1.2:1, less than or equal to about 1.1:1, less than or equal to about 0.9:1, less than or equal to about 0.8:1, less than or equal to about 0.7:1, less than or equal to about 0.6:1, or less than or equal to about 0.49:1.

In a semiconductor nanoparticle or a semiconductor nanoparticle in an ink composition of an embodiment, a mole ratio (Zn:(Ga+In+Ag)) of zinc (Zn) to a total of gallium (Ga), indium (In), and silver (Ag) may be greater than or equal to about 0.05:1, greater than or equal to about 0.1:1, greater than or equal to about 0.2:1, greater than or equal to about 0.25:1, greater than or equal to about 0.3:1, greater than or equal to about 0.35:1, or greater than or equal to about 0.4:1. In the semiconductor nanoparticles in the ink composition, a mole ratio (Zn:(Ga+In+Ag)) of zinc (Zn) to a total of gallium (Ga), indium (In), and silver (Ag) may be less than or equal to about 2:1, less than or equal to about 1.7:1, less than or equal to about 1.4:1, less than or equal to about 1.1:1, less than or equal to about 0.9:1, less than or equal to about 0.7:1, less than or equal to about 0.5:1, or less than or equal to about 0.45:1.

In a semiconductor nanoparticle or a semiconductor nanoparticle in an ink composition of an embodiment, a mole ratio (Zn:(Ga+In)) of zinc (Zn) to a total of gallium (Ga) and indium (In) may be greater than or equal to about 0.05:1, greater than or equal to about 0.1:1, greater than or equal to about 0.2:1, greater than or equal to about 0.25:1, greater than or equal to about 0.3:1, greater than or equal to about 0.35:1, or greater than or equal to about 0.4:1. In the semiconductor nanoparticles in the ink composition, a mole ratio (Zn:(Ga+In)) of zinc (Zn) to a total of gallium (Ga) and indium (In) may be less than or equal to about 2:1, less than or equal to about 1.7:1, less than or equal to about 1.4:1, less than or equal to about 1.1:1, less than or equal to about 0.9:1, less than or equal to about 0.7:1, less than or equal to about 0.5:1, or less than or equal to about 0.45:1.

An amount of the semiconductor nanoparticle in the ink composition or in the semiconductor nanoparticle polymer composite may be appropriately adjusted taking into consideration a desired end use (for example, a use as a luminescent type color filter), In an embodiment, an amount of the semiconductor nanoparticle in the ink composition (or in the semiconductor nanoparticle-polymer composite) may be greater than or equal to about 1 wt %, for example, greater than or equal to about 2 wt %, greater than or equal to about 3 wt %, greater than or equal to about 4 wt %, greater than or equal to about 5 wt %, greater than or equal to about 6 wt %, greater than or equal to about 7 wt %, greater than or equal to about 8 wt %, greater than or equal to about 9 wt %, greater than or equal to about 10 wt %, greater than or equal to about 12 wt %, greater than or equal to about 14 wt %, greater than or equal to about 15 wt %, greater than or equal to about 17 wt %, greater than or equal to about 19 wt %, greater than or equal to about 20 wt %, greater than or equal to about 23 wt %, greater than or equal to about 25 wt %, greater than or equal to about 27 wt %, greater than or equal to about 30 wt %, greater than or equal to about 33 wt %, greater than or equal to about 35 wt %, greater than or equal to about 37 wt %, or greater than or equal to about 40 wt %, based on a total weight or a total solid content of the composition or composite (hereinafter, “total weight” or “total solid content” may be a total weight or a total solid content of the composition or a total weight of the composite), The amount of the semiconductor nanoparticle in the ink composition (or composite) may be less than or equal to about 99 wt %, less than or equal to about 95 wt %, less than or equal to about 80 wt %, less than or equal to about 70 wt %, for example, less than or equal to about 65 wt %, less than or equal to about 60 wt %, less than or equal to about 55 wt %, less than or equal to about 50 wt %, or less than or equal to about 45 wt %, based on the total weight or total solid content of the composition or composite. A weight percentage of a given component with respect to a total solid content in a composition may represent an amount of the given component in the composite as described herein or in a solventless composition. The total solid content is a total weight of the solid content. In an embodiment, the total weight of the composition or composite may be the total weight of the solid content.

In an embodiment of the ink composition, a polymerizable monomer (e.g., monomer) may include a compound containing one or more carbon-carbon double bonds (e.g., greater than or equal to 2, or greater than or equal to three, and less than or equal to ten carbon-carbon double bonds). The monomer may be a precursor for an insulating polymer. The monomer may be polymerized by using light or heat.

In the ink composition, the monomer may include a compound represented by Chemical Formula 1:

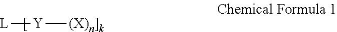

in Chemical Formula 1, X is a C2 to C30 organic group having a carbon-carbon double bond,
L is a single bond, a carbon atom, a substituted or unsubstituted C1 to C50 alkylene group, a substituted or unsubstituted C2 to C50 alkenylene group, a substituted or unsubstituted C3 to C50 (e.g. C6-C30) cycloalkylene group, a substituted or unsubstituted C3 to C50 (e.g. C6-C30) cycloalkenylene group, a substituted or unsubstituted C6 to C50 arylene group, a substituted or unsubstituted C3 to C30 heteroarylene group, a group having at least one oxyalkylene unit [e.g., (R—O)n where R is a substituted or unsubstituted C1 to C10 alkylene such as methylene, ethylene, isopropylene, butylene, and n is greater than or equal to about 1, greater than or equal to about 3, greater than or equal to about 5, or greater than or equal to about 10 and less than or equal to about 500, less than or equal to about 300, less than or equal to about 100, less than or equal to about 50, less than or equal to about or 15 or less], a sulfonyl group (—S(—O)₂—), a carbonyl group (—C(═O)—), an ether group (—O—), a thioether group (—S—), a sulfoxide group (—S(═O)—), an ester group (—C(═O)O—), an amide group (—C(═O) NR—) (where R is hydrogen or a linear or branched alkyl group of C1 to C10), an imine group (—NR—) (where R is hydrogen or a linear or branched alkyl group of C1 to C10) or a combination thereof,
Y is a single bond, a substituted or unsubstituted C1 to C50 alkylene group, a substituted or unsubstituted C2 to C50 alkenylene group, a sulfonyl group (—S(═O)₂—), a carbonyl group (—C(═O)—), an ether group (—O—), a thioether group (—S—), a sulfoxide group (—S(═O)—), an ester group (—C(═O)O—), an amide group (—C(═O)NR—) (where R is hydrogen or a linear or branched alkyl group of C1 to C10), an imine group (—NR—) (where R is hydrogen or a linear or branched alkyl group of C1 to C10) or a combination thereof,
n is an integer greater than or equal to 1 (for example, 1, 2, 3, or 4),
k is an integer of 1 to 8 (for example, 1, 2, 3, 4, 5, 6, 7, or 8).

The sum of n and k is an integer of 2 or more (e.g., 3 or more, or 4 or more and 10 or less, or 5 or less).

In Chemical Formula 1, n may be determined by a valence of Y, and k may be determined by a valence of L.

In Chemical Formula 1, X may include a vinyl group, a (meth)acrylate group, or a combination thereof.

The monomer may include a polyethylene glycol methacrylate, a polypropylene glycol methacrylate, a polyethylene glycol dimethacrylate, a polypropylene glycol dimethacrylate, a substituted or unsubstituted alkyl (meth)acrylate, an ethylene glycol di(meth)acrylate, a triethylene glycol di(meth)acrylate, a diethylene glycol di(meth)acrylate, a dipropylene glycol di(meth)acrylate, a 1,4-butanedialdi(meth)acrylate, a 1,6-hexanedialdi(meth)acrylate, a neopentyl glycol di(meth)acrylate, a pentaerythritol di(meth)acrylate, a pentaerythritol tri(meth)acrylate, a pentaerythritol tetra(meth)acrylate, a dipentaerythritol di(meth)acrylate, a dipentaerythritol(meth)acrylate, a dipentaerythritol penta(meth)acrylate, a dipentaerythritol pentaacrylate, a dipentaerythritol hexa(meth)acrylate, a bisphenol A epoxy acrylate, a bisphenol A di(meth)acrylate, a trimethylolpropane tri(meth)acrylate, a novolacepoxy(meth)acrylate, an ethyl glycol monomethyl ether(meth)acrylate, a tris(meth)acryloyloxyethyl phosphate, a propylene glycol di(meth)acrylate, a diacryloyloxyalkane, or a combination thereof.

The monomer may include a substituted or unsubstituted di(meth)acrylate compound, a substituted or unsubstituted tri(meth)acrylate compound, a substituted or unsubstituted tetra(meth)acrylate compound, a substituted or unsubstituted penta(meth)acrylate compound, a substituted or unsubstituted hexa(meth)acrylate compound, or a combination thereof.

An amount of the polymerizable monomer, based on a total weight of the ink composition, may be greater than or equal to about 0.5 wt %, for example, greater than or equal to about 1 wt %, greater than or equal to about 2 wt %, greater than or equal to about 3 wt %, greater than or equal to about 5 wt %, greater than or equal to about 10 wt %, greater than or equal to about 20 wt %, greater than or equal to about 30 wt %, or greater than or equal to about 40 wt %. An amount of the polymerizable monomer, based on the total weight of the ink composition, may be less than or equal to about 99 wt %, less than or equal to about 90 wt %, less than or equal to about 80 wt %, less than or equal to about 70 wt %, less than or equal to about 60 wt %, less than or equal to about 50 wt %, less than or equal to about 45 wt %, less than or equal to about 28 wt %, less than or equal to about 25 wt %, less than or equal to about 23 wt %, less than or equal to about 20 wt %, less than or equal to about 18 wt %, less than or equal to about 17 wt %, less than or equal to about 16 wt %, or less than or equal to about 15 wt %.

The ink composition may further include an initiator, a metal oxide (nano or fine) particle, or a combination thereof.

The (photo)initiator included in the ink composition may be used for (photo)polymerization of the aforementioned monomer, The initiator is a compound accelerating a radical reaction (e.g., radical polymerization of monomer) by producing radical chemical species under a mild condition (e.g., by heat or light), The initiator may be a thermal initiator or a photoinitiator. The initiator is not particularly limited and may be appropriately selected.

The thermal initiator may include azobisisobutyronitrile, benzoyl peroxide, or the like, but is not limited thereto. The photoinitiator may include, but is not limited to, a triazine-based compound, an acetophenone compound, a benzophenone compound, a thioxanthone compound, an oxime ester compound, an amino ketone compound, a phosphine or a phosphine oxide compound, a carbazole-based compound, a diketone-based compound, a sulfonium borate-based compound, a diazo-based compound, a biimidazole-based compound, or a combination thereof. The initiator may include Igacure 754, hydroxycyclohexyl phenyl ketone (Irgacure 184, CAS 947-19-3), 2,4,6-Trimethylbenzoyl diphenylphosphine oxide (Irgacure TPO, CAS 75980-60-8), oxyphenyl-acetic acid 2[2-oxo-2-phenyl-acetoxy-ethoxy]-ethyl ester, or a combination thereof.

In the ink composition, an amount of the initiator may be appropriately adjusted considering types and contents of the polymerizable monomers. In an embodiment, the amount of the initiator may be greater than or equal to about 0.01 wt %, for example, greater than or equal to about 1 wt %, and/or less than or equal to about 10 wt %, for example, less than or equal to about 9 wt %, less than or equal to about 8 wt %, less than or equal to about 7 wt %, less than or equal to about 6 wt %, or less than or equal to about 5 wt %, based on the total weight of the ink composition (or the total weight of the solid content), but embodiments are not limited thereto.

The metal oxide particle may include TiO₂, SiO₂, BaTiO₃, Ba₂TiO₄, ZnO, or a combination thereof. In the ink composition (or composite), an amount of the metal oxide particle may be greater than or equal to about 1 wt %, greater than or equal to about 2 wt %, greater than or equal to about 3 wt %, greater than or equal to about 5 wt %, or greater than or equal to about 10 wt % to less than or equal to about 50 wt %, less than or equal to about 40 wt %, less than or equal to about 30 wt %, less than or equal to about 25 wt %, less than or equal to about 20 wt %, less than or equal to about 15 wt %, less than or equal to about 10 wt %, less than or equal to about 7 wt %, less than or equal to about 5 wt %, or less than or equal to about 3 wt %, based on the total weight of the ink composition (or the total weight of the solid content).

A diameter of the metal oxide fine particle is not particularly limited, and may be appropriately selected. The diameter of the metal oxide fine particle may be greater than or equal to about 100 nm, for example greater than or equal to about 150 nm, or greater than or equal to about 200 nm and less than or equal to about 1000 nm, or less than or equal to about 800 nm.

The ink composition according to an embodiment may provide a semiconductor nanoparticle-polymer composite (e.g., composite) or pattern thereof via polymerization (e.g., photopolymerization). In an embodiment, the composite that includes a matrix and the aforementioned semiconductor nanoparticle (e.g., nanoparticle) dispersed in the matrix is provided. The nanoparticle or the composite containing the nanoparticle(s) of an embodiment can emit light of a desired wavelength (e.g., a first light) with an improved optical property (e.g., an increased light emitting efficiency and a narrower full width at half maximum) along with an increased level of blue light absorption (e.g., improved incident light absorption). The composite may be in a form of a sheet. The composite may be in a form of a patterned film.

In an aspect, the semiconductor nanoparticle-polymer composite includes a polymerization product of a polymerizable monomer (e.g., a polymer), and a semiconductor nanoparticle. The semiconductor nanoparticle-polymer composite may further include the first organic ligand. The semiconductor nanoparticle may be dispersed in a colloidal form in the polymer or the polymerization product. Details of the semiconductor nanoparticle and the first organic ligand are the same as described herein.

The (polymer) matrix may include a polymerization product of the polymerizable monomer. The matrix may include a linear polymer, a crosslinked polymer, or a combination thereof. The crosslinked polymer may include a thiolene resin, a crosslinked poly(meth)acrylate, a crosslinked polyurethane, a crosslinked epoxy resin, a crosslinked vinyl polymer, a crosslinked silicone resin, or a combination thereof. In an embodiment, the crosslinked polymer may include a polymerization product of the polymerizable monomer and optionally a multiple thiol compound.

The (linear) polymer may include a repeating unit derived from a carbon-carbon unsaturated bond (e.g., a carbon-carbon double bond). The repeating unit may include a carboxylic acid group. The (linear) polymer may include an ethylene repeating unit. The carboxylic acid group-containing repeating unit may include a unit derived from a monomer including a carboxylic acid group and a carbon-carbon double bond, a unit derived from a monomer having a dianhydride moiety, or a combination thereof. The (linear) polymer may be an alkali-soluble polymeric binder or resin. The ink composition of an embodiment may not include an alkali-soluble polymeric binder or resin.

In the semiconductor nanoparticle-polymer composite (e.g., a first composite) of one or more embodiments, the (polymer) matrix may include the components described herein with respect to the composition. In the composite, an amount of the matrix, based on a total weight of the composite, may be greater than or equal to about 10 wt %, greater than or equal to about 20 wt %, greater than or equal to about 30 wt %, greater than or equal to about 40 wt %, greater than or equal to about 50 wt %, or greater than or equal to about 60 wt %. The amount of the matrix may be, based on a total weight of the composite, less than or equal to about 95 wt %, less than or equal to about 90 wt %, less than or equal to about 80 wt %, less than or equal to about 70 wt %, less than or equal to about 60 wt %, or less than or equal to about 50 wt %.

The semiconductor nanoparticle-polymer composite may have, for example, a predetermined thickness and include a predetermined amount of the semiconductor nanoparticle. The ink composition or the composite prepared therefrom may include a film form having a thickness of less than or equal to about 10 micrometers (μm). The semiconductor nanoparticle-polymer composite may be in the form of a film or pattern, and the thickness of the composite may be, for example, less than or equal to about 30 μm, less than or equal to about 25 μm, less than or equal to about 20 μm, less than or equal to about 15 μm, less than or equal to about 10 μm, less than or equal to about 8 μm, or less than or equal to about 7 μm and greater than about 2 μm, for example, greater than or equal to about 3 μm, greater than or equal to about 3.5 μm, greater than or equal to about 4 μm, greater than or equal to about 5 μm, greater than or equal to about 6 μm, greater than or equal to about 7 μm, greater than or equal to about 8 μm, greater than or equal to about 9 μm, or greater than or equal to about 10 μm,

The ink composition or the semiconductor nanoparticle-polymer composite prepared therefrom may exhibit an increased incident light (e.g., blue light) absorbance, An incident light absorbance of the composite may be greater than or equal to about 70%, greater than or equal to about 73%, greater than or equal to about 75%, greater than or equal to about 77%, greater than or equal to about 80%, greater than or equal to about 83%, greater than or equal to about 85%, greater than or equal to about 87%, greater than or equal to about 90%, greater than or equal to about 93%, greater than or equal to about 94%, greater than or equal to about 95%, greater than or equal to about 96%, greater than or equal to about 97%, greater than or equal to about 98%, or greater than or equal to about 99%, The blue light absorbance of the composite may be about 70% to about 100%, about 80% to about 98%, about 95% to about 99%, about 96% to about 98%, or a combination thereof. The incident light absorbance may be determined using Equation 2:

$$incident light absorbance = [ ( B - {B}^{′} ) / B ] \times 100 ( \% ) \qquad Equation 2$$

wherein, in Equation 2,
B is an amount of incident light provided to the composite, and
B′ is an amount of incident light passing through the composite.

The ink composition may be configured to form a composite by polymerization, and a quantum efficiency maintaining percentage defined by the following Equation may be greater than or equal to about 50%, greater than or equal to about 51%, greater than or equal to about 55%, greater than or equal to about 57%, greater than or equal to about 60%, greater than or equal to about 65%, greater than or equal to about 70%, greater than or equal to about 75%, greater than or equal to about 80%, greater than or equal to about 85%, greater than or equal to about 88%, or greater than or equal to about 90%:

$$Quantum efficiency maintaining percentage ( \% ) = [ Quantum efficiency of a semiconductor nanoparticle - containing composite after polymerization / Quantum efficiency of a semiconductor nanoparticle ( e . g . , in the ink composition ) ] \times 100.$$

The quantum efficiency maintaining percentage may range from 88% to 100%, from 90% to 99%, from 93% to 97%, or a combination thereof.

The ink composition may be configured to form a composite by (photo) polymerization, and a process maintenance percentage defined by the following Equation may be greater than or equal to about 50%, greater than or equal to about 51%, greater than or equal to about 55%, greater than or equal to about 57%, greater than or equal to about 60%, greater than or equal to about 65%, greater than or equal to about 70%, greater than or equal to about 75%, greater than or equal to about 80%, greater than or equal to about 85%, greater than or equal to about 88%, or greater than or equal to about 90%:

$$Process maintenance percentage ( \% ) = [ Quantum efficiency of the semiconductor nanoparticle - containing composite after heat treatment at 180 °C . for 30 minutes / Quantum efficiency of the semiconductor nanoparticle - containing composite after ( photo ) polymerization ] \times 100.$$

The composite of an embodiment may exhibit improved process stability (e.g., stability against light or an external environment). In an embodiment, the semiconductor nanoparticle composite may have a quantum efficiency change rate defined by the following Equation that is greater than or equal to about 50%, greater than or equal to about 70%, greater than or equal to about 80%, greater than or equal to about 90%, greater than or equal to about 95%, or greater than or equal to about 98% when left under predetermined conditions (e.g., 20 Lux and/or in the atmosphere) for a predetermined time (e.g., 48 hours):

$$Quantum efficiency change rate ( \% ) = [ Quantum efficiency after the predetermined time elapsed / Initial quantum efficiency ] \times 100.$$

The composite or the semiconductor nanoparticle contained therein may have a quantum efficiency or a conversion efficiency (CE) obtained by the following Equation (e.g., after exposure or after heat treatment at 180° C. for 30 minutes) that is greater than or equal to about 25%, greater than or equal to about 30%, greater than or equal to about 32%, greater than or equal to about 33%, greater than or equal to about 34%, greater than or equal to about 36%, greater than or equal to about 40%, greater than or equal to about 45%, greater than or equal to about 50%, greater than or equal to about 55%, greater than or equal to about 60%, greater than or equal to about 63%, greater than or equal to about 69%, greater than or equal to about 75%, greater than or equal to about 80%, greater than or equal to about 85%, greater than or equal to about 89%, greater than or equal to about 90%, greater than or equal to about 95%, or greater than or equal to about 98%.

$$Internal quantum efficiency ( \% ) = [ A / ( B - {B}^{′} ) ] \times 100$$

External quantum efficiency (%)=[A/B]×100A: amount of the first light emitted from the composite
B: amount of the irradiated incident light
B′: amount of the incident light passing through the composite.

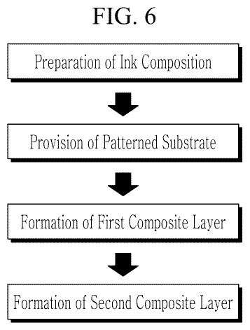

A patterned film of a color conversion layer or a nanoparticle composite may be produced by an inkjet printing method using the ink composition of an embodiment. Referring to FIG. 6, such a method may include preparing the ink composition; providing a substrate (e.g., a substrate in which a pixel area is patterned by an electrode and optionally a bank or a trench-shaped partition wall); and depositing the ink composition on the substrate (or the pixel area) to form, for example, a first composite layer (or a first region).

The method may further include depositing the ink composition on the substrate (or the pixel area) to form, for example, a second composite layer (or a second region). Formation of the first composite layer and formation of the second composite layer may be performed simultaneously or sequentially.

The deposition of the ink composition may be performed using a suitable liquid crystal discharge device such as an inkjet or nozzle printing system (e.g., having an ink reservoir and one or more print heads). The deposited ink composition may provide a (first or second) composite layer through removal of the solvent and polymerization by heating. Such a method can form a highly precise nanoparticle-polymer composite film or a patterned film in a short time in a simple manner.

The semiconductor nanoparticle, the composite (or the pattern thereof) including the semiconductor nanoparticle, or the color conversion panel including the same may be included in an electronic device, Such an electronic device or apparatus may include a display device, a light emitting diode (LED), an organic light emitting diode (OLED), a quantum dot LED, a sensor, a solar cell, an imaging sensor, a photodetector, or a liquid crystal display device, but is not limited thereto, The aforementioned quantum dot may be included in an electronic device or apparatus, Such an electronic device or apparatus may include, but is not limited to, a portable terminal device, a monitor, a personal computer (PC), a notebook personal computer (PC), a television, an electric sign board or electronic display board, a camera, a car, or the like, but embodiments are not limited thereto, The electronic apparatus may be a portable terminal device, a monitor, a note PC, or a television, including a display device (or a light emitting device) including quantum dots, The electronic device or apparatus may be a camera or a mobile terminal device including an image sensor including quantum dots, The electronic device or apparatus may be a camera or a vehicle including a photodetector including quantum dots.

Hereinafter, the exemplary embodiments are illustrated in further detail with reference to examples, However, embodiments of the present disclosure are not limited to the examples.

### EXAMPLES

### Analysis Methods

### [1] UV-Vis Absorption Spectroscopic Analysis

UV spectroscopic analysis was performed and a UV-Vis absorption spectrum was obtained using an Agilent Cary5000 spectrophotometer. From the obtained UV-Vis absorption spectrum, absorbances at 350 nm, 450 nm, and 530 nm were measured, respectively and the ratios therebetween are calculated as follows:

$$Absorbance ratio at 450 nm to at 350 nm = A 450 / A 350$$

$$Absorbance ratio at 530 nm to at 350 nm = A 530 / A 350$$

A450: Absorbance at 450 nm
A350: Absorbance at 350 nm
A530: Absorbance at 530 nm

### [2] ICP Analysis

Inductively coupled plasma atomic emission spectroscopy analysis (ICP-AES) is performed using a Shimadzu ICPS-8100.

### [3] Blue Light Absorbance and External Quantum Efficiency (EQE)

An integrating hemisphere of an absolute quantum efficiency measurement device (QE-2100, Otsuka) was used to measure the amount (B) of incident light having a wavelength of 450 nm. Subsequently, a QD polymer composite was placed in the integrating hemisphere, and the incident light was irradiated to measure the amount (A) of first light emitted from one side of the composite and the amount (B′) of incident light transmitted through the composite.

From the measured values, the incident light absorbance is calculated by the following equation:

$$Blue light absorbance ( \% ) ( Abs at 450 nm ) = [ ( B - {B}^{′} ) / B ] \times 100$$

$$External quantum efficiency ( \% ) = [ A / B ] \times 100$$

### [4] Light Transmittance Measurement

As a light transmittance measurement device, the integrating hemisphere of an absolute quantum efficiency measurement device (QE-2100, Otsuka) was used. A QD polymer composite was placed in the integrating hemisphere, and incident light (lo) having a wavelength of 530 nm is irradiated to measure the light transmitted (l) from one side of the composite, and the light transmittance (% T) is calculated:

$$\% T = 100 \times ( I / Io )$$

l: Amount of the transmitted light
lo: Amount of the incident light

### Reference Example 1: AIGS/AGS

Silver acetate was dissolved in oleylamine to provide a 0.06 molar (M) silver precursor containing solution (hereinafter, abbreviated as “silver precursor”), Sulfur was dissolved in oleylamine to provide a 1 M sulfur precursor containing solution (hereinafter, abbreviated as “sulfur precursor”), Indium chloride was dissolved in ethanol to provide a 0.2 M indium precursor containing solution (hereinafter, abbreviated as an indium precursor).

Gallium acetylacetonate, octadecene (ODE), and dodecanethiol were placed in a 100 milliliter (mL) reaction flask and heated at 120° C. for 10 minutes under vacuum. After cooling the flask to room temperature and flowing nitrogen into the flask, the silver precursor, the sulfur precursor, and the indium precursor were added to the flask. The flask was heated at a reaction temperature of 210° C., and a reaction proceeded for 60 minutes. After decreasing the temperature of the flask to 180° C., trioctylphosphine (TOP) was added to the flask, and then hexane and ethanol were added to the obtained mixture to promote precipitation, The solid first semiconductor nanocrystals were separated via centrifugation and dispersed in toluene.

A mole ratio among the indium precursor, the gallium precursor (specifically, gallium acetylacetonate), and the sulfur precursor as used was 1:2.3:4.8.

Gallium chloride was dissolved in toluene to prepare a 4.5 M gallium precursor containing solution (hereinafter, abbreviated as a “gallium precursor”). A silver compound dispersion was prepared by dispersing a silver compound (silver acetate, 0.06 M) in oleylamine.

Dimethylthiourea (DMTU), oleylamine, and dodecanethiol were placed in a flask and subjected to vacuum treatment at 120° C. for 10 minutes. After replacing the atmosphere in the reaction flask with N₂, the mixture was heated to 240° C. (a predetermined temperature), and then the first semiconductor nanocrystals prepared above, a gallium precursor, and the silver compound were added. Subsequently, the reactor was heated to 320° C. (reaction temperature) and the reaction was carried out for about 10 minutes (first time). The temperature of the reaction solution was lowered to 180° C., trioctylphosphine was added, and then the mixture was cooled to room temperature. Hexane and ethanol were added to precipitate the formed semiconductor nanoparticles, and the obtained semiconductor nanoparticles were collected by centrifugation and redispersed in toluene.

The amounts of the gallium precursor, silver compound, and sulfur precursor used were 34.17 millimole (mmol), 1.16 mmol, and 45.57 mmol, respectively. An ICP-AES analysis was performed on the obtained semiconductor nanoparticles, and the results are summarized in Table 1.

### Reference Examples 2 to 5:

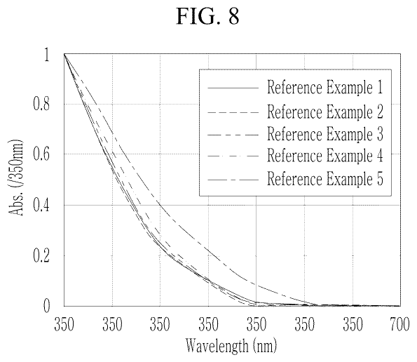

A semiconductor nanoparticle was obtained in the same manner as in Reference Example 1, except that the amount of the silver compound was increased as shown in Table 1 (1.5 times, 2 times, 3 times, and 6 times) relative to the amount of the silver compound used in Reference Example 1. ICP-AES analysis and UV-Vis absorption spectroscopic analysis were performed on the obtained semiconductor nanoparticles, and the results are summarized in Table 1, Table 2, and FIG. 8.

TABLE 1

| | Amount of the Ag | | | | | | |
|---|---|---|---|---|---|---|---|
| | compound in | | | | | | |
| | comparison with that | | | | | | |
| | of Ref. Example 1 | ICP Data | | | | | |
| | (mmol) | S/In | Ag/In | Ga/In | Ga/S | (In + Ga)/Ag | Ag/S |
| Ref. | Ag 1.0 × | 12.21 | 4.53 | 6.45 | 0.528 | 1.645 | 0.37 |
| Example 1 | 1.16 mmol | | | | | | |
| Ref. | Ag 1.5 × | 13.43 | 5.22 | 6.77 | 0.504 | 1.489 | 0.39 |
| Example 2 | 1.74 mmol | | | | | | |
| Ref. | Ag 2.0 × | 14.3 | 5.59 | 7.26 | 0.508 | 1.478 | 0.39 |
| Example 3 | 2.32 mmol | | | | | | |
| Ref. | Ag 3.0 × | 15.71 | 6.11 | 7.62 | 0.485 | 1.411 | 0.39 |
| Example 4 | 3.48 mmol | | | | | | |
| Ref. | Ag 6.0 × | 51.92 | 20.21 | 32.74 | 0.631 | 1.669 | 0.39 |
| Example 5 | 6.96 mmol | | | | | | |

TABLE 2

| | A450/A350 | A530/A350 |
|---|---|---|
| Ref. Example 1 | 0.22 | 0.02 |
| Ref. Example 2 | 0.23 | 0.03 |
| Ref. Example 3 | 0.25 | 0.04 |
| Ref. Example 4 | 0.28 | 0.05 |
| Ref. Example 5 | 0.4 | 0.15 |

From the results of Table 1 and Table 2, it was confirmed that the semiconductor nanoparticles of Reference Example 5 could exhibit different absorption characteristics compared to the semiconductor nanoparticles of Reference Examples 1 to 4.

### Reference Example 6: InP-Based Core/Shell Semiconductor Nanoparticles

Zinc acetate and oleic acid were dissolved in octadecene (ODE) in a 250 ml reaction flask, heated to 120° C. under vacuum, and then cooled to room temperature to obtain a zinc oleate solution. Indium acetate and lauric acid were added to the reaction flask, and the mixture was heated to 120° C. under vacuum. After 1 hour, the atmosphere in the reactor was replaced with nitrogen. While raising the temperature of the reaction flask to 250° C., a mixed solution of tris(trimethylsilyl)phosphine (TMS₃P) and trioctylphosphine was quickly injected into the reactor to proceed with the reaction. After completion of the reaction, the reaction solution was cooled to room temperature, a non-solvent (acetone) was added, and the resulting precipitate was collected by centrifugation and redispersed in toluene.

The mole ratio of indium, zinc, and phosphorus used was set to 6:7:4.5.

Selenium was dispersed in trioctylphosphine to prepare a Se/TOP stock solution, and sulfur was dispersed in trioctylphosphine to prepare an S/TOP stock solution.

In a 2 L flask, zinc acetate and oleic acid were dissolved in trioctylamine and subjected to vacuum treatment at 120° C. for 10 minutes. After replacing the atmosphere in the reaction flask with N₂, while raising the temperature of the obtained solution to a reaction temperature of 280° C., the toluene dispersion of the first semiconductor nanocrystals prepared above, the Se/TOP stock solution, and dodecanethiol were injected into the flask. While the reaction proceeded, the S/TOP stock solution was further added to the reaction solution, and additional reaction was carried out to obtain a reaction solution containing semiconductor nanoparticles comprising the first semiconductor nanocrystals and the second semiconductor nanocrystals present at least partially on the surface.

The total reaction time was 75 minutes, and the mole ratio between dodecanethiol and S/TOP was set to 1:0.4.

An excess amount of ethanol was added to the reaction solution, and the semiconductor nanoparticles (hereinafter referred to as QDs) were collected by centrifugation. After centrifugation, the supernatant was discarded, and the precipitate was dried and then dispersed in toluene to obtain a semiconductor nanoparticle solution (hereinafter referred to as a QD solution).

### Example 1: Preparation of Ink Composition/Composite and Evaluation of Properties of the Composite

### [1] Ligand Exchange Reaction

A zinc oleate was added to the toluene dispersion of the semiconductor nanocrystal particle obtained in Reference Example 1 at room temperature and stirred for 3 hours. Ethanol was added to the resulting dispersion to facilitate precipitation of particles, and a zinc salt-treated semiconductor nanocrystal particle was recovered by centrifugation.

A zinc chloride solution was prepared. A first ligand compound solution was prepared by dissolving 2-carboxyethyl acrylate (CAS no: 24615-84-7, purchased from Sigma Aldrich Co., Ltd.) having the following formula in toluene:

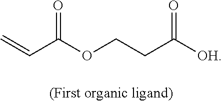

The zinc salt-treated semiconductor nanocrystal particle was dispersed in toluene to prepare a dispersion. The first ligand compound solution and the zinc chloride solution were mixed with the dispersion and stirred at room temperature for about 3 hours to conduct a ligand exchange reaction.

Hexane was then added to the reaction solution to induce precipitation of the ligand exchanged particle, which was recovered by centrifugation and dried.

A used amount of the first organic ligand was 4000 moles per one mole of the semiconductor nanocrystal particles. An amount of the zinc chloride was 5 mole %, based on an amount of the organic ligand.

### [2] Preparation of Ink Composition and Formation of Composite

An ink composition was prepared by adding the semiconductor nanoparticle prepared above, a titanium oxide nanoparticle, and an initiator to hexanediol diacrylate (a monomer).

The amounts of the semiconductor nanoparticle, the titanium oxide nanoparticle, and the initiator in the ink composition was set to 20 wt %, 5 wt %, and 1 wt %, respectively, and the remainder was the monomer.

The prepared composition was deposited on a substrate and subjected to exposure (exposure dose: 12 Joules) to perform photopolymerization, thereby obtaining a film having a thickness of 7 μm. The photo-conversion efficiency (CE) of the prepared film was measured, and the results are summarized in Table 2.

The obtained film was heat-treated at 180° C. for 30 minutes to obtain a semiconductor nanoparticle composite film.

[3] The light transmittance, blue light absorbance, and external quantum efficiency of the obtained composite film were measured, and the results are summarized in Table 3.

### Example 2

A semiconductor nanoparticle composite film was prepared in the same manner as in Example 1, except that the semiconductor nanoparticles of Reference Example 2 were used. The light transmittance, blue light absorbance, and external quantum efficiency of the obtained composite film were measured, and the results are summarized in Table 3.

### Example 3

A semiconductor nanoparticle composite film was prepared in the same manner as in Example 1, except that the semiconductor nanoparticles of Reference Example 3 were used. The light transmittance, blue light absorbance, and external quantum efficiency of the obtained composite film were measured, and the results are summarized in Table 3.

### Example 4

A semiconductor nanoparticle composite film was prepared in the same manner as in Example 1, except that the semiconductor nanoparticles of Reference Example 4 were used. The light transmittance, blue light absorbance, and external quantum efficiency of the obtained composite film were measured, and the results are summarized in Table 3.

### Comparative Example 1

A semiconductor nanoparticle composite film (thickness: 7 μm) was prepared in the same manner as in Example 1, except that the semiconductor nanoparticles of Reference Example 5 were used. The light transmittance, blue light absorbance, and external quantum efficiency (external quantum efficiency=number of green photons emitted in the forward direction [wavelength range of green light: 483-580 nm]/number of incident blue photons) of the obtained composite film were measured, and the results are summarized in Table 3.

TABLE 3

| | Blue light absorbance | Light transmittance | |
|---|---|---|---|
| | at 450 nm | at 530 nm | EQE |
| Example 1 | 82.0% | 68.5% | 29.4% |
| Example 2 | 83.0% | 68.0% | 34.1% |
| Example 3 | 87.8% | 64.6% | 32.1% |
| Example 4 | 90.4% | 58.3% | 31.1% |
| Comp. | 96.8% | 26.0% | 18.0% |
| Example 1 | | | |

From the results of the above table, it can be confirmed that the composite of the Example can achieve significantly higher external quantum efficiency compared to the composite of the Comparative Example. For example, the composite of the Example may have an external quantum efficiency greater than or equal to about 30%.

### Comparative Example 2

A semiconductor nanoparticle composite film was obtained by using the semiconductor nanoparticle of Reference Example 6 and by forming an ink composition in the same manner as in Example 1 (except that the ligand exchange process was omitted).

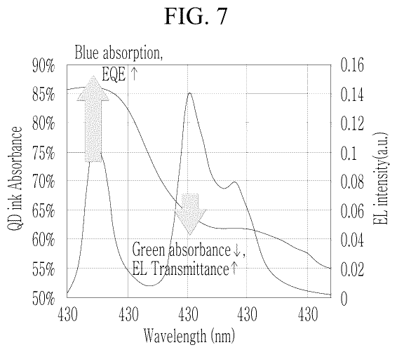

### Experimental Example 1

[1] The absorption and EL emission spectra of the semiconductor nanoparticle composite film of Example 2 and a Blue-Green OLED light source (4 stacks) having the structure described in FIG. 3B are shown in FIG. 7.

[2] For the semiconductor nanoparticle composite film of Example 2 and the semiconductor nanoparticle composite film of Comparative Example 2, brightness was measured using a Blue-Green OLED light source (4 stacks) having the structure described in FIG. 3B, and relative brightness to that of Comparative Example 2 was calculated. The results are summarized in Table 4 below.

TABLE 4

| | Relative Luminance |
|---|---|
| Example 2 | 115% |
| Comparative Example 2 | 100% |

$$Relative Luminance ( \% ) = [ Luminance of a given composite / Luminance of the composite of Comparative Example 2 ] \times 100$$

From the results of Table 4, it was confirmed that the composite of Example 2 provides improved brightness compared to the composite of Comparative Example 2.

While this disclosure has been described in connection with what is presently considered to be practical example embodiments, it is to be understood that the invention is not limited to the disclosed embodiments, On the contrary, it is intended to cover various modifications and equivalent arrangements included within the spirit and scope of the appended claims.

What is claimed is:

1. A display panel, comprising
a light emitting panel; and
a color conversion panel facing the light emitting panel,
wherein the light emitting panel is configured to emit incident light comprising a first light with a peak emission wavelength in a range of greater than or equal to about 440 nanometers and less than or equal to about 480 nanometers, and a second light with a peak emission wavelength in a range of greater than or equal to about 500 nanometers and less than or equal to about 580 nanometers,
wherein the color conversion panel comprises a color conversion layer comprising a color conversion region, the color conversion region comprises a first region corresponding to a green pixel,
the first region comprises a composite comprising a matrix and a semiconductor nanoparticle dispersed in the matrix,
the semiconductor nanoparticle comprises silver, a group 13 metal, and a chalcogen element, wherein the group 13 metal comprises indium and gallium, the chalcogen element comprises sulfur, and
wherein in the semiconductor nanoparticle, a mole ratio of gallium to indium is greater than or equal to about 6:1 and less than or equal to about 30:1, and a mole ratio of silver to indium is greater than or equal to about 3:1 and less than or equal to about 19:1.

2. The display panel of claim 1, wherein the light emitting panel comprises a first electrode, a second electrode, and an emission layer disposed between the first electrode and the second electrode, wherein the emission layer comprises a first emission layer and a second emission layer disposed on the first emission layer, and wherein the first emission layer is configured to emit the first light and the second emission layer is configured to emit the second light.

3. The display panel of claim 1, wherein a peak emission wavelength of the second light is greater than or equal to about 515 nanometers and less than or equal to about 535 nanometers, and
wherein a peak emission wavelength of the first light is greater than or equal to about 445 nanometers and less than or equal to about 465 nanometers.

4. The display panel of claim 1, wherein the semiconductor nanoparticle further comprises zinc, chlorine, or a combination thereof.

5. The display panel of claim 1, wherein the semiconductor nanoparticle comprises a core including a first semiconductor nanocrystal comprising silver, indium, gallium, and sulfur, and
a semiconductor nanocrystal shell disposed on the core, wherein the semiconductor nanocrystal shell comprises a second semiconductor nanocrystal comprising silver, gallium, and sulfur, a third semiconductor nanocrystal comprising zinc, gallium, and sulfur, or a combination thereof.

6. The display panel of claim 1, wherein
the composite has an absorbance greater than or equal to about 80% and less than or equal to about 99% for the first light, and a transmittance greater than or equal to about 55% and less than or equal to about 99% for light having a wavelength of 530 nanometers.

7. The display panel of claim 1, wherein in the semiconductor nanoparticle,
a mole ratio of gallium to sulfur is less than or equal to about 0.63:1 and greater than or equal to about 0.48:1,
a mole ratio of indium to sulfur is greater than or equal to about 0.02:1 and less than or equal to about 0.1:1, or
a mole ratio of silver to sulfur is greater than or equal to about 0.35:1 and less than or equal to about 0.44:1.

8. The display panel of claim 1, wherein in the semiconductor nanoparticle,
a mole ratio of a total of indium and gallium to silver is greater than or equal to about 1.4:1 and less than or equal to about 7:1, or
a mole ratio of a total of indium and gallium to sulfur is greater than or equal to about 0.54:1 and less than or equal to about 0.65:1.

9. The display panel of claim 1,
wherein the composite has an absorbance for the first light that is greater than or equal to about 85% and less than or equal to about 91%, and a transmittance for light having a wavelength of 530 nanometers that is greater than or equal to about 55% and less than or equal to about 85%,
or
wherein the composite has an external quantum efficiency defined by the following equation, when measured in an integrating hemisphere, that is greater than or equal to about 30%:
$$External Quantum Efficiency ( EQE , \% ) = [ A / B ] \times 100$$
A: a total of the amount of green light emitted from one surface of the first composite
B: an amount of the first light.

10. The display panel of claim 1, wherein the color conversion panel further comprises a partition wall defining each region of the color conversion layer, and the color conversion region further comprises a second region corresponding to a red pixel, a third region corresponding to a blue pixel, or a combination thereof.

11. A semiconductor nanoparticle composite, which comprises:
a matrix and a semiconductor nanoparticle dispersed in the matrix,
wherein the semiconductor nanoparticle comprises silver, a Group 13 metal, and a chalcogen element, wherein the Group 13 metal comprises indium and gallium,
wherein the chalcogen element comprises sulfur,
and wherein in the semiconductor nanoparticle,
a mole ratio of gallium to indium is greater than or equal to about 6:1 and less than or equal to about 30:1, and
a mole ratio of silver to indium is greater than or equal to about 3:1 and less than or equal to about 19:1.

12. The semiconductor nanoparticle composite of claim 11, wherein the semiconductor nanoparticle further comprises zinc, chlorine, or a combination thereof.

13. The semiconductor nanoparticle composite of claim 11, wherein
the semiconductor nanoparticle comprises a core including a first semiconductor nanocrystal comprising silver, indium, gallium, and sulfur, and
a semiconductor nanocrystal shell disposed on the core, wherein the semiconductor nanocrystal shell comprises a second semiconductor nanocrystal comprising silver, gallium, and sulfur; a third semiconductor nanocrystal comprising zinc, gallium, and sulfur; a fourth semiconductor nanocrystal comprising zinc and sulfur; or a combination thereof.

14. The semiconductor nanoparticle composite of claim 11,
wherein the semiconductor nanoparticle composite has an absorbance for a first light having a wavelength of 450 nanometers to 465 nanometers that is greater than or equal to about 80% and less than or equal to about 95%, and
wherein the semiconductor nanoparticle composite has a transmittance for light having a wavelength of 530 nanometers that is greater than or equal to about 55% and less than or equal to about 90%.

15. The semiconductor nanoparticle composite of claim 11, wherein in the semiconductor nanoparticle,
a mole ratio of gallium to sulfur is less than or equal to about 0.63:1 and greater than or equal to about 0.48:1,
a mole ratio of indium to sulfur is greater than or equal to about 0.02:1 and less than or equal to about 0.1:1,
or a mole ratio of silver to sulfur is greater than or equal to about 0.35:1 and less than or equal to about 0.44:1.

16. The semiconductor nanoparticle composite of claim 11,
wherein in the semiconductor nanoparticle,
a mole ratio of a total of indium and gallium to silver is greater than or equal to about 1.4:1 and less than or equal to about 7:1, or
a mole ratio of a total of indium and gallium to sulfur is greater than or equal to about 0.54:1 and less than or equal to about 0.65:1.

17. The semiconductor nanoparticle composite of claim 11,
wherein the semiconductor nanoparticle composite has an absorbance for the first light that is greater than or equal to about 82% and less than or equal to about 89%, and
a transmittance for light having a wavelength of 530 nanometers that is greater than or equal to about 60% and less than or equal to about 75%.

18. The semiconductor nanoparticle composite of claim 11,
wherein in an ultraviolet visual absorption spectrum of the semiconductor nanoparticle composite,
an absorption ratio of light having a wavelength of 450 nanometers to light having a wavelength of 350 nanometers is greater than or equal to about 0.2 and less than or equal to about 0.5, or
an absorption ratio of light having a wavelength of 530 nanometers to light having a wavelength of 350 nanometers is greater than or equal to about 0.001 and less than or equal to about 0.15.

19. An electronic device comprising the display panel of claim 1.

20. A color filter comprising the semiconductor nanoparticle composite of claim 11.
